(19) United States
(12) Patent Application Publication
(10) Pub. No.: US 2026/0290248 A1
(43) Pub. Date: Sep. 24, 2026

(54) Shift Register, Driving Method Thereof, Display Substrate and Display Device

(71) Applicants: Chengdu BOE Optoelectronics Technology Co., Ltd., Chengdu, Sichuan (CN); BOE Technology Group Co., Ltd., Beijing (CN)

(72) Inventors: Qian XU, Beijing (CN); Cong LIU, Beijing (CN); Gukhwan SONG, Beijing (CN); Youngjang LEE, Beijing (CN); Ming HU, Beijing (CN); Mengqi WANG, Beijing (CN)

(21) Appl. No.: 18/704,082

(22) PCT Filed: Aug. 11, 2023
(86) PCT No.: PCT/CN2023/112593

§ 371 Date: Apr. 24, 2024

(51) Int. Cl. G09G 3/3266; G11C 19/28

(52) U.S. Cl. CPC G09G 3/3266; G11C 19/28; G09G 2300/0426; G09G 2310/0286; G09G 2310/08; G09G 2320/0233; G09G 2330/021

(57) ABSTRACT

The invention discloses a shift register, a driving method thereof, a display substrate and a display device. The shift register includes a cascade output sub-circuit and a scan output sub-circuit; the cascade output sub-circuit is configured to provide signals to a first node and a second node under controlling of signals from a signal input terminal, a first clock signal terminal and a second clock signal terminal, and to provide a signal at a first power supply terminal or a second power supply terminal to a cascade output terminal under controlling of signals from the first node and the second node; the scan output sub-circuit is configured to provide a signal from a first power supply terminal or a second power supply terminal to a scan output terminal under controlling of signals from a first node, a second node and a scan control signal terminal.

### CROSS-REFERENCE TO RELATED APPLICATION

The present application is a U.S. National Phase Entry of International PCT Application No. PCT/CN2023/112593, having an international filing date of Aug. 11, 2023, the entire content of which is hereby incorporated by reference.

### TECHNICAL FIELD

The present disclosure relates to, but is not limited to, the field of display technology, and more particularly, to a shift register, a driving method thereof, a display substrate and a display device.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With constant development of display technologies, a flexible display apparatus (Flexible Display) in which an OLED or a QLED is used as a light emitting device and signal control is performed through a Thin Film Transistor (TFT) has become a mainstream product in the field of display at present.

### SUMMARY

The following is a summary of subject matter described in the present disclosure in detail. The summary is not intended to limit the scope of protection of the claims.

In a first aspect, the present disclosure provides a shift register including a cascaded output sub-circuit and a scan output sub-circuit;
the cascaded output sub-circuit is electrically connected with a signal input terminal, a first clock signal terminal, a second clock signal terminal, a first power supply terminal, a second power supply terminal, a cascaded output terminal, a first node and a second node, respectively, and is configured to provide signals to the first node and the second node under controlling of signals from the signal input terminal, the first clock signal terminal and the second clock signal terminal, and to provide a signal at the first power supply terminal or the second power supply terminal to the cascaded output terminal under controlling of signals from the first node and the second node;
the scan output sub-circuit is electrically connected with a scan control signal terminal, the first power supply terminal, the second power supply terminal, a scan output terminal, the first node and the second node, respectively, and is configured to provide a signal at the first power supply terminal or the second power supply terminal to the scan output terminal under controlling of signals from the first node, the second node and the scan control signal terminal.

In an exemplary embodiment, the scan output sub-circuit includes a first output control sub-circuit and a second output control sub-circuit;
the first output control sub-circuit is electrically connected with the second power supply terminal, the scan output terminal and the second node, respectively, and is configured to provide a signal at the second power supply terminal to the scan output terminal under controlling of a signal from the second node;
the second output control sub-circuit is electrically connected with the scan control signal terminal, the first power supply terminal, the scan output terminal and the first node, respectively, and is configured to provide signals at the first power supply terminal to the scan output terminal under the controls of signals from the scan control signal terminal and the first node.

In an exemplary embodiment, the scan output sub-circuit further includes a storage sub-circuit;
wherein the storage sub-circuit electrically connected with the scan output terminal and the first power supply terminal, respectively, and is configured to store voltage differences between signals at the scan output terminal and the first power supply terminal.

In an exemplary embodiment, the first output control sub-circuit includes a seventeenth transistor;
wherein a control electrode of the seventeenth transistor is electrically connected with the second node, a first electrode of the seventeenth transistor is electrically connected with the second power supply terminal, and a second electrode of the seventeenth transistor is electrically connected with the scan output terminal.

In an exemplary embodiment, the second output control sub-circuit includes an eighteenth transistor and a nineteenth transistor;
a control electrode of the eighteenth transistor is electrically connected with the first node, a first electrode of the eighteenth transistor is electrically connected with the first power supply terminal, and a second electrode of the eighteenth transistor is electrically connected with a third node;
a control electrode of the nineteenth transistor is electrically connected with the scan control signal terminal, a first electrode of the nineteenth transistor is electrically connected with the scan output terminal, and a second electrode of the nineteenth transistor is electrically connected with the third node.

In an exemplary embodiment, the second output control sub-circuit includes an eighteenth transistor and a nineteenth transistor;
a control electrode of the eighteenth transistor is electrically connected with the first node, a first electrode of the eighteenth transistor is electrically connected with the scan output terminal, and a second electrode of the eighteenth transistor is electrically connected with a third node;
a control electrode of the nineteenth transistor is electrically connected with the scan control signal terminal, a first electrode of the nineteenth transistor is electrically connected with the first power supply terminal, and a second electrode of the nineteenth transistor is electrically connected with the third node.

In an exemplary embodiment, the storage sub-circuit includes a fifth capacitor;
a first plate of the fifth capacitor is electrically connected with the scan output terminal, and a second plate of the fifth capacitor is electrically connected with the first power supply terminal.

In an exemplary embodiment, the cascaded output sub-circuit includes a first transistor to a sixteenth transistor and a first capacitor to a fourth capacitor, any one of the first capacitor to the fourth capacitor including a first plate and a second plate;
a control electrode of the first transistor is electrically connected with the first clock signal terminal, a first electrode of the first transistor is electrically connected with the signal input terminal, and a second electrode of the first transistor is electrically connected with a fourth node;
a control electrode of a second transistor is electrically connected with the fourth node, a first electrode of the second transistor is electrically connected with the first clock signal terminal, and a second electrode of the second transistor is electrically connected with a fifth node;
a control electrode of a third transistor is electrically connected with the first clock signal terminal, a first electrode of the third transistor is electrically connected with the first power supply terminal, and a second electrode of the third transistor is electrically connected with a fifth node;
a control electrode of a fourth transistor is electrically connected with a sixth node, a first electrode of the fourth transistor is electrically connected with the second clock signal terminal, and a second electrode of the fourth transistor is electrically connected with a seventh node;
a control electrode of a fifth transistor is electrically connected with the fifth node, a first electrode of the fifth transistor is electrically connected with the first power supply terminal, and a second electrode of the fifth transistor is electrically connected with the seventh node;
a control electrode of a sixth transistor is electrically connected with a ninth node, a first electrode of the sixth transistor is electrically connected with the second clock signal terminal, and a second electrode of the sixth transistor is electrically connected with an eighth node;
a control electrode of a seventh transistor is electrically connected with the second clock signal terminal, a first electrode of the seventh transistor is electrically connected with the eighth node, and a second electrode of the seventh transistor is electrically connected with the first node;
a control electrode of a eighth transistor is electrically connected with the fourth node, a first electrode of the eighth transistor is connected with the first power supply terminal, and a second electrode of the eighth transistor is connected with the first node;
a control electrode of a ninth transistor is electrically connected with the first node, a first electrode of the ninth transistor is electrically connected with the first power supply terminal, and a second electrode of the ninth transistor is electrically connected with the cascaded output terminal;
a control electrode of a tenth transistor is electrically connected with the second node, a first electrode of the tenth transistor is electrically connected with the second power supply terminal, and a second electrode of the tenth transistor is electrically connected with the cascaded output terminal;
a control electrode of a eleventh transistor is electrically connected with the second power supply terminal, a first electrode of the eleventh transistor is electrically connected with the fifth node, and a second electrode of the eleventh transistor is electrically connected with the ninth node;
a control electrode of a twelfth transistor is electrically connected with the second power supply terminal, a first electrode of the twelfth transistor is electrically connected with the fourth node, and a second electrode of the twelfth transistor is electrically connected with the second node;
a control electrode of a thirteenth transistor is electrically connected with a third power supply terminal, a first electrode of the thirteenth transistor is electrically connected with the first power supply terminal, and a second electrode of the thirteenth transistor is electrically connected with the fourth node;
a control electrode of a fourteenth transistor is electrically connected with the first clock signal terminal, a first electrode of the fourteenth transistor is electrically connected with the signal input terminal, and a second electrode of the fourteenth transistor is electrically connected with a tenth node;
a control electrode of a fifteenth transistor is electrically connected with the second power supply terminal, a first electrode of the fifteenth transistor is electrically connected with the tenth node, and a second electrode of the fifteenth transistor is electrically connected with the sixth node;
a control electrode of the sixteenth transistor is electrically connected with the sixth node, a first electrode of the sixteenth transistor is electrically connected with the sixth node, and a second electrode of the sixteenth transistor is electrically connected with the second node;
a first plate of the first capacitor is electrically connected with the ninth node, and a second plate of the first capacitor is electrically connected with the eighth node;
a first plate of a second capacitor is electrically connected with the first node, and the second plate of the second capacitor is electrically connected with the first power supply terminal;
a first plate of a third capacitor is electrically connected with the sixth node, and a second plate of the third capacitor is electrically connected with the seventh node;
a first plate of the fourth capacitor is electrically connected with the second power supply terminal, and a second plate of the fourth capacitor is electrically connected with the cascaded output terminal.

In an exemplary embodiment, the scan output sub-circuit includes a seventeenth transistor to a nineteenth transistor, or includes a seventeenth transistor to a nineteenth transistor and a fifth capacitor;
a control electrode of the seventeenth transistor is electrically connected with the second node, a first electrode of the seventeenth transistor is electrically connected with the second power supply terminal, and a second electrode of the seventeenth transistor is electrically connected with the scan output terminal;
a control electrode of an eighteenth transistor is electrically connected with the first node, a first electrode of the eighteenth transistor is electrically connected with the first power supply terminal, and a second electrode of the eighteenth transistor is electrically connected with a third node;
a control electrode of the nineteenth transistor is electrically connected with the scan control signal terminal, a first electrode of the nineteenth transistor is electrically connected with the scan output terminal, and a second electrode of the nineteenth transistor is electrically connected with a third node;
a first plate of the fifth capacitor is electrically connected with the scan output terminal, and the second plate of the fifth capacitor is electrically connected with the first power supply terminal.

In an exemplary embodiment, the scan output sub-circuit includes a seventeenth transistor to a nineteenth transistor, or includes a seventeenth transistor to a nineteenth transistor and a fifth capacitor;
a control electrode of the seventeenth transistor is electrically connected with the second node, a first electrode of the seventeenth transistor is electrically connected with the second power supply terminal, and a second electrode of the seventeenth transistor is electrically connected with the scan output terminal;
a control electrode of an eighteenth transistor is electrically connected with the first node, a first electrode of the eighteenth transistor is electrically connected with the scan output terminal, and a second electrode of the eighteenth transistor is electrically connected with the third node;
a control electrode of the nineteenth transistor is electrically connected with the scan control signal terminal, a first electrode of the nineteenth transistor is electrically connected with the first power supply terminal, and a second electrode of the nineteenth transistor is electrically connected with a third node;
a first plate of the fifth capacitor is electrically connected with the scan output terminal, and a second plate of the fifth capacitor is electrically connected with the first power supply terminal.

In a second aspect, the present disclosure also provides a display substrate including: a gate drive circuit located in a non-display area, and an array of sub-pixels and a plurality of gate lines located in a display area, the sub-pixels including a pixel drive circuit and a light emitting device, the gate lines extending at least partially in a first direction, the gate drive circuit including a plurality of cascaded shift registers, the pixel drive circuit including a plurality of transistors;
a cascaded output terminal of at least one stage of shift register is electrically connected with a signal input terminal of the at least one stage of shift register;
the gate line is electrically connected with a gate electrode of the at least one transistor, and any shift register is electrically connected with at least one gate line.

In an exemplary embodiment, the display area is divided into a plurality of display sub-areas, at least one display sub-area including at least one gate line; wherein display modes of any display sub-area include a first display mode and a second display mode, and a refresh frequency of the first display mode is greater than that of the second display mode;
in a state where a display mode of a display sub-area is the first display mode, for the shift register connected to the gate line in the display sub-area, when a signal at the cascade output terminal is a first level signal, a signal at the scan control signal terminal is an active level signal during at least part of time period, and a signal at the scan output terminal is a first level signal;
in a state where a display mode of a display sub-area is a second display mode, for the shift register connected to the gate line in the display sub-area, when a signal at the cascade output terminal is a first level signal, a signal at the scan control signal terminal is an inactive level signal, and a signal at the scan output terminal is a second level signal;
wherein, a voltage value of the first level signal is greater than that of the second level signal.

In an exemplary embodiment, further includes at least one scan control signal line located in the non-display area, the scan control signal line extending at least partially in a second direction, the first direction and the second direction intersecting;
scan control signal terminals connected to all shift registers are electrically connected with the at least one scan control signal line.

In an exemplary embodiment, a quantity of scan control signal lines is one,
and scan control signal terminals connected to all shift registers are electrically connected with the same scan control signal line.

In an exemplary embodiment, a quantity of the scan control signal lines is at least two;
a scan control signal terminal connected to any one of the shift registers of a M*(k−1)+k*M (a−1)+1 stage of shift register to a k*M+k*M (a−1) stage of shift register is electrically connected with a k-th scan control signal line, 1≤k≤K, 1≤a≤N/M, wherein M is a quantity of stages of shift registers to which a scan control signal line is connected, N is a total quantity of stages of shift registers, and K is a quantity of scan control signal lines.

In the exemplary embodiment, a picture displayed on the display substrate comprises a plurality of display frames, and in any display frame, a output signal at the scan output terminal of the shift register is a pulse signal, and the duration H of the pulse signal satisfies the following relational expression;

$$h = L * [ M * K - M - 1 ) ] * h$$

wherein L is a quantity of gate lines connected to any stage of shift registers, h is the unit time and is equal to a refresh interval time of adjacent row sub-pixels.

In an exemplary embodiment, further includes a first clock signal line, a second clock signal line, a first power supply line, a second power supply line, and a third power supply line located in the non-display area; wherein any one of the first clock signal line, the second clock signal line, the first power supply line, the second power supply line, and the third power supply line extends at least partially in the second direction;
a first clock signal terminal connected to any stage of shift registers is electrically connected with one of the first clock signal line and the second clock signal line, a second clock signal terminal connected to any stage of shift registers is electrically connected with the other of the first clock signal line and the second clock signal line, clock signal lines connected to first clock signal terminals connected to adjacent shift registers are different, clock signal lines connected to second clock signal terminals connected to adjacent shift registers are different, first power supply terminals connected to all shift registers are electrically connected with the first power supply line, second power supply terminals connected to all shift registers are electrically connected with the second power supply line, and third power supply terminals connected to all shift registers are electrically connected with the third power supply line.

In an exemplary embodiment, the scan control signal line is located on a side of any one of the first clock signal line, the second clock signal line, the first power supply line, the second power supply line, and the third power supply line near the display area.

In an exemplary embodiment, a quantity of the second power supply lines is two, and the first clock signal line, the second clock signal line, a first one of second power supply lines, the third power supply line, a second one of second power supply lines, and the first power supply line are sequentially arranged in a direction close to the display area.

In an exemplary embodiment, the shift register includes a seventeenth transistor to a nineteenth transistor; the seventeenth transistor to the nineteenth transistor are arranged in the second direction;
at least part of any one of the seventeenth transistor to the nineteenth transistor is located between the first power supply line and the scan control signal line.

In an exemplary embodiment, any transistor includes an active pattern, wherein an average length of the active pattern of the seventeenth transistor in the first direction is less than an average length of the active pattern of any of the eighteenth transistor and the nineteenth transistor in the first direction.

In an exemplary embodiment, a line width of either of the first power line and the second power line is larger than a line width of the scan control signal line.

In a third aspect, the present disclosure further provides a display device including the display substrate described above.

In a fourth aspect, the present disclosure further provides a driving method for a shift register, which is used for driving the shift register described above, the method includes:
a cascaded output sub-circuit provides signals to a first node and a second node under controlling of signals from a signal input terminal, a first clock signal terminal and a second clock signal terminal, and provides a signal at a first power supply terminal or a second power supply terminal to the cascaded output terminal under controlling of signals from the first node and the second node;
a scan output sub-circuit provides a signal at the first power supply terminal or the second power supply terminal to a scan output terminal under controlling of signals from the first node, the second node and the scan control signal terminal.

Other aspects of the present disclosure may be comprehended after the drawings and the detailed descriptions are read and understood.

### BRIEF DESCRIPTION OF DRAWINGS

Accompany drawings are used to provide further understanding of technical solution of the present disclosure, and form a part of the description. The accompany drawings and embodiments of the present disclosure are adopted to explain the technical solution of the present disclosure, and do not form limitations on the technical solution of the present disclosure.

FIG. 1 is a schematic structural diagram of a shift register in accordance with an embodiment of the present disclosure;

FIG. 2 is a schematic structural diagram of a shift register in accordance with an exemplary embodiment;

FIG. 3 is a schematic structural diagram of a shift register in accordance with an exemplary embodiment;

FIG. 4 is an equivalent circuit diagram of a first output control sub-circuit in accordance with an exemplary embodiment;

FIG. 5 is an equivalent circuit diagram of a second output control sub-circuit in accordance with an exemplary embodiment;

FIG. 6 is an equivalent circuit diagram of a second output control sub-circuit in accordance with another exemplary example;

FIG. 7 is an equivalent circuit diagram of a storage sub-circuit in accordance with an exemplary embodiment;

FIG. 8 is an equivalent circuit diagram of a cascaded output sub-circuit in accordance with an exemplary embodiment;

FIG. 9 is a first equivalent circuit diagram of a shift register;

FIG. 10 is a second equivalent circuit diagram of a shift register;

FIG. 11 is a third equivalent circuit diagram of a shift register;

FIG. 12 is a fourth equivalent circuit diagram of a shift register;

FIG. 13 is a timing diagram of a cascaded output sub-circuit in a shift register provided in FIGS. 9 to 12;

FIG. 14 is a first timing diagram of a scan output sub-circuit in a shift register provided in FIGS. 9 to 12;

FIG. 15 is a second timing diagram of a scan output sub-circuit in a shift register provided in FIGS. 9 to 12;

FIG. 16 is a third timing diagram of a scan output sub-circuit in a shift register provided in FIGS. 9 to 12;

FIG. 17 is a fourth timing diagram of a scan output sub-circuit in a shift register provided in FIGS. 9 to 12;

FIG. 18 is a schematic diagram of a structure of a display substrate;

FIG. 19 is a first cascade schematic diagram of a gate drive circuit;

FIG. 20 is a second cascade schematic diagram of a gate drive circuit;

FIG. 21 is a schematic diagram of an equivalent circuit of a pixel drive circuit;

FIG. 22 is an equivalent circuit diagram of another pixel drive circuit.

FIG. 23 is an operating timing diagram of a pixel drive circuit provided in FIGS. 21 and 22.

FIG. 24 is a timing diagram of a plurality of scan output terminals of a gate drive circuit provided in FIG. 19;

FIG. 25 is a timing diagram of a plurality of scan output terminals of a gate drive circuit provided in FIG. 20;

FIG. 26 is a partial schematic view of a non-display area of a display substrate;

FIG. 27 is a schematic diagram of active patterns of a seventeenth transistor to a nineteenth transistor;

FIG. 28 is a schematic diagram after a pattern of a semiconductor layer is formed in FIG. 26;

FIG. 29 is a schematic diagram of a pattern of a first conductive layer in FIG. 26.

FIG. 30 is a schematic diagram after a pattern of a first conductive layer is formed in FIG. 26;

FIG. 31 is a schematic diagram of a pattern of a second conductive layer in FIG. 26.

FIG. 32 is a schematic diagram after a pattern of a second conductive layer is formed in FIG. 26;

FIG. 33 is a schematic diagram after a pattern of a third insulation layer is formed in FIG. 26;

FIG. 34 is a schematic diagram of a pattern of a third conductive layer in FIG. 26.

FIG. 35 is a schematic diagram after a pattern of a third conductive layer is formed in FIG. 26;

FIG. 36 is a schematic diagram after a pattern of a fourth insulation layer is formed in FIG. 26.

FIG. 37 is a schematic diagram of a pattern of a fourth conductive layer in FIG. 26.

FIG. 38 is a schematic diagram after a pattern of a fourth conductive layer is formed in FIG. 26.

### DETAILED DESCRIPTION

To make the objectives, technical solutions, and advantages of the present disclosure clearer, the embodiments of the present disclosure will be described in detail below in with reference to the accompany drawings. It is to be noted that the implementation modes may be implemented in various forms. Those of ordinary skills in the art can easily understand such a fact that implementation modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflicts. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one implementation mode of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the composition elements may be changed as appropriate according to a direction according to which each composition element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or detachable connection, or integral connection; it may be mechanical connection or electrical connection; it may be direct connection, or indirect connection through an intermediate, or internal communication between two elements. Those of ordinary skills in the art can understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In cases that transistors with opposite polarities are used, or a current direction changes during operation of a circuit, or the like, functions of the “source electrode” and the “drain electrode” are sometimes interchangeable. Therefore, the “source electrode” and the “drain electrode” are interchangeable in the specification.

In the specification, “electrical connection” includes connection of composition elements through an element with a certain electrical action. An “element with a certain electrical action” is not particularly limited as long as electric signals between the connected composition elements may be sent and received. Examples of the “element with the certain electrical action” not only include an electrode and a line, but also include a switch element such as a transistor, a resistor, an inductor, a capacitor, another element with various functions, etc.

In the specification, “parallel” refers to a state in which an angle formed by two straight lines is −10° or more and 100 or less, and thus also includes a state in which the angle is −5° or more and 5° or less. In addition, “perpendicular” refers to a state in which an angle formed by two straight lines is 80° or more and 1000 or less, and thus also includes a state in which the angle is 850 or more and 950 or less.

In the specification, a “film” and a “layer” are interchangeable. For example, a “conductive layer” may be replaced with a “conductive thin film” sometimes. Similarly, an “insulation thin film” may be replaced with an “insulation layer” sometimes.

In the specification, “disposed in a same layer” refers to a structure formed by patterning two (or more than two) structures through a same patterning process, and their materials may be the same or different. For example, materials of precursors for forming multiple structures disposed in a same layer are the same, and final materials may be the same or different.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

A display substrate includes a pixel circuit, a light emitting device and a gate drive circuit, wherein the gate drive circuit is configured to provide a gate signal to the pixel circuit so that the pixel circuit can drive the light emitting device to emit light. The driving ability of gate drive circuit is weak such that the display requirements cannot be met.

In the display market, Low Temperature Poly-Silicon (LTPS) technology is used in most display substrates. LTPS technology has advantages of high resolution, high response speed, high brightness and high aperture ratio. Although it is welcomed by the market, the LTPS technology also has some defects, such as a relatively high production cost and relatively large power consumption. At this time, a technology solution of Low Temperature Polycrystalline Oxide (LTPO for short) came into being. Compared with the LTPS technology, in the LTPO technology, a leakage current is smaller, pixel point response is faster, and an additional layer of an oxide is added to a display substrate, which reduces energy consumption required for exciting pixel points, thus reducing power consumption during screen display.

The display product includes a gate drive circuit and a plurality of sub-pixels. A sub-pixel comprises a pixel drive circuit. When displaying a picture by the display product, the gate drive circuit generates a drive signal, and the pixel drive circuit initializes and writes data under a control of a drive signal, thus realizing the display. When the display product is displaying, the picture will be refreshed in each frame, that is, the pixel drive circuit needs to be initialized and data written in each frame. However, for some special pictures (such as off-screen displayed picture, static picture or less updated picture, etc.), it is not necessary to initialize and write data to the pixel drive circuit in at least some display frames, and the original brightness can be maintained by the pixel drive circuit with low leakage current. A gate drive circuit of a display product generates a drive signal in each frame regardless of which picture is displayed, and repeatedly initializes and writes data to the pixel drive circuit, so that the power consumption of the display product is high.

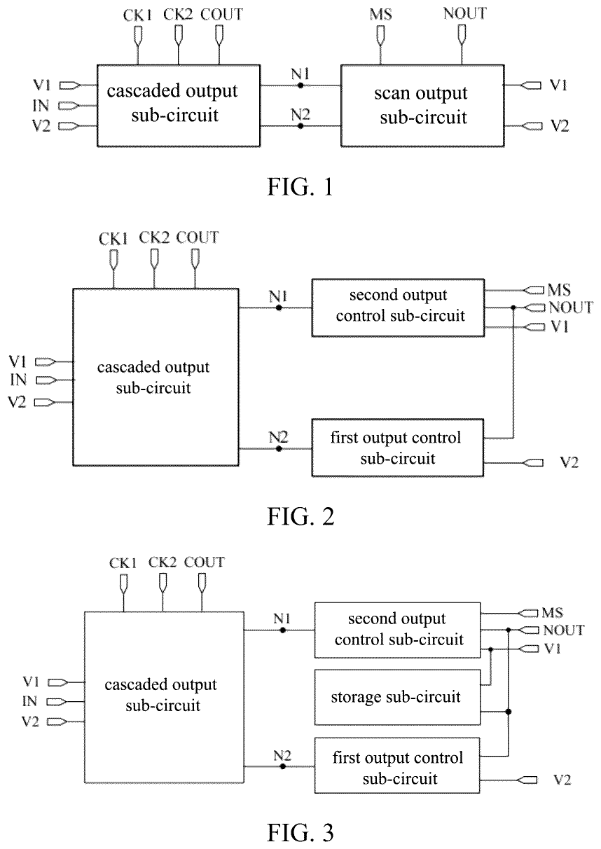

FIG. 1 is a schematic structural diagram of a shift register in accordance with an embodiment of the present disclosure. As shown in FIG. 1 an embodiment of the present disclosure provides a shift register that may include a cascaded output sub-circuit and a scan output sub-circuit.

As shown IN FIG. 1, the cascaded output sub-circuit is electrically connected with a signal input terminal IN, a first clock signal terminal CK1, a second clock signal terminal CK2, a first power supply terminal V1, a second power supply terminal V2, a cascaded output terminal COUT, a first node N1 and a second node N2, respectively, and is configured to provide signals to a first node N1 and a second node N2 under controlling of signals from the signal input terminal IN, the first clock signal terminal CK1 and the second clock signal terminal CK2, and to provide a signal at the first power supply terminal V1 or the second power supply terminal V2 to the cascaded output terminal COUT under controlling of signals from the first node N1 and the second node N2; the scan output sub-circuit is electrically connected with a scan control signal terminal MS, the first power supply terminal V1, the second power supply terminal V2, a scan output terminal NOUT, the first node N1 and the second node N2, respectively, and is configured to provide a signal at the first power supply terminal V1 or the second power supply terminal V2 to the scan output terminal NOUT under controlling of signals from the first node N1, the second node N2 and the scan control signal terminal MS.

In an exemplary embodiment, the signal at the signal input terminal IN is a single pulse signal.

In an exemplary embodiment, the signals at either of the first clock signal terminal CK1 and the second clock signal terminal CK2 may be square wave signals that repeat high and low voltages. Exemplarily, the signals at the first clock signal terminal CK1 and the second clock signal terminal CK2 may have the same period and may be configured as phase-shifted signals. Here, the signals at the second clock signal terminal CK2 may be phase shifted by half a period compared to the signals at the first clock signal terminal CK1. A high voltage period of a signal at either of the first clock signal terminal CK1 and the second clock signal terminal CK2 in each cycle may be set longer than a low voltage period.

In an exemplary embodiment, the high voltage period of the signal at the first clock signal terminal CK1 may be set so that its width overlaps the low voltage period of the signal at the second clock signal terminal CK2, and the low voltage period of the signal at the first clock signal terminal CK1 may be set so that its width overlaps the high voltage period of the signal at the second clock signal terminal CK2.

In an exemplary embodiment, a signal at the first power supply terminal V1 is a constant voltage signal and is a high level signal.

In an exemplary embodiment, a signal at the second power supply terminal V2 is a constant voltage signal and is a low-level signal.

In an exemplary embodiment, when the display product is displayed with a normal picture, a signal at the scan control signal terminal is an active level signal when a signal at the cascade output terminal is a first level signal in any display frame, so that the signal at the first power supply terminal V1 is written into the scan output terminal NOUT, and when the display product is displayed with a special picture, the signal at the scan control signal terminal is an inactive level signal when the signal at the cascade output terminal is a first level signal in some of the display frames, so that the signal at the second power supply terminal V2 is written into the scan output terminal NOUT. Wherein, the first level signal can be a high-level signal, a signal A is an active level signal which means that the signal A can make the transistor connected to the signal A turned on, and a signal A is an inactive level signal which means that the signal A can make the transistor connected to the signal A turned off.

The scan output sub-circuit provided by the embodiment of the present disclosure can control outputs in one display frame and can also control local picture refreshes of different display frames, thereby reducing the power consumption of the display product.

The shift register provided by the embodiment of the disclosure is electrically connected with the scan control signal terminal through the scan output sub-circuit, and can control whether to provide a drive signal to the scan output terminal through the scan control signal terminal, and when a normal picture is displayed, can output the drive signal in each frame and repeatedly initialize and write data to the pixel drive circuit to ensure the normal display, and when a special picture is displayed, cannot output the drive signal in some display frames, thus reducing the times of initializing and writing data to the pixel drive circuit, thereby reducing the power consumption of the display product and realizing the low power consumption display of the display product.

FIG. 2 is a schematic structural diagram of a shift register in accordance with an exemplary embodiment. As shown in FIG. 2, in an exemplary embodiment, a scan output sub-circuit may include a first output control sub-circuit and a second output control sub-circuit.

As shown in FIG. 2, the first output control sub-circuit is electrically connected with a second power supply terminal V2, a scan output terminal NOUT and a second node N2, respectively, and is configured to provide a signal at the second power supply terminal V2 to a scan output terminal NOUT under controlling of signals from the second node N2; the second output control sub-circuit is electrically connected with a scan control signal terminal MS, a first power supply terminal V1, the scan output terminal NOUT and the first node N1, respectively, and is configured to provide a signal at the first power supply terminal V1 to the scan output terminal NOUT under controlling of signals from the scan control signal terminal MS and the first node N1.

FIG. 3 is a schematic structural diagram of a shift register in accordance with an exemplary embodiment. As shown in FIG. 3, in an exemplary embodiment, a scan output sub-circuit may further include a storage sub-circuit. Wherein the storage sub-circuit is electrically connected with a scan output terminal NOUT and a first power supply terminal V1, respectively, and is configured to store voltage differences between the signals at the scan output terminal NOUT and the first power supply terminal V1.

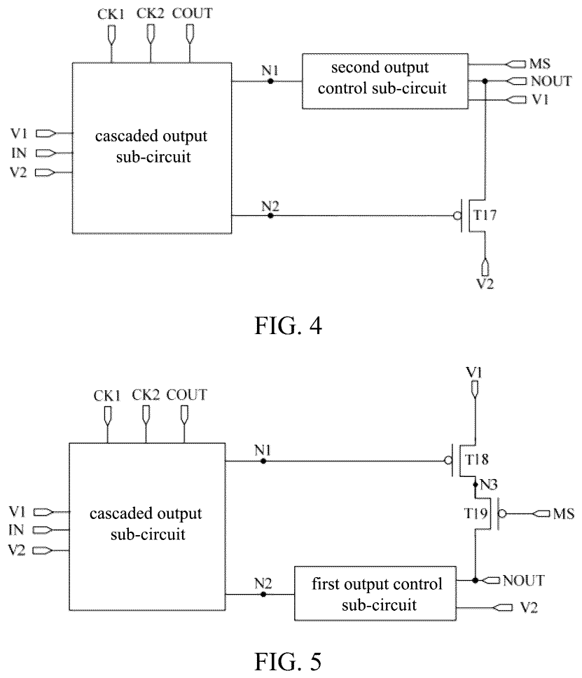

FIG. 4 is an equivalent circuit diagram of a first output control sub-circuit in accordance with an exemplary embodiment. As shown in FIG. 4, in an exemplary embodiment, the first output control sub-circuit may include a seventeenth transistor T17.

As shown in FIG. 4, a control electrode of the seventeenth transistor T17 is electrically connected with a second node N2, a first electrode of the seventeenth transistor T17 is electrically connected with a second power supply terminal V2, and a second electrode of the seventeenth transistor T17 is electrically connected with a scan output terminal NOUT.

Only one exemplary structure of the first output control sub-circuit is shown in FIG. 4, and it will be readily understood by those skilled in the art that the implementation of the first output control sub-circuit is not limited thereto.

FIG. 5 is an equivalent circuit diagram of a second output control sub-circuit in accordance with one exemplary embodiment and FIG. 6 is an equivalent circuit diagram of a second output control sub-circuit in accordance with another exemplary embodiment. As shown in FIGS. 5 and 6, in an exemplary embodiment, the second output control sub-circuit may include an eighteenth transistor T18 and a nineteenth transistor T19.

As shown in FIG. 5, a control electrode of the eighteenth transistor T18 is electrically connected with a first node N1, a first electrode of the eighteenth transistor T18 is electrically connected with a first power supply terminal V1, and a second electrode of the eighteenth transistor T18 is electrically connected with a third node N3; a control electrode of the nineteenth transistor T19 is electrically connected with a scan control signal terminal MS, a first electrode of the nineteenth transistor T19 is electrically connected with a scan output terminal NOUT, and a second electrode of the nineteenth transistor T19 is electrically connected with a third node N3.

As shown in FIG. 6, a control electrode of the eighteenth transistor T18 is electrically connected with a first node N1, a first electrode of the eighteenth transistor T18 is electrically connected with a scan output terminal NOUT, and a second electrode of the eighteenth transistor T18 is electrically connected with a third node N3; a control electrode of the nineteenth transistor T19 is electrically connected with a scan control signal terminal MS, a first electrode of the nineteenth transistor T19 is electrically connected with a first power supply terminal V1, and a second electrode of the nineteenth transistor T19 is electrically connected with a third node N3.

Only two exemplary structures of the second output control sub-circuit are shown in FIGS. 5 and 6, and it will be readily understood by those skilled in the art that the implementation of the second output control sub-circuit is not limited thereto.

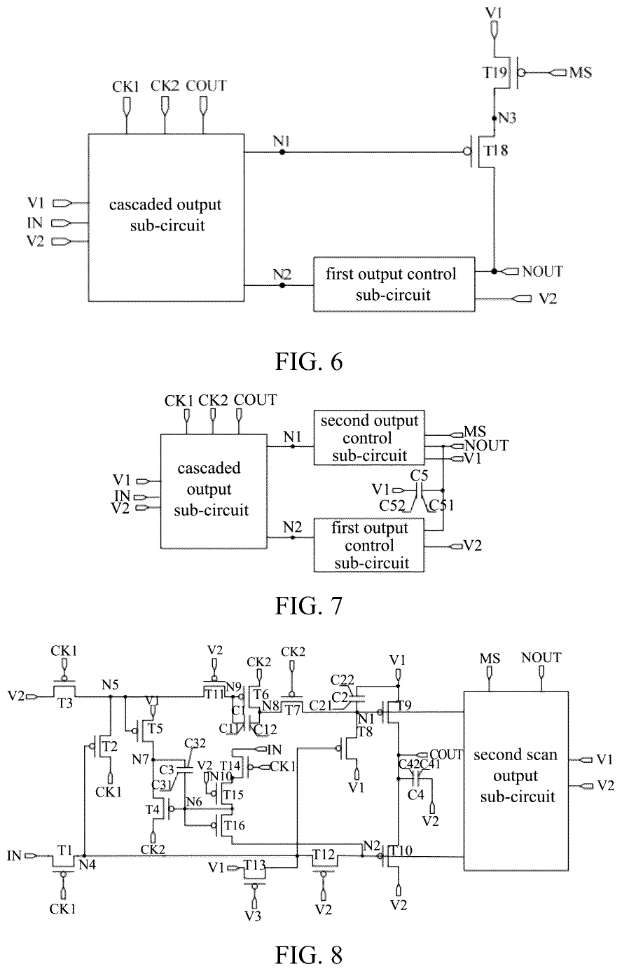

FIG. 7 is an equivalent circuit diagram of a storage sub-circuit in accordance with an exemplary embodiment, and as shown in FIG. 7, in the exemplary embodiment, the storage sub-circuit may include a fifth capacitor C5.

As shown in FIG. 7, a first plate C51 of the fifth capacitor C5 is electrically connected with a scan output terminal NOUT, and a second plate C52 of the fifth capacitor C5 is electrically connected with a first power supply terminal V1.

In an exemplary embodiment, the storage sub-circuit is arranged to ensure the stability of the output signal at the scan output NOUT and to improve the reliability of the shift register.

Only one exemplary structure of the storage sub-circuit is shown in FIG. 7, and it will be readily understood by those skilled in the art that the implementation of the storage sub-circuit is not limited thereto.

In an exemplary embodiment, a cascaded output sub-circuit may be a circuit structure of 10T3C, 10T4C, 12T3C, 12T4C, 13T3C, 13T4C, 16T3C, or 16T4C, which is not limited in this disclosure.

The scan output sub-circuit in accordance with the embodiment of the disclosure only comprises three transistors, and has a simple structure, and is beneficial to the layout of the odor register, and can also reduce the area occupied by the shift register, and can realize a narrow frame.

FIG. 8 is an equivalent circuit diagram of a cascaded output sub-circuit in accordance with an exemplary embodiment. FIG. 8 is illustrated by an example of 16T4C. As shown in FIG. 8, in the exemplary embodiment, the cascaded output sub-circuit may include a first transistor T1 to a sixteenth transistor T16 and a first capacitor C1 to a fourth capacitor C4, and any one of the first capacitors C1 to the fourth capacitor C4 includes a first plate and a second plate.

As shown in FIG. 8, a control electrode of the first transistor T1 is electrically connected with a first clock signal terminal CK1, a first electrode of the first transistor T1 is electrically connected with a signal input terminal IN, and a second electrode of the first transistor T1 is electrically connected with a fourth node N4; a control electrode of a second transistor T2 is electrically connected with the fourth node N4, a first electrode of the second transistor T2 is electrically connected with the first clock signal terminal CK1, and a second electrode of the second transistor T2 is electrically connected with a fifth node N5; a control electrode of a third transistor T3 is electrically connected with the first clock signal terminal CK1, a first electrode of the third transistor T3 is electrically connected with a second power supply terminal V2, and a second electrode of the third transistor T3 is electrically connected with the fifth node N5; a control electrode of a fourth transistor T4 is electrically connected with a sixth node N6, a first electrode of the fourth transistor T4 is electrically connected with a second clock signal terminal CK2, and a second electrode of the fourth transistor T4 is electrically connected with a seventh node N7; a control electrode of a fifth transistor T5 is electrically connected with the fifth node N5, a first electrode of the fifth transistor T5 is electrically connected with a first power supply terminal V1, and a second electrode of the fifth transistor T5 is electrically connected with a seventh node N7; a control electrode of a sixth transistor T6 is electrically connected with a ninth node N9, a first electrode of the sixth transistor T6 is electrically connected with the second clock signal terminal CK2, and a second electrode of the sixth transistor T6 is electrically connected with a eighth node N8; a control electrode of a seventh transistor T7 is electrically connected with the second clock signal terminal CK2, a first electrode of the seventh transistor T7 is electrically connected with the eighth node N8, and a second electrode of the seventh transistor T7 is electrically connected with the first node N1; a control electrode of the eighth transistor T8 is electrically connected with the fourth node N4, a first electrode of the eighth transistor T8 is electrically connected with the first power supply terminal V1, and a second electrode of the eighth transistor T8 is electrically connected with the first node N1; a control electrode of the ninth transistor T9 is electrically connected with the first node N1, a first electrode of the ninth transistor T9 is electrically connected with the first power supply terminal V1, and a second electrode of the ninth transistor T9 is electrically connected with a cascade output terminal COUT; a control electrode of a tenth transistor T10 is electrically connected with a second node N2, a first electrode of the tenth transistor T10 is electrically connected with the second power supply terminal V2, and a second electrode of the tenth transistor T10 is electrically connected with the cascaded output terminal COUT; a control electrode of a eleventh transistor T11 is electrically connected with the second power supply terminal V2, a first electrode of the eleventh transistor T11 is electrically connected with the fifth node N5, and a second electrode of the eleventh transistor T11 is electrically connected with the ninth node N9; a control electrode of a twelfth transistor T12 is electrically connected with the second power supply terminal V2, a first electrode of the twelfth transistor T12 is electrically connected with the fourth node N4, and a second electrode of the twelfth transistor T12 is electrically connected with the second node N2; a control electrode of a thirteenth transistor T13 is electrically connected with a third power supply terminal V3, a first electrode of the thirteenth transistor T13 is electrically connected with the first power supply terminal V1, and a second electrode of the thirteenth transistor T13 is electrically connected with the fourth node N4; a control electrode of a fourteenth transistor T14 is electrically connected with the first clock signal terminal CK1, a first electrode of the fourteenth transistor T14 is electrically connected with a signal input terminal IN, and a second electrode of the fourteenth transistor T14 is electrically connected with a tenth node N10; a control electrode of a fifteenth transistor T15 is electrically connected with the second power supply terminal V2, a first electrode of the fifteenth transistor T15 is electrically connected with the tenth node N10, and a second electrode of the fifteenth transistor T15 is electrically connected with the sixth node N6; a control electrode of the sixteenth transistor T16 is electrically connected with the sixth node N6, a first electrode of the sixteenth transistor T16 is electrically connected with the sixth node N6, and a second electrode of the sixteenth transistor T16 is electrically connected with the second node N2; a first plate C11 of the first capacitor C1 is electrically connected with the ninth node N9, and a second plate C12 of the first capacitor C1 is electrically connected with the eighth node N8; a first plate C21 of a second capacitor C2 is electrically connected with the first node N1, and a second plate C22 of the second capacitor C2 is electrically connected with the first power supply terminal V1; a first plate C31 of the third capacitor C3 is electrically connected with the sixth node N6, and a second plate C32 of the third capacitor C3 is electrically connected with the seventh node N7; a first plate C41 of the fourth capacitor C4 is electrically connected with the second power supply terminal V2, and a second plate C42 of the fourth capacitor C4 is electrically connected with the cascaded output terminal COUT.

In an exemplary embodiment, when the cascaded output sub-circuit is a circuit structure of 10T3C, the cascaded output sub-circuit includes a first transistor T1 to a tenth transistor T10 and a first capacitor C1 to a third capacitor C3.

In an exemplary embodiment, when the cascaded output sub-circuit is a circuit structure of 10T4C, the cascaded output sub-circuit includes a first transistor T1 to a tenth transistor T10 and a first capacitor C1 to a fourth capacitor C4.

In an exemplary embodiment, when the cascaded output sub-circuit is a circuit structure of 12T3C, the cascaded output sub-circuit includes a first transistor T1 to a twelfth transistor T12 and a first capacitor C1 to a third capacitor C3.

In an exemplary embodiment, when the cascaded output sub-circuit is a circuit structure of 12T3C, the cascaded output sub-circuit includes a first transistor T1 to a twelfth transistor T12 and a first capacitor C1 to a fourth capacitor C4.

In an exemplary embodiment, when the cascaded output sub-circuit is a circuit structure of 13T3C, the cascaded output sub-circuit includes a first transistor T1 to a thirteenth transistor T13 and a first capacitor C1 to a third capacitor C3.

In an exemplary embodiment, when the cascaded output sub-circuit is a circuit structure of 13T4C, the cascaded output sub-circuit includes a first transistor T1 to a thirteenth transistor T13 and a first capacitor C1 to a fourth capacitor C4.

In an exemplary embodiment, when the cascaded output sub-circuit is a circuit structure of 16T3C, the cascaded output sub-circuit includes a first transistor T1 to a sixteenth transistor T16 and a first capacitor C1 to a third capacitor C3.

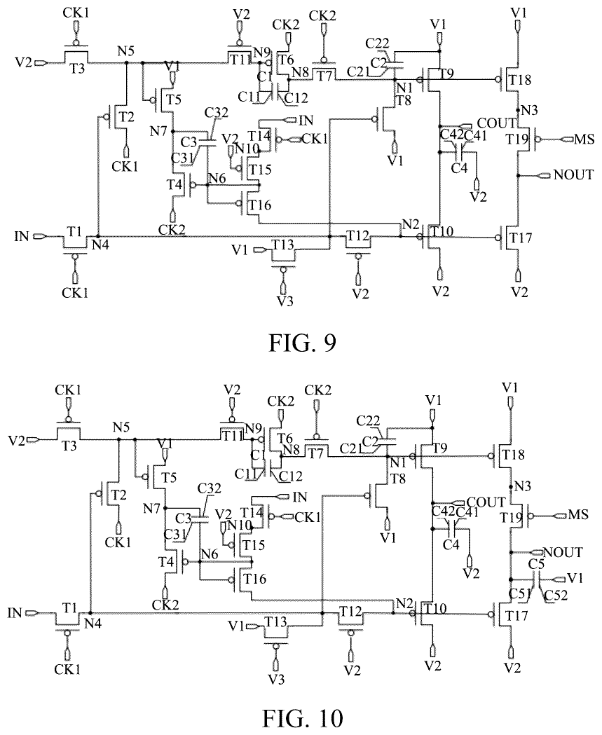

FIG. 9 is a first equivalent circuit diagram of a shift register, and FIG. 10 is a second equivalent circuit diagram of a shift register. As shown in FIGS. 9 and 10, in exemplary embodiments, the cascaded output sub-circuit may include a first transistor T1 to a sixteenth transistor T16 and a first capacitor C1 to a fourth capacitor C4, and any of the first capacitor C1 to the fourth capacitor C4 includes a first plate and a second plate, and the scan output sub-circuit may include a seventeenth transistor T17 to a nineteenth transistor T19, or include a seventeenth transistor to a nineteenth transistor T19 and a fifth capacitor C5. FIG. 9 illustrates an example of a scan output sub-circuit including a seventeenth transistor T17 to a nineteenth transistor T19, and FIG. 10 illustrates an example of a scan output sub-circuit including a seventeenth transistor T17 to a nineteenth transistor T19 and a fifth capacitor C5.

As shown in FIGS. 9 and 10, a control electrode of the first transistor T1 is electrically connected with a first clock signal terminal CK1, a first electrode of the first transistor T1 is electrically connected with a signal input terminal IN, and a second electrode of the first transistor T1 is electrically connected with a fourth node N4; a control electrode of a second transistor T2 is electrically connected with the fourth node N4, a first electrode of the second transistor T2 is electrically connected with the first clock signal terminal CK1, and a second electrode of the second transistor T2 is electrically connected with a fifth node N5; a control electrode of a third transistor T3 is electrically connected with the first clock signal terminal CK1, a first electrode of a third transistor T3 is electrically connected with a second power supply terminal V2, and a second electrode of the third transistor T3 is electrically connected with the fifth node N5; a control electrode of a fourth transistor T4 is electrically connected with a sixth node N6, a first electrode of the fourth transistor T4 is electrically connected with a second clock signal terminal CK2, and a second electrode of the fourth transistor T4 is electrically connected with a seventh node N7; a control electrode of a fifth transistor T5 is electrically connected with a fifth node N5, a first electrode of the fifth transistor T5 is electrically connected with a first power supply terminal V1, and a second electrode of the fifth transistor T5 is electrically connected with the seventh node N7; a control electrode of a sixth transistor T6 is electrically connected with a ninth node N9, a first electrode of the sixth transistor T6 is electrically connected with the second clock signal terminal CK2, and a second electrode of the sixth transistor T6 is electrically connected with a eighth node N8; a control electrode of a seventh transistor T7 is electrically connected with the second clock signal terminal CK2, a first electrode of the seventh transistor T7 is electrically connected with the eighth node N8, and a second electrode of the seventh transistor T7 is electrically connected with a first node N1; a control electrode of a eighth transistor T8 is electrically connected with the fourth node N4, a first electrode of the eighth transistor T8 is electrically connected with the first power supply terminal V1, and a second electrode of the eighth transistor T8 is electrically connected with the first node N1; a control electrode of a ninth transistor T9 is electrically connected with the first node N1, a first electrode of the ninth transistor T9 is electrically connected with the first power supply terminal V1, and a second electrode of the ninth transistor T9 is electrically connected with a cascade output terminal COUT; a control electrode of a tenth transistor T10 is electrically connected with a second node N2, a first electrode of the tenth transistor T10 is electrically connected with the second power supply terminal V2, and a second electrode of the tenth transistor T10 is electrically connected with the cascaded output terminal COUT; a control electrode of a eleventh transistor T11 is electrically connected with the second power supply terminal V2, a first electrode of the eleventh transistor T11 is electrically connected with the fifth node N5, and a second electrode of the eleventh transistor T11 is electrically connected with the ninth node N9; a control electrode of a twelfth transistor T12 is electrically connected with the second power supply terminal V2, a first electrode of the twelfth transistor T12 is electrically connected with the fourth node N4, and a second electrode of the twelfth transistor T12 is electrically connected with the second node N2; a control electrode of a thirteenth transistor T13 is electrically connected with a third power supply terminal V3, a first electrode of the thirteenth transistor T13 is electrically connected with the first power supply terminal V1, and a second electrode of the thirteenth transistor T13 is electrically connected with the fourth node N4; a control electrode of a fourteenth transistor T14 is electrically connected with the first clock signal terminal CK1, a first electrode of the fourteenth transistor T14 is electrically connected with the signal input terminal IN, and a second electrode of the fourteenth transistor T14 is electrically connected with a tenth node N10; a control electrode of a fifteenth transistor T15 is electrically connected with the second power supply terminal V2, a first electrode of the fifteenth transistor T15 is electrically connected with the tenth node N10, and a second electrode of the fifteenth transistor T15 is electrically connected with the sixth node N6; a control electrode of the sixteenth transistor T16 is electrically connected with the sixth node N6, a first electrode of the sixteenth transistor T16 is electrically connected with the sixth node N6, and a second electrode of the sixteenth transistor T16 is electrically connected with the second node N2; a first plate C11 of the first capacitor C1 is electrically connected with the ninth node N9; a control electrode of the seventeenth transistor T17 is electrically connected with the second node N2, a first electrode of the seventeenth transistor T17 is electrically connected with the second power supply terminal V2, and a second electrode of the seventeenth transistor T17 is electrically connected with a scan output terminal NOUT; a control electrode of a eighteenth transistor T18 is electrically connected with the first node N1, a first electrode of the eighteenth transistor T18 is electrically connected with the first power supply terminal V1, and a second electrode of the eighteenth transistor T18 is electrically connected with a third node N3; a control electrode of the nineteenth transistor T19 is electrically connected with a scan control signal terminal MS, a first electrode of the nineteenth transistor T19 is electrically connected with the scan output terminal NOUT, and a second electrode of the nineteenth transistor T19 is electrically connected with the third node N3; a second plate C12 of the first capacitor C1 is electrically connected with the eighth node N8; a first plate C21 of a second capacitor C2 is electrically connected with the first node N1, and a second plate C22 of the second capacitor C2 is electrically connected with the first power supply terminal V1; a first plate C31 of a third capacitor C3 is electrically connected with the sixth node N6, and a second plate C32 of the third capacitor C3 is electrically connected with the seventh node N7; a first plate C41 of the fourth capacitor C4 is electrically connected with the second power supply terminal V2, and a second plate C42 of the fourth capacitor C4 is electrically connected with the cascaded output terminal COUT; a first plate C51 of a fifth capacitor C5 is electrically connected with the scan output terminal NOUT, and a second plate C52 of the fifth capacitor C5 is electrically connected with the first power supply terminal V1.

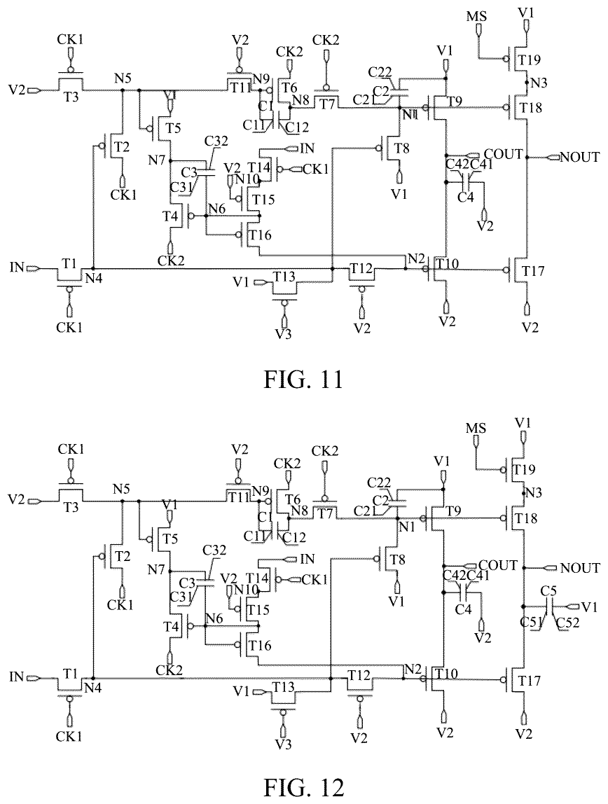

FIG. 11 is a third equivalent circuit diagram of a shift register, and FIG. 12 is a fourth equivalent circuit diagram of a shift register. As shown in FIGS. 11 and 12, in exemplary embodiments, a cascaded output sub-circuit may include a first transistor T1 to a sixteenth transistor T16 and a first capacitor C1 to a fourth capacitor C4, and any of the first capacitor C1 to the fourth capacitor C4 includes a first plate and a second plate, and a scan output sub-circuit may include a seventeenth transistor T17 to a nineteenth transistor T19, or include a seventeenth transistor T17 to a nineteenth transistor T19 and a fifth capacitor C5. FIG. 11 illustrates an example of a scan output sub-circuit including a seventeenth transistor T17 to a nineteenth transistor T19, and FIG. 12 illustrates an example of a scan output sub-circuit including a seventeenth transistor to a nineteenth transistor T19 and a fifth capacitor C5.

As shown in FIGS. 11 and 12, a control electrode of the first transistor T1 is electrically connected with a first clock signal terminal CK1, a first electrode of the first transistor T1 is electrically connected with a signal input terminal IN, and a second electrode of the first transistor T1 is electrically connected with a fourth node N4; a control electrode of a second transistor T2 is electrically connected with a fourth node N4, a first electrode of the second transistor T2 is electrically connected with the first clock signal terminal CK1, and a second electrode of the second transistor T2 is electrically connected with a fifth node N5; a control electrode of a third transistor T3 is electrically connected with the first clock signal terminal CK1, a first electrode of the third transistor T3 is electrically connected with a second power supply terminal V2, and a second electrode of the third transistor T3 is electrically connected with the fifth node N5; a control electrode of a fourth transistor T4 is electrically connected with a sixth node N6, a first electrode of the fourth transistor T4 is electrically connected with a second clock signal terminal CK2, and a second electrode of the fourth transistor T4 is electrically connected with a seventh node N7; a control electrode of a fifth transistor T5 is electrically connected with a fifth node N5, a first electrode of the fifth transistor T5 is electrically connected with a first power supply terminal V1, and a second electrode of the fifth transistor T5 is electrically connected with a seventh node N7; a control electrode of a sixth transistor T6 is electrically connected with a ninth node N9, a first electrode of the sixth transistor T6 is electrically connected with the second clock signal terminal CK2, and a second electrode of the sixth transistor T6 is electrically connected with the eighth node N8; a control electrode of a seventh transistor T7 is electrically connected with the second clock signal terminal CK2, a first electrode of the seventh transistor T7 is electrically connected with the eighth node N8, and a second electrode of the seventh transistor T7 is electrically connected with the first node N1; a control electrode of a eighth transistor T8 is electrically connected with the fourth node N4, a first electrode of the eighth transistor T8 is electrically connected with the first power supply terminal V1, and a second electrode of the eighth transistor T8 is electrically connected with the first node N1; a control electrode of a ninth transistor T9 is electrically connected with the first node N1, a first electrode of the ninth transistor T9 is electrically connected with the first power supply terminal V1, and a second electrode of the ninth transistor T9 is electrically connected with the cascade output terminal COUT; a control electrode of a tenth transistor T10 is electrically connected with the second node N2, a first electrode of the tenth transistor T10 is electrically connected with the second power supply terminal V2, and a second electrode of the tenth transistor T10 is electrically connected with the cascaded output terminal COUT; a control electrode of a eleventh transistor T11 is electrically connected with the second power supply terminal V2, a first electrode of the eleventh transistor T11 is electrically connected with the fifth node N5, and a second electrode of the eleventh transistor T11 is electrically connected with the ninth node N9; a control electrode of a twelfth transistor T12 is electrically connected with the second power supply terminal V2, a first electrode of the twelfth transistor T12 is electrically connected with the fourth node N4, and a second electrode of the twelfth transistor T12 is electrically connected with the second node N2; a control electrode of a thirteenth transistor T13 is electrically connected with the third power supply terminal V3, a first electrode of the thirteenth transistor T13 is electrically connected with the first power supply terminal V1, and a second electrode of the thirteenth transistor T13 is electrically connected with the fourth node N4; a control electrode of a fourteenth transistor T14 is electrically connected with the first clock signal terminal CK1, a first electrode of the fourteenth transistor T14 is electrically connected with the signal input terminal IN, and a second electrode of the fourteenth transistor T14 is electrically connected with a tenth node N10; a control electrode of a fifteenth transistor T15 is electrically connected with the second power supply terminal V2, a first electrode of the fifteenth transistor T15 is electrically connected with the tenth node N10, and a second electrode of the fifteenth transistor T15 is electrically connected with the sixth node N6; a control electrode of a sixteenth transistor T16 is electrically connected with the sixth node N6, a first electrode of the sixteenth transistor T16 is electrically connected with the sixth node N6, and a second electrode of the sixteenth transistor T16 is electrically connected with the second node N2; a first plate C11 of the first capacitor C1 is electrically connected with the ninth node N9; a control electrode of a seventeenth transistor T17 is electrically connected with the second node N2, a first electrode of the seventeenth transistor T17 is electrically connected with the second power supply terminal V2, and a second electrode of the seventeenth transistor T17 is electrically connected with the scan output terminal NOUT; a control electrode of a eighteenth transistor T18 is electrically connected with the first node N1, a first electrode of the eighteenth transistor T18 is electrically connected with the scan output terminal NOUT, and a second electrode of the eighteenth transistor T18 is electrically connected with the third node N3; a control electrode of a nineteenth transistor T19 is electrically connected with a scan control signal terminal MS, a first electrode of the nineteenth transistor T19 is electrically connected with a first power supply terminal V1, and a second electrode of the nineteenth transistor T19 is electrically connected with a third node N3; a second plate C12 of the first capacitor C1 is electrically connected with the eighth node N8; a first plate C21 of a second capacitor C2 is electrically connected with the first node N1, and a second plate C22 of the second capacitor C2 is electrically connected with the first power supply terminal V1; a first plate C31 of a third capacitor C3 is electrically connected with a sixth node N6, and a second plate C32 of the third capacitor C3 is electrically connected with a seventh node N7; a first plate C41 of the fourth capacitor C4 is electrically connected with the second power supply terminal V2, and a second plate C42 of the fourth capacitor C4 is electrically connected with the cascaded output terminal COUT; a first plate C51 of the fifth capacitor C5 is electrically connected with the scan output terminal NOUT, and a second plate C52 of the fifth capacitor C5 is electrically connected with the first power supply terminal V1.

In an exemplary embodiment, any of the first capacitor C1 to fifth capacitor C5 may be a capacitor device fabricated by a process, for example, the capacitor device may be implemented by fabricating a special capacitor electrode, and a plurality of capacitor electrodes of the capacitor may be implemented by metal layers, semiconductor layers (e.g. doped polysilicon), or the like. Alternatively, any of the first capacitance C1 to the fifth capacitance C5 may be a parasitic capacitance between a plurality of devices, and may be implemented by the transistor itself and other devices or lines. The connection mode of any of the first capacitor C1 to the fifth capacitor C5 includes but is not limited to the mode described above, and may be another suitable connection mode which may store the level of the corresponding node. Herein, the illustrative embodiments of the present disclosure are not limited thereto.

In the exemplary embodiments, FIGS. 9 to 12 illustrate an example of a circuit structure in which the cascaded output sub-circuit is 16T4C.

In an exemplary embodiment, the transistors may be divided into N type transistors and P type transistors according to their characteristics. When a transistor is a P-type transistor, its turn-on voltage is a low-level voltage (e.g., 0V, −5 V, −10 V, or another suitable voltage), and its turn-off voltage is a high-level voltage (e.g., 5 V, 10 V, or another suitable voltage). When a transistor is an N-type transistor, its turn-on voltage is a high-level voltage (e.g., 5 V, 10 V, or another suitable voltage), and its turn-off voltage is a low-level voltage (e.g., 0 V, −5 V, −10 V, or another suitable voltage).

In an exemplary embodiment, the first transistor T1 to the nineteenth transistor T19 may be P-type transistors in the shift registers provided in FIGS. 9 to 12. The first transistor T1 to the nineteenth transistor T19 may be P-type transistors, thereby simplifying the manufacturing process of the shift register.

In an exemplary embodiment, the outputs of the cascaded output sub-circuit and the scan output sub-circuit are independent due to the presence of the scan control signal terminal MS, and the operating processes of the cascaded output sub-circuit and the scan output sub-circuit will now be described separately.

In an exemplary embodiment, the first power supply terminal V1 continuously provides a high-level signal, and the second power supply terminal V2 continuously provides a low-level signal. The eleventh transistor T11, the twelfth transistor T12, and the fifteenth transistor T15 are continuously turned on since the second power supply terminal V2 continuously provides a low level signal.

In an exemplary embodiment, the third power supply terminal V3 is a low-level signal during startup initialization stage, which prevents the ninth transistor T9 and the tenth transistor T10 of a control shift register in a last stage from simultaneously being turned on because of delay of an output signal, or is a low-level signal during abnormal shutdown stage, which prevents the ninth transistor T9 and the tenth transistor T10 from simultaneously being turned on. The third power supply terminal V3 continuously provides the high-level signal during normal display stage, i.e., the thirteenth transistor T13 is turned off during the normal display stage.

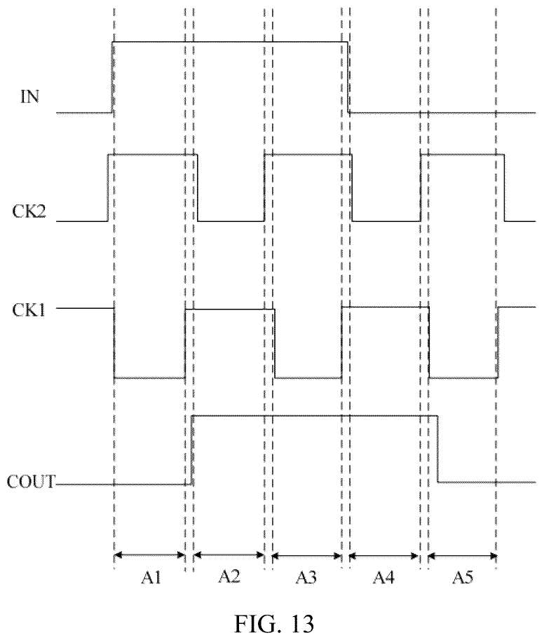

FIG. 13 is a timing diagram of the cascaded output sub-circuits in the shift registers provided in FIGS. 9 to 12. FIG. 13 shows an exemplary embodiment of the first transistor T1 to the sixteenth transistor T16 that are P-type transistors. As shown in FIG. 13, the operating process of the cascaded output sub-circuit in accordance with an exemplary embodiment may include the following stages.

During a first stage A1, signals at a signal input terminal IN and a second clock signal terminal CK2 are high-level signals and a signal at a first clock signal terminal CK1 is a low-level signal. As the signal at the first clock signal terminal CK1 is a low-level signal, the first transistor T1, the third transistor T3 and the twelfth transistor T12 are turned on, and the turned-on first transistor T1 transmits the high-level signal at the signal input terminal IN to a fourth node N4, and the signal at the fourth node N4 becomes a high-level signal, and the turned-on twelfth transistor T12 transmits the high-level signal at the fourth node N4 to a second node N2, and the turned-on fourteenth transistor T14 transmits the high-level signal at the signal input terminal IN to a tenth node N10, and the signal at the tenth node N10 becomes a high-level signal, and the turned-on fifteenth transistor T15 transmits the high-level signal at the tenth node N10 to a sixth node N6, and a second transistor T2, a fourth transistor T4, a eighth transistor T8, a tenth transistor T10 and a sixteenth transistor T16 are turned off. In addition, the turned-on third transistor T3 transmits the low-level signal at the third power supply terminal V2 to the second node N5, and a signal at the second node N5 becomes the low-level signal, the turned-on eleventh control transistor T11 transmits the low-level signal at the second node N5 to a ninth node N9, and a signal at the ninth node N9 becomes the low-level signal, and the fifth transistor T5 and the sixth transistor T6 are turned on. Although the signal at the second clock signal terminal CK2 is the high-level signal, since the seventh transistor T7 is turned off, the signal at the first node N1 is not pulled high and is kept at the low-level signal, the ninth transistor T9 is turned off, and the signal at the cascade output terminal COUT is kept at a previous low level. During the first stage A1, the signal at the first node N1 is the low-level signal, the signal at the second node N2 is the high-level signal, and the signal at the cascaded output terminal COUT keeps the previous low-level signal.

During a second stage A2, the signal at the second clock signal terminal CK2 is the low-level signal, and the signals at the signal input terminal IN and the first clock signal terminal CK1 are high-level signals. As the signal at the second clock signal terminal CK2 is the low-level signal, the seventh transistor T7 is turned on. The signal at the first clock signal terminal CK1 is the high-level signal, and the first transistor T1 and the third transistor T3 are turned off. Under the action of the third control capacitor C3, the fourth node N4, the second node N2, the sixth node N6, and the tenth node N10 may continue to keep the high-level signal during a previous stage, and under an action of the first control capacitor C1, the fifth node N5 and the ninth node N9 may continue to keep the low level during the previous stage, so the fifth transistor T5 and the sixth transistor T6 are turned on. The second transistor T2, the fourth transistor T4, the eighth transistor T8, and the tenth transistor T10 are turned off. In addition, as the low-level signal at the second clock signal terminal CK2 is transmitted to the first node N1 through the turned-on sixth transistor T6 and the turned-on seventh transistor T7, the ninth transistor T9 is turned on, and the high-level signal at the first power supply terminal V1 is transmitted to the cascade output terminal COUT through the turned-on ninth transistor T9. Therefore, during this stage, the signal at the first node N1 is the low-level signal, the signal at the second node N2 is the high-level signal, and the signal at the cascade output terminal COUT is the high-level signal.

During a third stage A3, the signal at the first clock signal terminal CK is the low-level signal, and the signals at the signal input terminal IN and the second clock signal terminal CK2 are high-level signals. As the signal at the second clock signal terminal CK2 is the high-level signal, the seventh transistor T7 is turned off, and under the action of the second capacitor C2, the first node N1 keeps the low-level signal during the previous stage, the ninth transistor T is continuously turned on, and the high-level signal at the first power supply terminal V1 is transmitted to the cascade output terminal COUT through the turned-on ninth transistor T9. As the signal at the first clock signal terminal CK1 is the low-level signal, the first transistor T1, the third transistor T3 and the twelfth transistor T12 are turned on, and as the turned-on first transistor T1 transmits the high-level signal at the signal input terminal IN to the fourth node N4, the signal at the fourth node N4 becomes the high-level signal, and as the turned-on twelfth transistor T12 transmits the high-level signal at the fourth node N4 to the second node N2, and the turned-on fourteenth transistor T14 transmits the high-level signal at the signal input terminal IN to the tenth node N10, the signal at the tenth node N10 becomes the high-level signal, and as the turned-on fifteenth transistor T15 transmits the high-level signal at the tenth node N10 to the sixth node N6, the second transistor T2, the fourth transistor T4, the eighth transistor T8, the tenth transistor T10 and the sixteenth transistor T16 are turned off. In addition, as the turned-on third transistor T3 transmits the low-level signal at the third power supply terminal V2 to the fifth node N5, the signal at the second node N5 becomes the low-level signal, and as the turned-on eleventh transistor T11 transmits the low-level signal at the second node N5 to the ninth node N9, the signal at the sixth node N9 becomes the low-level signal, and the fifth transistor T5 and the sixth control transistor T6 are turned on. During this stage, the signal at the first node N1 is the low-level signal, the signal at the second node N2 is the high-level signal, and the signal of the cascaded output terminal COUT is the high-level signal.

During a fourth stage A4, the signals at the signal input terminal IN and the second clock signal terminal CK2 are low-level signals, and the signal at the first clock signal terminal CK1 is the high-level signal. As the signal at the first clock signal terminal CK1 is the high-level signal, the first transistor T1 and the third transistor T3 are turned off. As the signal at the second clock signal terminal CK2 is the low-level signal, the seventh transistor T7 is turned on. Due to a storage function of the third capacitor C3, the signals at the fourth node N4, the second node N2, the sixth node N6 and the tenth node N10 are kept at the high-level signal during the previous stage, and the second transistor T2, the fourth transistor T4, the eighth transistor T8 and the tenth transistor T10 are turned off. Due to a storage function of the first capacitor C1, the ninth node N9 is continuously kept at the low level during the previous stage, and the fifth transistor T5 and the sixth transistor T6 are turned on. In addition, the low-level signal at the second clock signal terminal CK2 is transmitted to the first node N1 through the turned-on sixth transistor T6 and the turned-on seventh transistor T7, and the high-level signal at the first power supply terminal V1 is transmitted to the cascade output terminal COUT through the turned-on ninth transistor T9, and the signal at the cascade output terminal COUT is still the high-level signal. During this stage, the signal at the first node N1 is the high-level signal, the signal at the second node N2 is the low-level signal, and the signal at the cascaded output COUT is the high-level signal.

During a fifth stage A5, the signal at the second clock signal terminal CK2 is the high-level signal, and the signals at the signal input terminal IN and the second clock signal terminal CK1 are low-level signals. As the signal at the first clock signal terminal CK1 is the low-level signal, the first transistor T1, the third transistor T3, and the fourteenth transistor T14 are turned on. As the signal at the second clock signal terminal CK2 is the high-level signal, the seventh transistor T7 is turned off. As the turned-on first transistor T1 transmits the low-level signal at the signal input IN to the fourth node N4, the signal at the fourth node N4 becomes the low-level signal, and as the turned-on twelfth transistor T12 transmits the low-level signal at the fourth node N4 to the first node N1, the signal at the first node N1 becomes the low-level signal, and as the turned-on fourteenth transistor T14 transmits the low-level signal at the signal input IN to the tenth node N10, the signal at the tenth node N10 becomes the low-level signal, and as the turned-on fifteenth transistor T15 transmits the low-level signal at the tenth node N10 to the sixth node N6, the signal at the sixth node N6 becomes the low-level signal, and the second transistor T2, the fourth transistor T4, the eighth transistor T8 and the tenth transistor T10 are turned on. As the turned-on second transistor T2 transmits the low-level signal at the first clock signal terminal CK1 to the fifth node N5 so that the fifth node N5 becomes the low-level signal, the fifth node N5 and the ninth node N9 are continuously kept at the low-level signal during the previous stage, and the fifth transistor T5 and the sixth transistor T6 are turned on. As the signal at the second clock signal terminal CK2 is the high-level signal, the seventh transistor T7 is turned off. In addition, as the high-level signal at the first power supply terminal V1 is transmitted to the first node N1 through the turned-on eighth transistor T8, the ninth transistor T9 is turned off. As the low-level signal at the second power supply terminal V2 is transmitted to the cascade output terminal COUT through the turned-on tenth transistor T10, the signal at the cascade output terminal COUT becomes the low-level signal. During this stage, the signal at the first node N1 is the high-level signal, the signal at the second node N2 is the low-level signal, and the signal at the cascade output terminal COUT is the low-level signal.

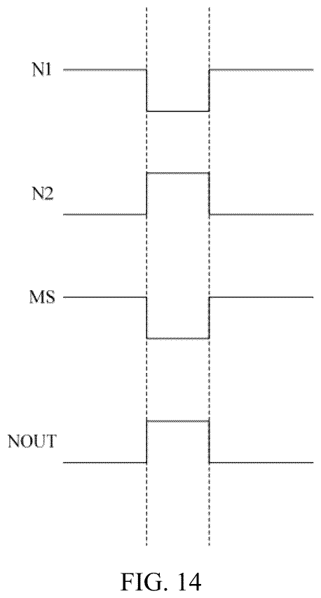

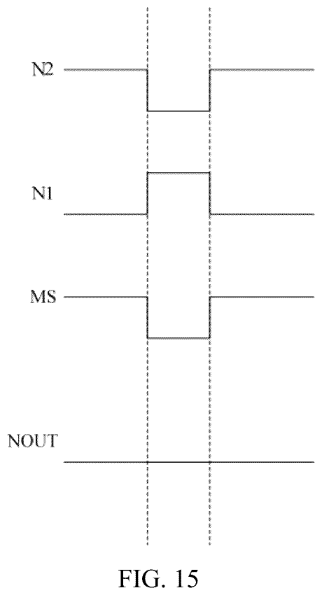

FIG. 14 is a first timing diagram of a scan output sub-circuit in the shift registers provided in FIGS. 9 to 12, FIG. 15 is a second timing diagram of a scan output sub-circuit in the shift registers provided in FIGS. 9 to 12, FIG. 16 is a third timing diagram of a scan output sub-circuit in the shift registers provided in FIGS. 9 to 12, and FIG. 17 is a fourth timing diagram of a scan output sub-circuit in the shift registers provided in FIGS. 9 to 12. FIG. 14 to 17 illustrate an exemplary embodiment of the seventeenth transistor T17 to the nineteenth transistor T19 that are P-type transistors.

FIG. 14 and FIG. 15 illustrate an example when a display product is displaying a normal display picture. In any frame, when a signal of a cascade output terminal COUT is a high-level signal, the signal at a scan control signal terminal MS is a low-level signal during at least a part of a time period.

As shown in FIG. 14, when an output signal of the cascade output terminal COUT is a high-level signal, the signal at a first node N1 is a low-level signal and the signal at a second node N2 is a high-level signal. As the signal at the second node N2 is the high-level signal, the seventeenth transistor T17 becomes turned off. As the signal at the first node N1 is the low-level signal, an eighteenth transistor T18 is turned on, and as the signal at the scan control signal terminal MS is the low-level signal during at least part of a time period, a nineteenth transistor T19 is turned on, the signal at the first power supply terminal V1 is transmitted to the scan output terminal NOUT through the turned-on eighteenth transistor T18 and the turned-on nineteenth transistor T19, the signal at the scan output terminal NOUT is the high-level signal.

As shown in FIG. 15, when an output signal at the cascade output terminal COUT is a low-level signal, a signal at the first node N1 is a high-level signal and a signal at the second node N2 is a low-level signal. As the signal at the first node N1 is the high-level signal, a signal at an eighteenth transistor T18 is turned off, and the high-level signal at a first power supply terminal V1 cannot be transmitted to a scan output terminal NOUT. As the signal at the second node N2 is the low-level signal, the seventeenth transistor T17 is turned on, the low-level signal at a second power supply terminal V2 is transmitted to the scan output terminal NOUT, and the signal at the scan output terminal NOUT is the low-level signal.

When the display product is displaying a normal picture, as the signal at the cascade output terminal COUT becomes the high-level signal, the signal at the scan output terminal NOUT becomes the high-level signal, and as the signal at the cascade output terminal COUT becomes the low-level signal, the signal at the scan output terminal NOUT becomes the low-level signal, that is, the signal at the cascade output terminal COUT is consistent with the signal at the scan output terminal NOUT, and thus a normal display of the display product can be realized.

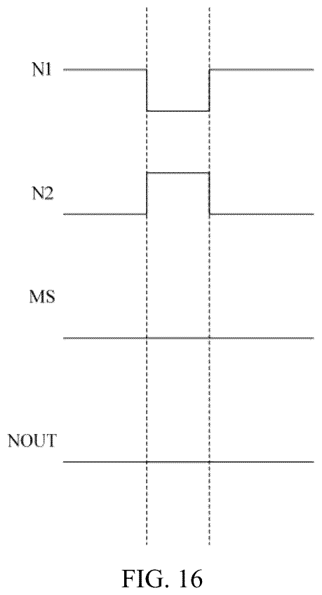

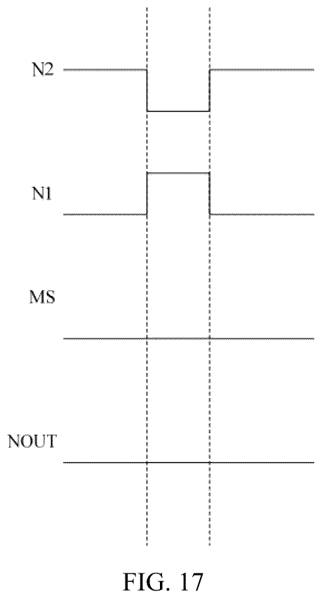

FIG. 16 and FIG. 17 illustrate exemplary embodiments in which a special picture is displayed by a display product. In some frames, a signal at a scan control signal terminal MS is a high-level signal when a signal at a cascade output terminal is the high-level signal.

As shown in FIG. 16, when an output signal at a cascaded output terminal COUT is the high-level signal, a signal at a first node N1 is a low-level signal and a signal at a second node N2 is the high-level signal. As the signal at the second node N2 is the high-level signal, a seventeenth transistor T17 is turned off. As the signal at the first node N1 is the low-level signal, an eighteenth transistor T18 is turned on, the signal at the scan control signal terminal MS is the high-level signal, the nineteenth transistor T19 is turned off, a signal at a first power supply terminal V1 cannot be written to a scan output terminal NOUT, and the signal at the scan output terminal NOUT is kept the low-level signal.

As shown in FIG. 17, when the output signal at the cascade output terminal COUT is the low-level signal, the signal at the first node N1 is the high-level signal and the signal at the second node N2 is the low-level signal. As the signal at the first node N1 is the high-level signal, the eighteenth transistor T18 is turned off, and as the signal at the scan control signal terminal MS is the high-level signal, the nineteenth transistor T19 is turned off, and the high-level signal at the first power supply terminal V1 cannot be transmitted to the scan output terminal NOUT. As the signal at the second node N2 is the low-level signal, the seventeenth transistor T17 is turned on, the low-level signal at the second power supply terminal V2 is transmitted to the scan output terminal NOUT, and the signal at the scan output terminal NOUT is the low-level signal.

As shown in FIGS. 16 and 17, when a special picture is displayed by a display product, the signal at the scan output NOUT is the low-level signal regardless of whether the signal at the cascade output COUT is the high-level signal or the low-level signal, thereby reducing quantities of initialization and data writing of a pixel drive circuit and reducing power consumption of the display product.

The embodiment of the present disclosure also provides a driving method of a shift register, which is configured to drive the shift register. The driving method for the shift register may include acts 100-200.

In act 100, a cascaded output sub-circuit provides signals to a first node and a second node under controlling of signals from a signal input terminal, a first clock signal terminal and a second clock signal terminal, and the cascaded output sub-circuit provides a signal at a first power supply terminal or a second power supply terminal to a cascaded output terminal under controlling of signals from the first node and the second node.

In act 200, the scan output sub-circuit provides a signal at the first power supply terminal or the second power supply terminal to a scan output terminal under controlling of the signals from the first node, the second node and the scan control signal terminal.

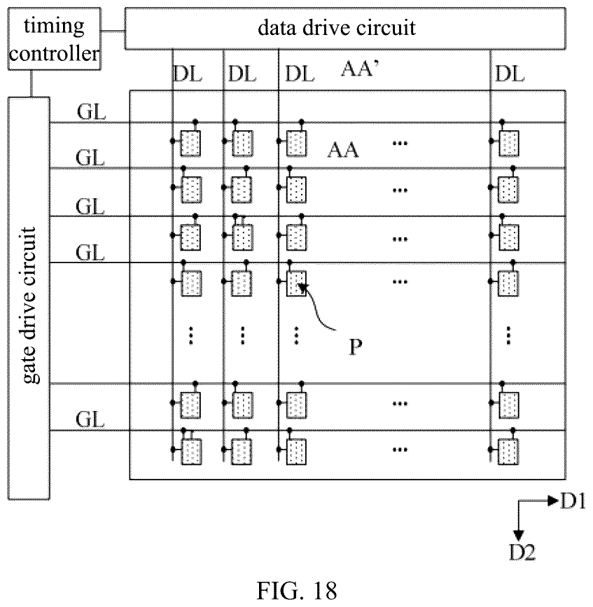

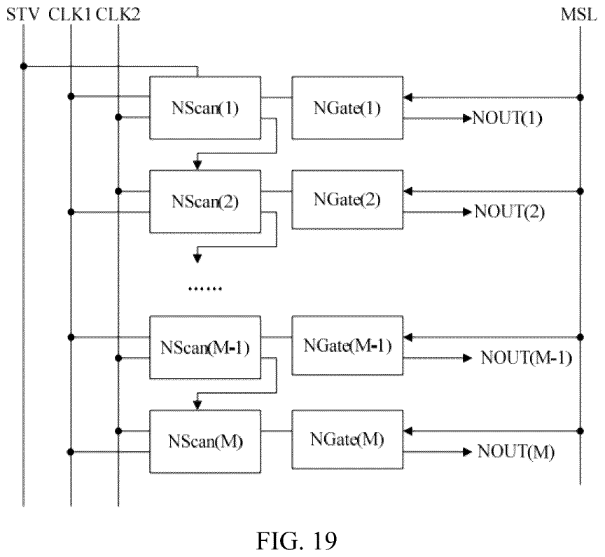

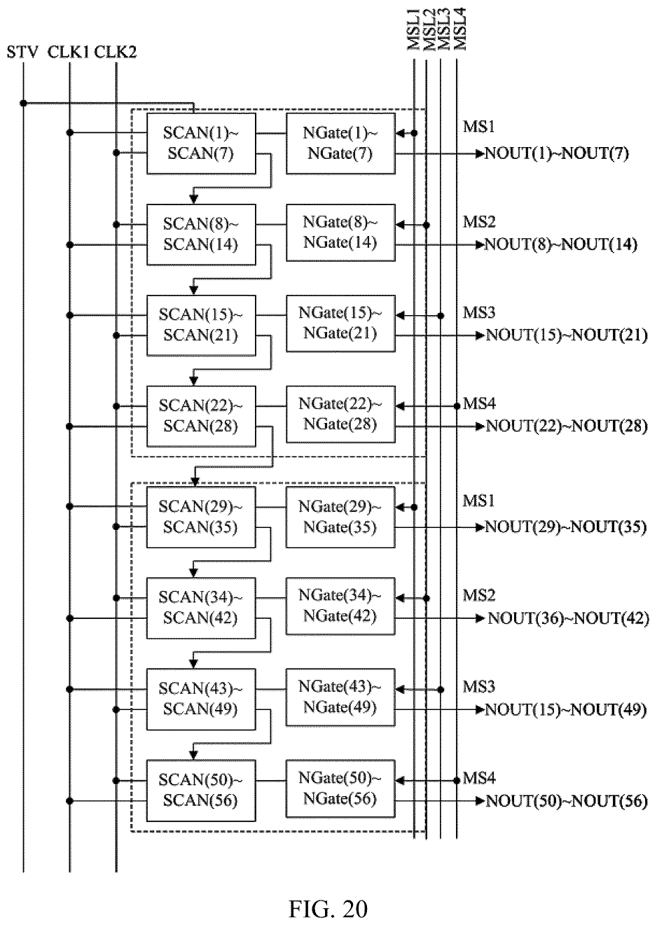

FIG. 18 is a schematic diagram of a structure of a display substrate, FIG. 19 is a first cascade schematic diagram of a gate drive circuit, and FIG. 20 is a second cascade schematic diagram of a gate drive circuit. As shown in FIGS. 18 to 20, the display substrate has a display area AA and a non-display area AA′, and the display substrate may include a gate drive circuit located in the non-display area AA′ and sub-pixels and a plurality of gate lines GL arranged in an array located in the display area AA, the sub-pixels including a pixel drive circuit P and a light emitting device. Wherein the gate line GL extends at least partially in a first direction D1, the gate drive circuit includes a plurality of cascaded shift registers, and the pixel drive circuit includes a plurality of transistors. Wherein, a cascaded output terminal of at least one stage of shift register is electrically connected with the signal input terminal of the at least one stage of shift register, a gate line is electrically connected with a gate electrode of at least one transistor, and any shift register is electrically connected with at least one gate line. In FIGS. 19 and 20, NScan (i) is a cascaded output sub-circuit of an ith stage of shift register, NGate (i) is a scan output sub-circuit of the ith stage of shift register, and NOUT (i) is a scan output terminal of the ith stage of shift register.

The shift register may be the shift register in accordance with any one of the aforementioned embodiments, and its implementation principle and implementation effect are similar to the foresaid implementation principle and implementation effect and will not be repeated herein.

In an exemplary embodiment, as shown in FIG. 18, the display substrate may further include a timing controller and a data drive circuit located in the non-display area AA′ and a plurality of data lines DL located in the display area AA, the data lines DL extending in the second direction D2, and the first direction D1 and the second direction D2 intersect. The pixel drive circuit is also electrically connected with the data line DL. The timing controller is respectively connected with the data drive circuit and the gate drive circuit, the data drive circuit being respectively connected with the plurality of data lines DL and the gate drive circuit being respectively connected to a plurality of gate lines GL. The display substrate further includes the light-emitting devices arranged in the array located in the display area, the pixel drive circuit being configured to drive the light-emitting devices to emit light, and the sub-pixels being composed of the pixel drive circuit and the light-emitting devices driven by the pixel drive circuit.

In an exemplary embodiment, the timing controller may provide a control signal and a gray scale value suitable for the specification of the data drive circuit to the data drive circuit, and may provide a start signal, a clock signal suitable for the specification of the gate drive circuit and the like to the gate drive circuit. The data drive circuit may generate a data voltage to be provided to a data line DL by using the gray-scale value and the control signal received from the timing controller. For example, the data drive circuit may sample the gray-scale value by using a clock signal, and apply a data voltage corresponding to the gray-scale value to the data line DL by taking a pixel row as a unit. The gate drive circuit may generate a scan signal to be provided to the gate line by receiving a clock signal, a start signal, or the like from the timing controller. For example, the gate drive circuit may sequentially provide a scan signal with an on-level pulse to the gate line GL.

In an exemplary embodiment, the display substrate may include a plurality of pixel units arranged in a matrix, at least one of the plurality of pixel units includes a first sub-pixel emitting light of a first color, a second sub-pixel emitting light of a second color, and a third sub-pixel emitting light of a third color, and the first sub-pixel, the second sub-pixel, and the third sub-pixel each includes a pixel drive circuit and a light emitting device. Pixel drive circuits in the first sub-pixel, the second sub-pixel, and the third sub-pixel are respectively connected with a data line and a gate line. The pixel drive circuit is configured to receive a data voltage transmitted by the data line and output a corresponding current to the light emitting device under controlling of the gate line. The light emitting devices in the first sub-pixel, the second sub-pixel and the third sub-pixel are respectively connected to the pixel drive circuits of the sub-pixels where the light emitting devices are located. The light emitting device is configured to emit light of corresponding brightness in response to a current output by the pixel drive circuit of the sub-pixel where the light emitting device is located.

In an exemplary embodiment, the first sub-pixel may be a red (R) sub-pixel emitting red light, the second sub-pixel may be a blue (B) sub-pixel emitting blue light, and the third sub-pixel may be a green (G) sub-pixel emitting green light. In an exemplary embodiment, the sub-pixels may be in a shape of rectangular, rhombic, pentagonal, or hexagonal, and the present disclosure is not limited herein.

In an exemplary implementation, a pixel unit may include three sub-pixels, and the three sub-pixels may be arranged side by side horizontally, side by side vertically, or in a manner like a Chinese character “ ”, and the present disclosure is not limited herein.

In an exemplary embodiment, a pixel unit may include four sub-pixels, and the four sub-pixels may be arranged in a manner to stand side by side horizontally, in a manner to stand side by side vertically, or in a manner to form a square, which is not limited here in the present disclosure.

For different display products, cascade relationships of the plurality of shift registers in the gate driving circuit may be different. Regardless of the cascade relationships of the plurality of shift registers and no matter how many rows of sub-pixels are driven by each of the shift registers, as long as such a large-area device is changed and such a change generates additional space, both possible simple translation and stretching of a small device are within protection scope of the present disclosure.

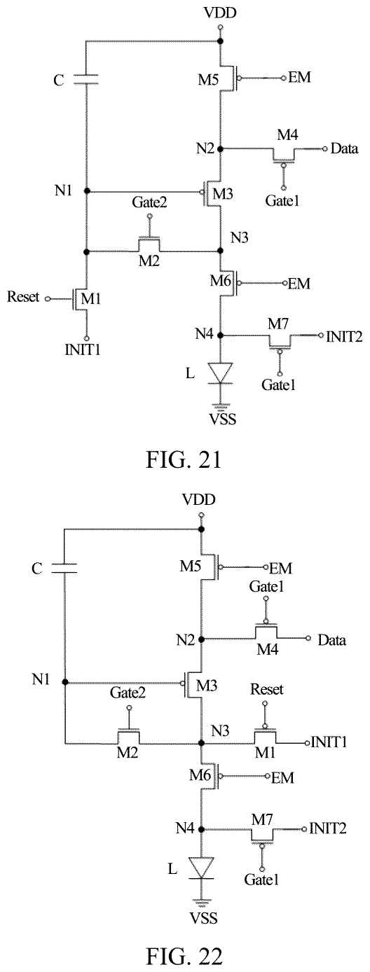

FIG. 21 is a schematic diagram of an equivalent circuit of one pixel drive circuit, and FIG. 22 is a schematic diagram of an equivalent circuit of another pixel drive circuit. In an exemplary embodiment, the pixel drive circuit may have a structure of 3T1C, 4T1C, 5T1C, 5T2C, 6T1C, 7T1C, or 8T1C. As shown in FIGS. 21 and 22, the pixel drive circuit may include seven transistors (a first transistor M1 to a seventh transistor M7), and one capacitor C.

As shown in FIGS. 21 and 22, a gate electrode of the first transistor M1 is electrically connected with a reset signal line Reset, a first electrode of the first transistor M1 is electrically connected with a first initial signal line INIT1, and a second electrode of the first transistor M1 is electrically connected with a first node N1 or a third node N3; a gate electrode of a second transistor M2 is electrically connected with a second scan signal line Gate2, a first electrode of the second transistor M2 is electrically connected with the first node N1, and a second electrode of the second transistor M2 is electrically connected with the third node N3; a gate electrode of a third transistor M3 is electrically connected with the first node N1, a first electrode of the third transistor M3 is electrically connected with a second node N2, and a second electrode of the third transistor M3 is electrically connected with the third node N3; a gate electrode of a fourth transistor M4 is electrically connected with a first scan signal line Gate1, a first electrode of the fourth transistor M4 is electrically connected with a Data signal line Data, and a second electrode of the fourth transistor M4 is electrically connected with the second node N2; a gate electrode of a fifth transistor M5 is electrically connected with a light emitting signal line EM, a first electrode of the fifth transistor M5 is electrically connected with a high-level power supply line VDD, and a second electrode of the fifth transistor M5 is electrically connected with the second node N2; a gate electrode of a sixth transistor M6 is electrically connected with a light emitting signal line EM, a first electrode of the sixth transistor M6 is electrically connected with the third node N3, and a second electrode of the sixth transistor M6 is electrically connected with a fourth node N4; a gate electrode of the seventh transistor M7 is electrically connected with the first scan signal line Gate1, a first electrode of the seventh transistor M7 is electrically connected with a second initial signal line INIT2, and a second electrode of the seventh transistor M7 is electrically connected with the fourth node N4; a first plate of the capacitor C is electrically connected with the first node N1, and a second plate of the capacitor C is electrically connected with the high-level power line VDD. FIG. 21 illustrates an example of an electric connection between the second electrode of the first transistor M1 and the first node N1, and FIG. 22 illustrates an example of an electric connection between the second electrode of the first transistor M1 and the third node N3.

In an exemplary embodiment, for the first transistor M1 to the seventh transistor M7, low temperature poly-silicon thin film transistors may be used, or oxide thin film transistors may be used, or both a low temperature poly-silicon thin film transistor and an oxide thin film transistor may be used. An active pattern of a low temperature poly-silicon thin film transistor may be made of Low Temperature Poly-Silicon (LTPS for short), and an active pattern of an oxide thin film transistor may be made of an oxide semiconductor (Oxide). A Low-temperature Poly Silicon thin film transistor has advantages such as a high mobility rate and fast charging, and an oxide thin film transistor has advantages such as a low leakage current. The Low Temperature Poly Silicon thin film transistor and the oxide thin film transistor are integrated on one display substrate to form a LTPO display substrate, and advantages of both the Low Temperature Poly Silicon thin film transistor and the oxide thin film transistor may be utilized, which may achieve low frequency drive, reduce power consumption, and improve display quality.

In exemplary embodiments, the first transistor M1 and the second transistor M2 are of opposite transistor types to the third transistor M3 to the seventh transistor M7. Exemplarily, the first transistor M1 and the second transistor M2 may be N-type transistors, and the third transistors M3 to the seventh transistors M7 may be P-type transistors.

In an exemplary embodiment, the first transistor M1 and the second transistor M2 may be oxide transistors, and the third transistor M3 to the seventh transistor M7 may be low-temperature poly silicon transistors.

In an exemplary embodiment, a voltage value of a signal of the first initial signal line INIT1 is constant and the signal is a DC signal. The voltage value of the signal of the first initial signal line INIT1 may be −3V.

In an exemplary embodiment, the voltage value of the signal of the second initial signal line INIT2 is constant and the signal is a DC signal, and the voltage value of the signal of the second initial signal line INIT2 may be 0V.

In an exemplary embodiment, the light emitting device L may be electrically connected with the fourth node N4 and the low-level power supply line VSS, respectively.

In an exemplary implementation, a high-level power supply line VDD continuously provides a high-level signal, and a low power supply line VSS continuously provides a low-level signal.

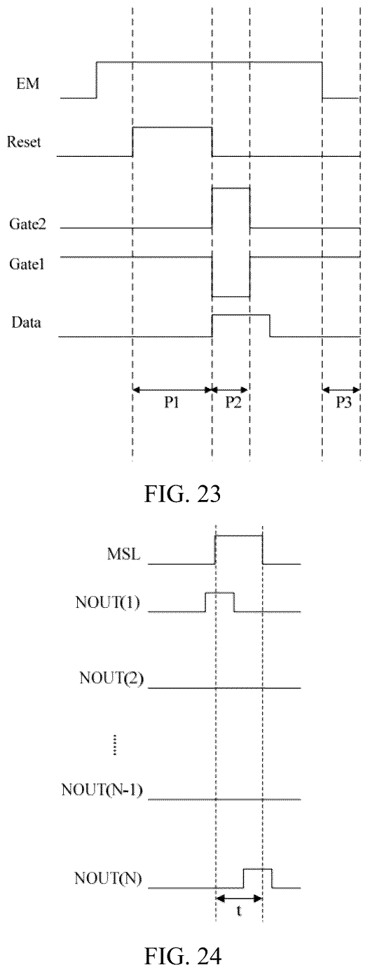

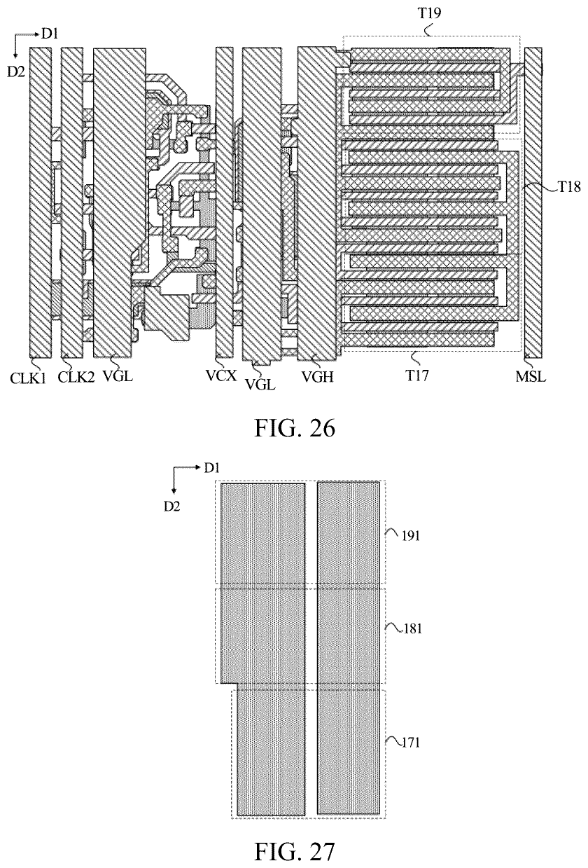

FIG. 23 is an operating timing diagram of a pixel drive circuit provided in FIGS. 21 and 22. Exemplary embodiments of the present disclosure are described below through an operation process of the pixel circuit illustrated in FIGS. 21 and 22 in a display stage. FIG. 23 illustrates an exemplary embodiment in which a first transistor M1 and a second transistor M2 are N-type transistors and a third transistor M3 to a seventh transistor M7 are P-type transistors. A pixel drive circuit in FIG. 26B includes a first transistor M1 to a seventh transistors M7, one capacitor C, and eight signal lines (a Data signal line Data, a first scan signal line Gate1, a second scan signal line Gate2, a reset signal line Reset, a first initial signal line INIT1, a second initial signal line INIT2, a light emitting signal line EM, and a high-level power supply line VDD).

As shown in conjunction with FIG. 21, FIG. 22, and FIG. 23, the operation process of the Pixel Drive Circuit may include following stages.

In a second stage P1, referred as an initialization stage, the signal of the reset signal line Reset is a high-level signal, the first transistor M1 is turned on, and the signal of the first initial signal terminal INIT1 is written into the first node N1 of the third transistor M3 through the turned-on first transistor M1, so as to initialize (reset) the first node N1 or the third transistor M3, empty the pre-stored voltage inside it and complete the initialization.

In a second stage P2, referred to as a data writing stage or a threshold compensation stage, the signal of the first scan signal line Gate1 is a low-level signal, the signal of the second scan signal line Gate2 is a high-level signal, and the data signal line Data outputs a data voltage. In this stage, since the first node N1 is a low-level signal, the third transistor M3 is turned on. The signal of the first scan signal line Gate1 is a low-level signal, the fourth transistor M4 is turned on and the seventh transistor M7 is turned on, the signal of the second scan signal line Gate2 is a high-level signal, the second transistor M2 is turned on, the data voltage outputted from the data signal line Data is provided to the first node N1 through the turned-on fourth transistor M4, the second node N2, the turned-on third transistor M3, the third node N3 and the turned-on second transistor M2, the difference between the data voltage output by the data signal line Data and the threshold voltage of the third transistor M3 is charged into the capacitor C, until the voltage of the first node N1 is Vd−|Vth|, Vd is the data voltage output by the data signal line Data, Vth is the threshold voltage of the third transistor M3, the signal of the second reset signal line Reset2 is a low-level signal, the seventh transistor M7 is turned on, and the signal of the second initial signal line INIT2 is written into the fourth node N4 through the turned-on seventh transistor M7, so as to initialize (reset) the first electrode of the light emitting device L, empty the pre-stored voltage inside it and complete the initialization.

In a third stage P3, referred to as a light emitting stage, the signal of the light emitting signal line EM is the low-level signal, the fifth transistor M5 and the sixth transistor M6 are turned on, and a power supply voltage output by the high-level power supply line VDD provides a drive voltage to the first electrode of the light emitting device L through the turned-on fifth transistor M5, the third transistor M3, and the sixth transistor M6, to drive the light emitting device L to emit light.

In a drive process of the pixel drive circuit, a drive current flowing through the third transistor M3 (drive transistor) is determined by a voltage difference between the gate electrode and the first electrode of the third transistor T3. Since the voltage of the first node N1 is Vd−|Vth|, the drive current of the third transistor M3 is as follows:

$$I = K * {( Vgs - Vth )}^{2} = K * {[ ( Vdd - Vd + \vert Vth \vert ) - Vth ]}^{2} = K * {( Vdd - Vd )}^{2}$$

Herein, I is the drive current flowing through the third transistor M3, i.e., a drive current for driving the light emitting device L, K is a constant, Vgs is the voltage difference between the gate electrode and the first electrode of the third transistor M3, Vth is the threshold voltage of the third transistor M3, Vd is the data voltage output by the data signal line Data, and Vdd is the power voltage output by the high-level power supply line VDD.

In an exemplary embodiment, the gate line may include a first gate line and a second gate line, wherein the first gate line may include a first scan signal line and a light emitting signal line, and the second gate line may include a reset signal line and a second scan signal line.

In some exemplary embodiments, the light emitting device may include any one of an organic light emitting diode (OLED), a quantum dot light emitting diode, and an inorganic light emitting diode. For example, the light emitting device may employ a micron-scale light emitting device, such as a Micro Light emitting Diode (Micro LED), a Mini Light emitting Diode (Mini LED), a Micro Organic Light Emitting Diode (Micro OLED), and the like, which are not limited by the embodiments of the present disclosure. For example, taking a case in which the light emitting device L is an organic electroluminescent diode (OLED) as an example, the light emitting device may include a first electrode (for example, as an anode), an organic light emitting layer, and a second electrode (for example, as a cathode) which are stacked.

In an exemplary implementation, the display substrate according to the present disclosure may be applied to a display device with a gate drive circuit, such as an OLED, a quantum dot display (QLED), a light emitting diode display (Micro LED or Mini LED), or a Quantum Dot Light Emitting Diode display (QDLED), etc., which is not limited here in the present disclosure.

In an exemplary embodiment, at least one shift register provided in embodiments of the present disclosure may be electrically connected with a second gate line.

As shown in FIGS. 19 and 20, the display substrate may further include at least one scan control signal line located in the non-display area extending at least partially in the second direction D2. The scan control signal terminals to which all the shift registers are connected are electrically connected with at least one scan control signal line. FIG. 19 illustrates an example of one scan control signal line MSL, and FIG. 20 illustrates an example of four scan control signal lines MSL1 to MSL4.

In an exemplary embodiment, as shown in FIG. 19, when the quantity of scan control signal lines is one, the scan control signal terminals to which all shift registers are connected are electrically connected with the same scan control signal line MSL.

In an exemplary embodiment, as shown in FIG. 20, when the quantity of scan control signal lines is at least two, a scan control signal terminal connected to any of the M*(k−1)+k*M (a−1)+1 stage of shift register to the k*M+k*M (a−1) stage of shift register is electrically connected to the Kth scan control signal line, 1≤k≤K, 1≤a≤N/M, M is the quantity of stages of shift registers to which a scan control signal line is connected, N is the total quantity of stages of shift registers, K is the quantity of scan control signal lines, M≥1.

Exemplarily, when M=7, K=4, a scan control signal terminal connected to a first stage shift register to a seventh stage of shift register is electrically connected with a first scan control signal line MSL1, a scan control signal terminal connected to an eighth stage of shift register to a fourteenth stage of shift register is electrically connected with a second scan control signal line MSL2, a scan control signal terminal connected to a fifteenth stage of shift register to a twenty-first stage of shift register is electrically connected with a third scan control signal line MSL3, a scan control signal terminal connected to a twenty-second stage of shift register to a twenty-eighth stage of shift register is electrically connected with a fourth scan control signal line MSL4, a scan control signal terminal connected to a twenty-ninth stage of shift register to a thirty-fifth stage of shift register is electrically connected with the first scan control signal line MSL1, a scan control signal terminal connected to a thirty-sixth stage of shift register to a forty-second stage of shift register is electrically connected with the second scan control signal line MSL2, a scan control signal terminal connected to a forty-third stage of shift register to a forty-ninth stage of shift register is electrically connected with the third scan control signal line MSL3, and a scan control signal terminal connected to a fiftieth stage of shift register to a fifty-sixth stage of shift register are electrically connected with the fourth scan control signal line MSL4, and so on.

In an exemplary embodiment, a picture displayed on a display substrate comprises a plurality of display frames, and in any display frame, a output signal of a scan output terminal of a shift register is a pulse signal, and the duration H of the pulse signal satisfies the following relational expression;

$$H = L * [ M * K - ( M - 1 ) ] * h$$

where L is the quantity of gate lines connected to any one shift register, h is the unit time and is equal to a refresh interval time of adjacent row sub-pixels.

In an exemplary embodiment, the display area may be divided into a plurality of display sub-areas, at least one display sub-area including at least one gate line. The display modes of any of the display sub-areas include a first display mode and a second display mode, wherein a refresh frequency of the first display mode is greater than that of the second display mode.

In an exemplary embodiment, in a state where the display mode of the display sub-area is the first display mode, for the shift register connected to the gate line in the display sub-area, when a signal at the cascade output terminal is a first level signal, a signal at the scan control signal terminal during at least part of a time period is an active level signal, and a signal at the scan output terminal is a first level signal. In a state where the display mode of the display sub-area is the second display mode, for the shift register connected to the gate line in the display sub-area, when the signal at the cascade output terminal is the first level signal, a signal at the scan control signal terminal is an inactive level signal, and a signal at the scan output terminal is a second level signal. Herein, the voltage value of the first level signal is larger than that of the second level signal, the first level signal is a high-level signal, and the second level signal is a low-level signal.

FIG. 24 is a timing diagram of a plurality of scan outputs of the gate drive circuit provided in FIG. 19. As shown in FIG. 24, in time period t, since a signal of the scan control signal line MSL is a high-level signal, a signal of any output terminal from the scan output terminal NOUT (2) of the second stage of shift register to the scan output terminal NOUT (N−1) of the N−1 stage of shift register is a low-level signal, that is, a pixel drive circuit connected to a gate line connected to a scan output terminal of the second stage of shift register to a scan output terminal of the N−1 stage of shift register does not initialize and write data, thus achieving low-frequency display and low-power display of the display product.

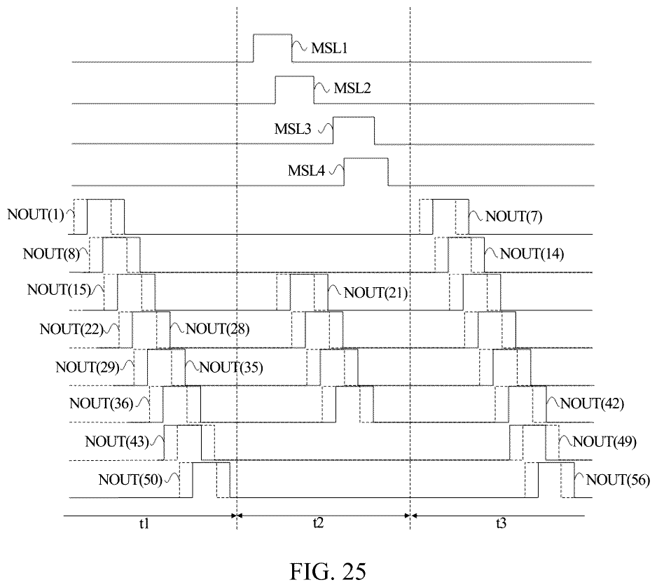

FIG. 25 is a timing diagram of a plurality of scan outputs of the gate drive circuit provided in FIG. 20. As shown in FIG. 25, in time periods t1 and t3, the signals of the first scan control signal line MSL1 to the fourth scan control signal line MSL4 are low-level signals, and at this time, the scan output terminals of all shift registers sequentially output high-level signals.

As shown in FIG. 25, in time period t2, the signal of the first scan control signal line MSL1 is a high-level signal during a part of the time period such that the scan output terminals of the first stage of shift register and the seventh stage of shift register output low-level signals, and the time period in which the signal of the first scan control signal line MSL1 is a high-level signal is from a start time when the signal of the first stage of shift register cascade output terminal is a high-level signal to an end time when the signal of the seventh stage of shift register cascade output terminal is a high-level signal.

As shown in FIG. 25, in time period t2, the signal of the second scan control signal line MSL2 is a high-level signal during a part of the time period such that the scan output terminals of the eighth shift register and the fourteenth shift register output low-level signals, and the time period in which the signal of the second scan control signal line MSL2 is a high-level signal is from a start time when the signal of the eighth shift register cascade output terminal is a high-level signal to an end time when the signal of the fourteenth shift register cascade output terminal is a high-level signal.

As shown in FIG. 25, in time period t2, the signal of the third scan control signal line MSL3 is a high-level signal during a part of the time period such that the scan output terminals of the forty-third shift register and the forty-ninth shift register output low-level signals, and the time period in which the signal of the third scan control signal line MSL3 is a high-level signal is from a start time when the signal at the forty-third shift register cascade output terminal is a high-level signal to an end time when the signal at the forty-ninth shift register cascade output terminal is a high-level signal.

As shown in FIG. 25, in time period t2, the time period in which the signal of the fourth scan control signal line MSL4 is a high-level signal is from a start time when the signal at the fiftieth shift register cascade output terminal is a high-level signal to an end time when the signal at the fifty-sixth shift register cascade output terminal is a high-level signal, and the time period in which the signal the fourth scan control signal line MSL4 is a high-level signal is from a start time when the signal at the fiftieth shift register cascade output terminal is a high-level signal to an end time when the signal at the fifty-sixth shift register cascade output terminal is a high-level signal.

FIG. 26 is a partial schematic diagram showing a non-display area of a display substrate. As shown in FIGS. 19, 20, and 26, the display substrate may further include a first clock signal line CLK1, a second clock signal line CLK2, a first power supply line VGH, a second power supply line VGL, and a third power supply line VCX located in a non-display area. The shift register in FIG. 26 is the shift register provided in FIG. 11, and FIG. 26 is illustrated with a scan control signal line as an example.

In an exemplary embodiment, any one of the first clock signal line CLK1, the second clock signal line CLK2, the first power supply line VGH, the second power supply line VGL, and the third power supply line VCX extends at least partially in a second direction D2.

In an exemplary embodiment, the first clock signal terminal to which any stage of shift register is connected is electrically connected with one of the first clock signal lines CLK1 and the second clock signal line CLK2, the second clock signal terminal to which any stage of shift register is connected is electrically connected with the other of the first clock signal lines CLK1 and the second clock signal line CLK2, the clock signal lines to which the first clock signal terminals to which adjacent shift registers are connected are different, the clock signal lines to which the second clock signal terminals to which adjacent shift registers are connected are different, the first power supply terminals to which all shift registers are connected are electrically connected with the first power supply line VGH, the second power supply terminals to which all shift registers are connected are electrically connected with the second power supply line VGL, and the third power supply terminals to which all shift registers are connected are electrically connected with the third power supply line VCX.

In an exemplary embodiment, the display substrate may further include an initial signal line located in a non-display area, and a signal input of at least one stage of shift register is electrically connected with the initial signal line. The initial signal line may extend in the second direction and may be located on a side of the first clock signal line away from the display area.

In an exemplary embodiment, as shown in FIGS. 19, 20, and 25, the scan control signal line MSL may be located on a side near the display area of any one of the first clock signal line CLK1, the second clock signal line CLK2, the first power supply line VGH, the second power supply line VGL, and the third power supply line VCX.

In the exemplary embodiment, as shown in FIG. 25, the quantity of second power supply lines VGL is two, and the first clock signal line CLK1, the second clock signal line CLK2, the first one of second power lines VGL, the third power line VCX, the second one of second power lines VGL, and the first power line VGH are sequentially arranged in a direction close to the display area.

In an exemplary embodiment, as shown in FIG. 25, the shift register may include a seventeenth transistor T17 to a nineteenth transistor T19; the Seventeenth transistor T17 to the nineteenth transistor T19 may be arranged in the second direction D2.

In an exemplary embodiment, as shown in FIG. 25, at least part of any one of the seventeenth transistor T17 to the nineteenth transistor T19 is located between the first power supply line VGH and the scan control signal line MSL.

In an exemplary embodiment, any transistor includes an active pattern, and FIG. 27 is a schematic diagram of the active patterns of the seventeenth transistor T17 to the nineteenth transistor T19. As shown in FIG. 27, the average length of the active pattern 171 of the seventeenth transistor in the first direction D1 is less than the average length of any one of the active pattern 181 of the eighteenth transistor and the active pattern 191 of the nineteenth transistor in the first direction D1.

In an exemplary embodiment, as shown in FIG. 25, a line width of either of the first power line VGH and the second power line VGL may be greater than a line width of the scan control signal line MSL.

Exemplary description is made below through a manufacturing process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B. FIGS. 11 to 18 are illustrated by taking the display substrate including the shift register provided in FIG. 8, that is, the shift register including the first transistor T1 through the eighth transistor T8 and the tenth transistor T10, as an example.

(1) A pattern of a semiconductor layer is formed on a base substrate.

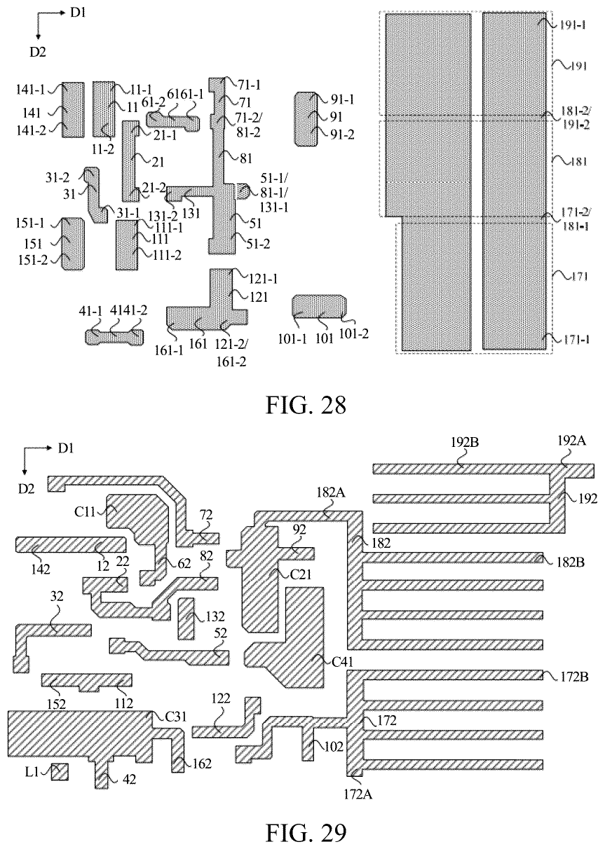

In an exemplary embodiment, forming a semiconductor layer pattern on a base substrate may include: depositing a semiconductor thin film on the base substrate, patterning the semiconductor thin film by a patterning process, and forming a semiconductor layer pattern. As shown in FIG. 28, FIG. 28 is a schematic diagram after the semiconductor layer patterns are formed in FIG. 26.

In an exemplary embodiment, as shown in FIG. 28, the semiconductor layer pattern of each shift register may include at least an active pattern 11 of a first transistor to an active pattern 191 of a nineteenth transistor.

In an exemplary embodiment, as shown in FIG. 28, an active pattern 51 of a fifth transistor, an active pattern 71 of a seventh transistor, an active pattern 81 of an eighth transistor and an active pattern 131 of a thirteenth transistor are in an integral structure, an active pattern 121 of a twelfth transistor and an active pattern 161 of a sixteenth transistor are in an integral structure, an active pattern 171 of a seventeenth transistor, an active pattern 181 of an eighteenth transistor and an active pattern 191 of a nineteenth transistor are in an integral structure, and an active pattern 11 of a first transistor, an active pattern 21 of a second transistor, an active pattern 31 of a third transistor, an active pattern 41 of a fourth transistor, an active pattern 61 of a sixth transistor, an active pattern 91 of a ninth transistor, an active pattern 101 of a tenth transistor, an active pattern 111 of an eleventh transistor, an active pattern 141 of a fourteenth transistor and an active pattern 151 of a fifteenth transistor are separately provided.

In the exemplary embodiment, as shown in FIG. 28, the active pattern 11 of the first transistor and the active pattern 141 of the fourteen transistor are arranged in a first direction D1, and the active pattern 11 of the first transistor is located on the side of the active pattern 141 of the fourteen transistor near the display area, and the active pattern 21 of the second transistor is located on the side of the active pattern 11 of the first transistor near the display area. The active pattern 31 of the third transistor and the active pattern 11 of the first transistor are arranged in a second direction D2, and in the same stage of shift register the active pattern 31 of the third transistor is located on the side of the active pattern 11 of the first transistor near the next stage of shift register, the active pattern 111 of the eleventh transistor and the active pattern 151 of the fifteenth transistor are arranged in the first direction D1, the active pattern 111 of the eleventh transistor and the active pattern 11 of the first transistor are arranged in the second direction D2, the active pattern 151 of the fifteenth transistor and the active pattern 141 of the fourteenth transistor are arranged in the second direction D2, the active pattern 111 of the eleventh transistor is located on the side of the fifteenth transistor near the display area, and in the same stage of shift register the active pattern 111 of the eleventh transistor of the shift register is located on the side of the active pattern 31 of the third transistor near the next stage of shift register. In the same stage of shift register, the active pattern 41 of the fourth transistor of the shift register is located on the side of the active pattern 111 of the eleventh transistor near the next stage of shift register. The active pattern 61 of the sixth transistor is located on the side of the active pattern 21 of the second transistor near the display area. The active pattern 71 of the seventh transistor is located on the side of the active pattern 61 of the sixth transistor near the display area, the active pattern 81 of the eighth transistor and the active pattern 131 of the thirteenth transistor are located on the side of the active pattern 21 of the second transistor near the display area, and the active pattern 131 of the thirteenth transistor is located on the side of the active pattern 81 of the eighth transistor away from the display area, the active pattern 51 of the fifth transistor is located on the side of the active pattern 111 of the eleventh transistor near the display area, the active pattern 71 of the seventh transistor, the active pattern 81 of the eighth transistor and the active pattern 51 of the fifth transistor are arranged in the second direction D2, and in the same stage of shift register the active pattern 71 of the seventh transistor of the shift register is located on the side of the active pattern 81 of the eighth transistor near the upper stage of shift register, and in the same stage of shift register the active pattern 51 of the fifth transistor is located on the side of the active pattern 81 of the eighth transistor near the next stage of shift register. The active pattern 161 of the sixteenth transistor is located on the side of the active pattern 41 of the fourth transistor near the display area, the active pattern 121 of the twelfth transistor is located on the side of the active pattern 161 of the sixteenth transistor near the display area, the active pattern 51 of the fifth transistor and the active pattern 121 of the twelfth transistor are arranged in the second direction D2, and in the same stage of shift register the active pattern 121 of the twelfth transistor is located on the side of the active pattern 51 of the fifth transistor near the next stage of shift register. The active pattern 91 of the ninth transistor is located on the side of the active pattern 71 of the seventh transistor near the display area, the active pattern 101 of the tenth transistor is located on the side of the active pattern 161 of the sixteenth transistor near the display area, the active pattern 91 of the ninth transistor and the active pattern 101 of the tenth transistor are arranged in the second direction D2, and in the same stage of shift register the active pattern 91 of the ninth transistor may be located on the side of the active pattern 101 of the tenth transistor near the upper stage of shift register. The active pattern 171 of the seventeenth transistor (also the active pattern 181 of the eighteenth transistor and the active pattern 191 of the nineteenth transistor) is located on the sides of the active pattern 91 of the ninth transistor and the active pattern 101 of the tenth transistor near the display area, and the active patterns 171 of the seventeenth transistor to the active patterns 191 of the ninth transistor are arranged in the second direction D2. In the same stage of shift register the active pattern 171 of the seventeenth transistor is located on the side of the active pattern 181 of the eighteenth transistor near the next stage of shift register, and in the same stage of shift register the active pattern 191 of the nineteenth transistor is located on the side of the active pattern 181 of the eighteenth transistor near the upper stage of shift register.

In an exemplary embodiment, as shown in FIG. 28, any one of the active pattern 11 of the first transistor, the active pattern 21 of the second transistor, the active pattern 31 of the third transistor, the active pattern 51 of the fifth transistor, 71 of the seventh transistor, the active pattern 81 of the eighth transistor, the active pattern 91 of the ninth transistor, the active pattern 111 of the eleventh transistor, the active pattern 121 of the twelfth transistor, the active pattern 141 of the fourteenth transistor, the active pattern 151 of the fifteenth transistor, the active pattern 171 of the seventeenth transistor, the active pattern 181 of the eighteenth transistor and the active pattern 191 of the nineteenth transistor has a strip shape and extends in the second direction D2.

In an exemplary embodiment, as shown in FIG. 28, any one of the active pattern 41 of the fourth transistor, the active pattern 61 of the sixth transistor, the active pattern 101 of the tenth transistor, the active pattern 131 of the thirteenth transistor, and the active pattern 161 of the sixteenth transistor has a strip shape and extends in the first direction D1.

In an exemplary embodiment, as shown in FIG. 28, the integral structure of the active pattern 121 of the twelfth transistor and the active pattern 161 of the sixteenth transistor is in an inverted “T” shape, the integral structure of the active pattern 51 of the fifth transistor, the active pattern 71 of the seventh transistor, the active pattern 81 of the eighth transistor, and the active pattern 131 of the thirteenth transistor may be in a “ [symbol] ” shape, and the integral structure of the active pattern 171 of the seventeenth transistor, the active pattern 181 of the eighteenth transistor, and the active pattern 191 of the nineteenth transistor is in a strip shape and extends in the second direction D2.

In an exemplary embodiment, as shown in FIG. 28, the average length of the active pattern 171 of the seventeenth transistor in the first direction D1 is less than the average length of any one of the active pattern 181 of the eighteenth transistor and the active pattern 191 of the nineteenth transistor in the first direction D1.

In an exemplary embodiment, as shown in FIG. 28, an active pattern of each transistor may include a first region, a second region and a channel region between the first region and the second region. In an exemplary embodiment, a first region 51-1 of the active pattern 51 of the fifth transistor may be a first region 81-1 of the active pattern 81 of the eighth transistor and a first region 131-1 of the active pattern 131 of the thirteenth transistor, a second region 71-2 of the active pattern 71 of the seventh transistor may be a second region 81-2 of the active pattern 81 of the eighth transistor, a second region 121-2 of the active pattern 121 of the twelfth transistor may be a second region 161-2 of the active pattern 161 of the sixteenth transistor, a second region 171-2 of the active pattern 171 of the seventeenth transistor may be a first region 181-1 of the active pattern 181 of the eighteenth transistor, and a second region 181-2 of the active pattern 181 of the eighteenth transistor may be a first region 191-2 of the active pattern 191 of the nineteenth transistor. A first region 11-1 and a second region 11-2 of the active pattern 11 of the first transistor, a first region 21-1 and a second region 21-2 of the active pattern 21 of the second transistor, a first region 31-1 and a second region 31-2 of the active pattern 31 of the third transistor, a first region 41-1 and a second region 41-2 of the active pattern 41 of the fourth transistor, a second region 51-2 of the active pattern 51 of the fifth transistor, a first region 61-1 and a second region 61-2 of the active pattern 61 of the sixth transistor, a first region 71-1 of the active pattern 71 of the seventh transistor, a first region 91-1 and a second region 91-2 of the active pattern 91 of the ninth transistor, a first region 101-1 and a second region 101-2 of the active pattern 101 of the tenth transistor, a first region 111-1 and a second region 111-2 of the active pattern 111 of the eleventh transistor, a first region 121-1 of the active pattern 121 of the twelve transistor, a second region 131-2 of the active pattern 131 of the thirteenth transistor, a first region 141-1 and a second region 141-2 of the active pattern 141 of the fourteenth transistor, a first region 151-1 and a second region 151-2 of the active pattern 151 of the fifteenth transistor, a first region 161-1 of the active pattern 161 of the sixteenth transistor, a first region 171-1 of the active pattern 171 of the seventeenth transistor, and a first region 191-1 of the active pattern 191 of the nineteenth transistor are separately provided.

(2) A pattern of a first conductive layer is formed.

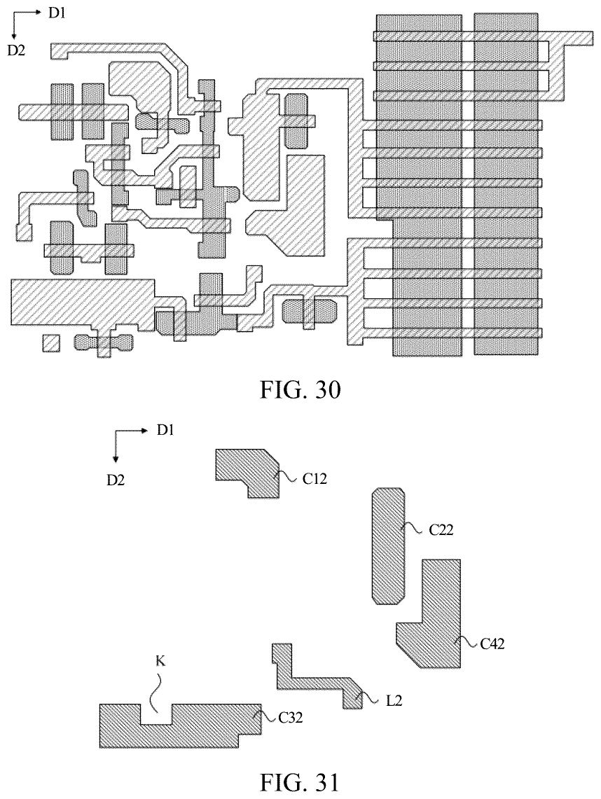

In an exemplary embodiment, forming a pattern of a first conductive layer may include: depositing a first insulating film and a first conductive film on a base substrate on which the pattern is formed, patterning the first conductive film by a patterning process, forming the first insulation layer covering the semiconductor layer pattern, and disposing the pattern of the first conductive layer on the first insulation layer, as shown in FIGS. 29 and 30, wherein FIG. 29 is a schematic diagram of the pattern of the first conductive layer in FIG. 26, and FIG. 30 is a schematic diagram after the pattern of the first conductive layer is formed in FIG. 26. In an exemplary embodiment, the first conductive layer may be referred to as a first gate metal (GATE1) layer.

In an exemplary embodiment, as shown in FIGS. 29 and 30, the pattern of the first conductive layer of each shift register may include at least a gate electrode 12 of a first transistor to a gate electrode 192 of a nineteenth transistor, a first plate C11 of a first capacitor to a first plate C41 of a fourth capacitor, and a first connection portion L1.

In the exemplary embodiment, as shown in FIGS. 29 and 30, the gate electrode 12 of the first transistor and the gate electrode 142 of the fourteenth transistor are in an integral structure, and the integral structure of the gate electrode 12 of the first transistor and the gate electrode 142 of the fourteenth transistor has a strip shape and extends in the first direction D1.

In the exemplary embodiment, as shown in FIGS. 29 and 30, the gate electrode 22 of the second transistor and the gate electrode 82 of the eighth transistor are in an integral structure. The gate electrode 22 of the second transistor may has a “n” shape with an opening facing the display area, and the gate electrode 82 of the eighth transistor may has a polyline shape and extends at least partially in the first direction D1.

In an exemplary embodiment, as shown in FIGS. 29 and 30, the gate electrode 32 of the third transistor is individually provided, and its shape may be a “ [symbol] ” shape.

In the exemplary embodiment, as shown in FIGS. 29 and 30, the gate electrode 42 of the fourth transistor, the gate electrode 162 of the sixteenth transistor and the C31 of the third capacitor are an integral structure. The shape of C31 of the third capacitor is rectangular. In the same stage of shift register the gate electrode 42 of the fourth transistor is located on the side of the third capacitor C31 near the next stage of shift register, and the gate electrode 42 of the fourth transistor has a strip shape and extends in the second direction D2. The gate electrode 162 of the sixteenth transistor is located on the side of the third capacitor C31 near the display area, and the gate electrode 162 of the sixteenth transistor has a “ [symbol] ” shape

In an exemplary embodiment, as shown in FIGS. 29 and 30, the gate electrode 52 of the fifth transistor is individually provided. The gate electrode 52 of the fifth transistor has a polyline shape and extends at least partially in the first direction D1.

In the exemplary embodiment, as shown in FIGS. 29 and 30, the gate electrode 62 of the sixth transistor and the first plate C11 of the first capacitor are an integral structure. In the same stage of shift register the gate electrode 62 of the sixth transistor is located on the side of the first plate C11 of the first capacitor near the next stage of shift register. The first plate C11 of the first capacitor may have a “ [symbol] ” shape. The gate electrode 62 of the sixth transistor has a polyline shape and extends at least partially in the second direction D2.

In an exemplary embodiment, as shown in FIGS. 29 and 30, the gate electrode 72 of the seventh transistor is individually provided. The gate electrode 72 of the seventh transistor has a polyline shape and extends at least partially in the first direction D1.

In the exemplary embodiment, as shown in FIGS. 29 and 30, the gate electrode 92 of the ninth transistor, the gate electrode 182 of the eighteenth transistor, and the first plate C21 of the second capacitor are in an integral structure. The gate electrode 92 of the ninth transistor and the gate electrode 182 of the eighteenth transistor are both located on the side of the first plate C21 of the second capacitor near the display area, the gate electrode 92 of the ninth transistor is connected to the first plate C21 of the second capacitor near the boundary of the display area, and in the same stage of shift register the gate electrode 182 of the eighteenth transistor is connected to the first plate C21 of the second capacitor near the boundary of the upper stage of shift register. The shape of the first plate C21 of the second capacitor may be a rectangular shape, and the corners of the rectangular shape may be chamfered. The gate electrode 92 of the ninth transistor has a strip shape and extends in the first direction D1. The gate electrode 182 of the eighteenth transistor includes a first connection section 182A and at least one first branch section 182B, wherein the first plate C21 of the second capacitor is located on the side of the first connection section 182A away from the display area, the first branch section 182B is located on the side of the first connection section 182A near the display area, and the first connection section 182A is electrically connected with the first plate C21 of the second capacitor and at least one first branch section 182B, respectively. The gate electrode 182 of the eighteenth transistor may have a comb-shaped structure. The first connection section 182A may have a “ [symbol] ” shape, which is equivalent to a “comb back”, the first branch section 182B may have a strip shape and extend in the first direction D1, which is equivalent to a “comb tooth”, and at least one first branch section 182B is arranged in the second direction D2.

In the exemplary embodiment, as shown in FIGS. 29 and 30, the gate electrode 102 of the tenth transistor and the gate electrode 172 of the seventeenth transistor are in an integral structure. The gate electrode 102 of the tenth transistor may have an “F” shape rotated to the left, and the gate electrode 172 of the seventeenth transistor may include a second connection section 172A and at least one second branch section 172B. The second branch section 172B is located on the side of the second connection section 172A near the display area. The gate electrode 172 of the seventeenth transistor has a comb-shaped structure, the second connection section 172A extends in the second direction D2 which is equivalent to a “comb back”, the second branch section 172B extends in the first direction D1 which is equivalent to a “comb tooth”, and at least one second branch section 172B is arranged in the second direction D2.

In the exemplary embodiment, as shown in FIGS. 29 and 30, the gate electrode 112 of the eleventh transistor and the gate electrode 152 of the fifteenth transistor are in an integral structure, and the integral structure of the gate electrode 112 of the eleventh transistor and the gate electrode 152 of the fifteenth transistor has a strip shape and extends in the first direction D1.

In an exemplary embodiment, as shown in FIGS. 29 and 30, the gate electrode 122 of the twelfth transistor is individually provided, and the shape may be a “ [symbol] ” shape.

In an exemplary embodiment, as shown in FIGS. 29 and 30, the gate electrode 132 of the thirteenth transistor is individually provided. The gate electrode 132 of the thirteenth transistor has a strip shape and extends in the second direction D2.

In an exemplary embodiment, as shown in FIGS. 29 and 30, the gate electrode 192 of the nineteenth transistor is individually provided. The gate electrode 192 of the nineteenth transistor includes a third connection section 192A and at least one third branch section 192B. The third branch section 192B is located on the side of the third connection section 192A away from the display area. The gate electrode 192 of the nineteenth transistor may have a comb-shaped structure, the third connection section 192A may have a “ [symbol] ” shape which is equivalent to a “comb back”, the third branch section 192B has a strip shape and extends in the first direction D1 which is equivalent to a “comb tooth”, and at least one third branch section 192B is arranged in the second direction D2.

In an exemplary embodiment, as shown in FIGS. 29 and 30, the first plate C41 of the fourth capacitor is individually provided and is located between the gate electrode 52 of the fifth transistor and the gate electrode 182 of the eighteenth transistor. The first plate C41 of the fourth capacitor includes a main body portion which may have a rectangular shape and a convex portion which is located on a side of the main body portion away from the display area. In the exemplary embodiment, as shown in FIGS. 29 and 30, the first connection portion L1 is individually provided and has a block shape. The first connection portion L1 is located on the side of the gate electrode 42 of the fourth transistor away from the display area, and in the same stage of shift register the first plate C31 of the third capacitor is near the side of the next stage of shift register.

In an exemplary embodiment, as shown in FIGS. 29 and 30, a gate electrode 12 of the first transistor is provided across an active pattern of the first transistor, a gate electrode 22 of the second transistor is provided across an active pattern of the second transistor, a gate electrode 32 of the third transistor is provided across an active pattern of the third transistor, a gate electrode 42 of the fourth transistor is provided across an active pattern of the fourth transistor, a gate electrode 52 of the fifth transistor is provided across an active pattern of the fifth transistor, a gate electrode 62 of the sixth transistor is provided across an active pattern of the sixth transistor, a gate electrode 72 of the seventh transistor is provided across an active pattern of the seventh transistor, a gate electrode 82 of the eighth transistor is provided across an active pattern of the eighth transistor, a gate electrode 92 of the ninth transistor is provided across an active pattern of the ninth transistor, a gate electrode 102 of the tenth transistor is provided across an active pattern of the tenth transistor, a gate electrode 112 of the eleventh transistor is provided across an active pattern of the eleventh transistor, a gate electrode 122 of the twelfth transistor is provided across an active pattern of the twelfth transistor, a gate electrode 132 of the thirteenth transistor is provided across an active pattern of the thirteenth transistor, a gate electrode 142 of the fourteenth transistor is provided across an active pattern of the fourteenth transistor, a gate electrode 152 of the fifteenth transistor is provided across an active pattern of the fifteenth transistor, a gate electrode 162 of the sixteenth transistor is provided across an active pattern of the fifteenth transistor, at least one second branch section 172B of gate electrode 172 of the seventeenth transistor is provided across an active pattern of the seventeenth transistor, at least one first branch section 182B of gate electrode 182 of the eighteenth transistor is provided across an active pattern of the eighteenth transistor, at least one third section 192B is provided across an active pattern of the nineteenth transistor, that is, the extension direction of a control electrode of at least one transistor and the extension direction of the active pattern are perpendicular to each other.

In an exemplary implementation, after the pattern of the first conductive layer is formed, a conductive treatment may be performed on the semiconductor layer by using the first conductive layer as a shield. A region of the semiconductor layer, which is shielded by the first conductive layer, forms channel regions of the first transistor to the nineteenth transistor, and a region of the semiconductor layer, which is not shielded by the first conductive layer, is made to be conductive, that is, first regions and second regions of the first transistor to the nineteenth transistor are all made to be conductive. As shown in FIG. 30, the first connection portion L1 in the present disclosure is processed into a conductive layer, to form a conductive first connection portion L1.

(3) A pattern of a second conductive layer is formed.

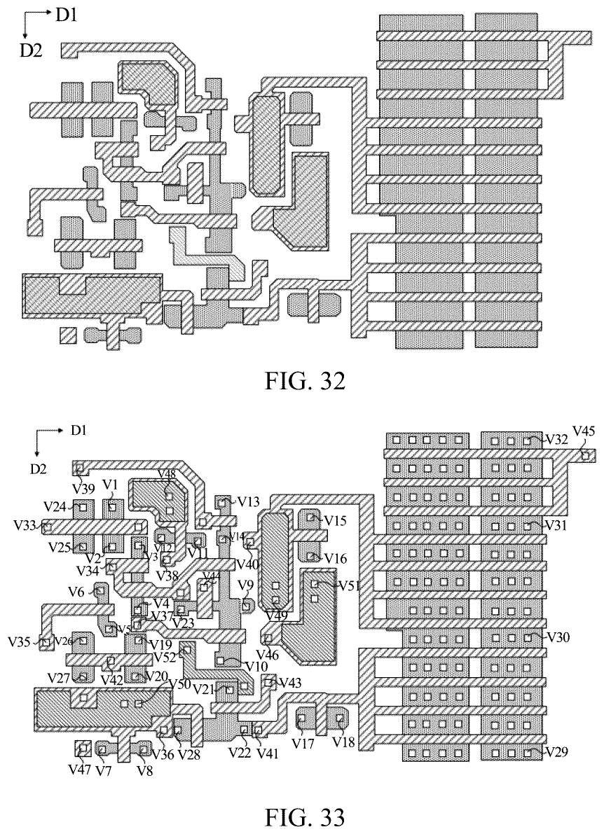

In an exemplary embodiment, forming a pattern of a second conductive layer may include depositing a second insulating film and a second conductive film on a base substrate on which the pattern is formed, patterning the second conductive film by a patterning process, forming a pattern of a second insulation layer covering the pattern of the first conductive layer and the pattern of the second conductive layer on the pattern of the second insulation layer, as shown in FIGS. 31 and 32, FIG. 31 is a schematic diagram of the pattern of the second conductive layer in FIG. 26, and FIG. 32 is a schematic diagram after forming the pattern of the second conductive layer in FIG. 26. In an exemplary embodiment, the second conductive layer may be referred to as a second gate metal (GATE2) layer.

In an exemplary embodiment, as shown in FIGS. 31 and 32, the pattern of the second conductive layer may include at least a second plate C12 of the first capacitor to a second plate C42 of the fourth capacitor and a second connection portion L2 located in each of the shift registers.

In an exemplary embodiment, as shown in FIGS. 31 and 32, an orthographic projection of the second plate C12 of the first capacitor on the base substrate overlaps at least partially an orthographic projection of the first plate of the first capacitor on the base substrate. The area of the second plate C12 of the first capacitor is smaller than the area of the first plate of the first capacitor. The shape of the second plate C12 of the first capacitor is the same as that of the first plate of the first capacitor.

In an exemplary embodiment, as shown in FIGS. 31 and 32, an orthographic projection of the second plate C22 of the second capacitor on the base substrate overlaps at least partially an orthographic projection of the first plate of the second capacitor on the base substrate. The area of the second plate C22 of the second capacitor is smaller than the area of the first plate of the second capacitor. The shape of the second plate C22 of the second capacitor may be a rectangular shape, and the corners of the rectangular shape may be chamfered and extend in the second direction D2.

In an exemplary embodiment, as shown in FIGS. 31 and 32, an orthographic projection of the second plate C32 of the third capacitor on the base substrate overlaps at least partially an orthographic projection of the first plate of the third capacitor on the base substrate. The area of the second plate C32 of the third capacitor is smaller than the area of the first plate of the third capacitor. The shape of the second plate C32 of the third capacitor may be rectangular. The second plate C32 of the third capacitor is provided with a groove K near the boundary of the second plate C32 adjacent to the first capacitor, an orthographic projection of the groove K on the base substrate overlapping at least partially an orthographic projection of the first plate of the third capacitor on the base substrate and exposing the first plate of the third capacitor.

In an exemplary embodiment, as shown in FIGS. 31 and 32, an orthographic projection of the second plate C42 of the fourth capacitor on the base substrate overlaps at least partially an orthographic projection of the first plate of the fourth capacitor on the base substrate. The second plate C42 of the fourth capacitor has the same shape as the first plate C41 of the fourth capacitor, and the area of the second plate C42 of the fourth capacitor is less than the area of the first plate of the fourth capacitor.

In the exemplary embodiment, as shown in FIGS. 31 and 32, the second connection portion L2 is located between the second plate C32 of the third capacitor and the second plate C22 of the second capacitor, and in the same shift register the second connection portion L2 is located on the side of the first capacitor C12 near the next stage of shift register. The second connection portion L2 has a polyline shape and extends at least partially in the first direction D1.

(4) A pattern of a third insulation layer is formed.

In an exemplary embodiment, forming a pattern of a third insulation layer may include depositing a third insulating film on a base substrate on which the pattern is formed, and patterning the third insulating film by a patterning process to form a pattern of a third insulation layer covering the structure, wherein the third insulation layer is provided with a plurality of via patterns, as shown in FIG. 33, which is a schematic diagram after forming the third insulation layer pattern in FIG. 26.

In an exemplary embodiment, as shown in FIG. 33, the pattern of the third insulation layer of each shift register may include at least a first via V1 to a fifty-first via V51.

In an exemplary embodiment, as shown in FIG. 33, an orthographic projection of the first via V1 on the base substrate is located within a range of an orthographic projection of the first region of the active pattern of the first transistor on the base substrate. The first insulation layer, the second insulation layer and the third insulation layer within the first via V1 are etched away to expose the surface of the first region of the active pattern of the first transistor, and the first via V1 is configured such that the first electrode of the first transistor (also the first electrode of the fourteenth transistor) formed subsequently is connected to the first region of the active pattern of the first transistor through the first via V1.

In an exemplary embodiment, an orthographic projection of the second via V2 on the base substrate is located within a range of an orthographic projection of the second region of the active pattern of the first transistor on the base substrate. The first insulation layer, the second insulation layer and the third insulation layer in the second via V2 are etched away to expose a surface of the second region of the active pattern of the first transistor, and the second via V2 is configured such that a second electrode of the first transistor to be formed subsequently is connected to the second region of the active pattern of the first transistor through the second via V2.

In an exemplary embodiment, an orthographic projection of the third via V3 on the base substrate is located within a range of an orthographic projection of the first region of the active pattern of the second transistor on the base substrate. The first insulation layer, the second insulation layer and the third insulation layer in the third via V3 are etched away to expose a surface of the first region of the active pattern of the second transistor, and the third via V3 is configured such that a first electrode of the second transistor to be formed subsequently is connected to the first region of the active pattern of the second transistor through the third via V3.

In an exemplary embodiment, as shown in FIG. 33, an orthographic projection of the fourth via V4 on the base substrate is located within a range of an orthographic projection of the second region of the active pattern of the second transistor on the base substrate. The first insulation layer, the second insulation layer and the third insulation layer within the fourth via V4 are etched away to expose the surface of the second region of the active pattern of the second transistor, and the fourth via V4 is configured such that a second electrode of the second transistor (also the second electrode of the third transistor and the first electrode of the eleventh transistor) to be formed subsequently is connected to the second region of the active pattern of the second transistor through the fourth via V4.

In an exemplary embodiment, as shown in FIG. 33, an orthographic projection of the fifth via V5 on the base substrate is located within a range of an orthographic projection of a first region of the active pattern of the third transistor on the base substrate, the fourth insulation layer. The first insulation layer, the second insulation layer and the third insulation layer within the fifth via V5 are etched away to expose a surface of a first region of the active pattern of the third transistor, and the fifth via V5 is configured such that a first electrode of the third transistor formed subsequently is connected with the first region of the active pattern of the third transistor through the fifth via V5.

In an exemplary embodiment, as shown in FIG. 33, an orthographic projection of the sixth via V6 on the base substrate is located within a range of an orthographic projection of the second region of the active pattern of the third transistor on the base substrate. The first insulation layer, the second insulation layer and the third insulation layer within the sixth via V6 are etched away to expose the surface of the second region of the active pattern of the third transistor, and the sixth via V6 is configured such that the second electrode of the second transistor (also the second electrode of the third transistor and the first electrode of the eleventh transistor) formed subsequently is connected to the second region of the active pattern of the third transistor through the sixth via V6.

In an exemplary embodiment, as shown in FIG. 33, an orthographic projection of the seventh via V7 on the base substrate is located within a range of an orthographic projection of the first region of the active pattern of the fourth transistor on the base substrate. The first insulation layer, the second insulation layer and the third insulation layer within the seventh via V7 are etched away to expose the surface of the first region of the active pattern of the fourth transistor, and the seventh via V7 is configured such that the first electrode of the fourth transistor formed subsequently is connected to the first region of the active pattern of the fourth transistor through the seventh via V7.

In an exemplary embodiment, as shown in FIG. 33, an orthographic projection of the eighth via V8 on the base substrate is located within a range of an orthographic projection of a second region of the active pattern of the fourth transistor on the base substrate. The first insulation layer, the second insulation layer, the third insulation layer within the eighth via V8 are etched away to expose a surface of the second region of the active pattern of the fourth transistor, and the eighth via V8 is configured such that a second electrode of the fourth transistor (also the second electrode of the fifth transistor) formed subsequently is connected to the second region of the active pattern of the fourth transistor through the eighth via H8.

In an exemplary embodiment, as shown in FIG. 33, an orthographic projection of the ninth via V9 on the base substrate is located within a range of an orthographic projection of the first region of the active pattern of the fifth transistor (also the first region of the active pattern of the eighth transistor and the first region of the active pattern of the thirteenth transistor) on the base substrate. The first insulation layer, the second insulation layer and the third insulation layer within the ninth via V9 are etched away to expose the surface of the second region of the active pattern of the fourth transistor, and the ninth via V9 is configured such that the first electrode of the fifth transistor (also the first electrode of the eighth transistor, the first electrode of the ninth transistor and the first electrode of the thirteenth transistor) subsequently formed is connected to the first region of the active pattern of the fifth transistor (also the first region of the active pattern of the eighth transistor and the first region of the active pattern of the thirteenth transistor) through the ninth via V9.

In an exemplary implementation, as shown in FIG. 33, an orthographic projection of the tenth via V10 on the base substrate is located within a range of an orthographic projection of a second region of the active pattern of the fifth transistor on the base substrate. The first insulation layer, the second insulation layer and the third insulation layer within the tenth via V10 is etched away to expose a surface of the second region of the active pattern of the fifth transistor, and the tenth via V10 is configured such that a second electrode of the fourth transistor (also the second electrode of the fifth transistor) formed subsequently is connected to the second region of the active pattern of the fifth transistor through the tenth via V10.

In an exemplary implementation, as shown in FIG. 33, an orthographic projection of the eleventh via V11 on the base substrate is located within a range of an orthographic projection of a first region of the active pattern of the sixth transistor on the base substrate. The first insulation layer, the second insulation layer and the third insulation layer within the eleventh via V11 are etched away to expose a surface of the first region of the active pattern of the fourth transistor, and the eleventh via V11 is configured such that a first electrode of the sixth transistor formed subsequently is connected to the first region of the active pattern of the sixth transistor through the eleventh via V11.

In an exemplary implementation, as shown in FIG. 33, an orthographic projection of the twelfth via V12 on the base substrate is located within a range of an orthographic projection of a second region of the active pattern of the sixth transistor on the base substrate. The first insulation layer, the second insulation layer and the third insulation layer within the twelfth via V12 is etched away to expose a surface of the second region of the active pattern of the sixth transistor, and the twelfth via V12 is configured such that a second electrode of the sixth transistor formed subsequently is connected to the second region of the active pattern of the sixth transistor through the twelfth via V12.

In an exemplary embodiment, as shown in FIGS. 33, an orthographic projection of the thirteen via V13 on the base substrate is located within a range of an orthographic projection of a first region of the active pattern of the fourth transistor T4 on the base substrate, the first insulation layer and the second insulation layer within the third via V13 are etched away to expose a surface of the first region of the active pattern of the fourth transistor T4, and the third via V13 is configured such that a first electrode of the fourth transistor formed subsequently is connected to the first region of the active pattern of the fourth transistor T4 through the via.

In an exemplary embodiment, as shown in FIG. 33, an orthographic projection of the fourteenth via V14 on the base substrate is located within a range of an orthographic projection of the second region of the active pattern of the seventh transistor (also the second region of the active pattern of the eighth transistor) on the base substrate. The first insulation layer, the second insulation layer and the third insulation layer within the fourteenth via V14 are etched away to expose the surface of the second region of the active pattern of the seventh transistor (also the second region of the active pattern of the eighth transistor), and the fourteenth via V14 is configured such that the second electrode of the seventh transistor (also the second electrode of the eighth transistor) formed subsequently is connected to the second region of the active pattern of the seventh transistor (also the second region of the active pattern of the eighth transistor) through the fourteenth via V14.

In an exemplary embodiment, as shown in FIG. 33, an orthographic projection of the fifteenth via V15 on the base substrate is located within a range of an orthographic projection of the first region of the active pattern of the ninth transistor on the base substrate. The first insulation layer, the second insulation layer and the third insulation layer within the fifteenth via V15 are etched away to expose the surface of the first region of the active pattern of the ninth transistor, and the fifteenth via V15 is configured such that the first electrode of the fifth transistor (also the first electrode of the eighth transistor, the first electrode of the ninth transistor and the first electrode of the thirteenth transistor) formed subsequently is connected to the first region of the active pattern of the ninth transistor through the fifteenth via V15.

In an exemplary implementation, as shown in FIG. 33, an orthographic projection of the sixteenth via V16 on the base substrate is located within a range of an orthographic projection of a second region of the active pattern of the ninth transistor on the base substrate. The first insulation layer, the second insulation layer and the third insulation layer within the sixteenth via V16 is etched away to expose a surface of the second region of the active pattern of the ninth transistor, and the sixteenth via V16 is configured such that the second electrode of the ninth transistor (also the second electrode of the nth transistor) formed subsequently is connected to the second region of the active pattern of the ninth transistor through the sixteenth via V16.

In an exemplary implementation, as shown in FIG. 33, an orthographic projection of the seventeenth via V17 on the base substrate is located within a range of an orthographic projection of a first region of the active pattern of the tenth transistor on the base substrate. The first insulation layer, the second insulation layer and the third insulation layer within the seventeenth via V17 is etched away to expose a surface of the first region of the active pattern of the tenth transistor, and the seventeenth via V17 is configured such that a first electrode of the tenth transistor formed subsequently is connected to the first region of the active pattern of the tenth transistor through the seventeenth via V17.

In an exemplary implementation, as shown in FIG. 33, an orthographic projection of the eighteenth via V18 on the base substrate is located within a range of an orthographic projection of a second region of the active pattern of the tenth transistor on the base substrate. The first insulation layer, the second insulation layer and the third insulation layer within the eighteenth via V18 is etched away to expose a surface of the second region of the active pattern of the tenth transistor, and the eighteenth via V18 is configured such that the second electrode of the ninth transistor (also the second electrode of the tenth transistor) formed subsequently is connected to the second region of the active pattern of the tenth transistor through the eighteenth via V18.

In an exemplary embodiment, as shown in FIG. 33, an orthographic projection of the nineteenth via V19 on the base substrate is located within a range of an orthographic projection of the first region of the active pattern of the eleventh transistor on the base substrate. The first insulation layer, the second insulation layer and the third insulation layer within the nineteenth via V19 are etched away to expose the surface of the first region of the active pattern of the eleventh transistor, and the nineteenth via V19 is configured such that the second electrode of the second transistor (also the second electrode of the third transistor and the first electrode of the eleventh transistor) formed subsequently is connected to the first region of the active pattern of the eleventh transistor through the nineteenth via V19.

In an exemplary implementation, as shown in FIG. 33, an orthographic projection of the twentieth via V20 on the base substrate is located within a range of an orthographic projection of a second region of the active pattern of the eleventh transistor on the base substrate. The first insulation layer, the second insulation layer and the third insulation layer within the twentieth via V20 are etched away to expose a surface of the second region of the active pattern of the eleventh transistor, and the twentieth via V20 is configured such that a second electrode of the eleventh transistor formed subsequently is connected to the second region of the active pattern of the eleventh transistor through the twentieth via V20.

In an exemplary embodiment, as shown in FIG. 33, an orthographic projection of the twenty-first via V21 on the base substrate is located within a range of an orthographic projection of the first region of the active pattern of the twelfth transistor on the base substrate. The first insulation layer, the second insulation layer and the third insulation layer within the twenty-first via V21 are etched away to expose the surface of the first region of the active pattern of the twelfth transistor, and the twenty-first via V21 is configured such that the first electrode of the twelfth transistor formed subsequently is connected to the first region of the active pattern of the twelfth transistor through the twenty-first via V21.

In an exemplary embodiment, as shown in FIG. 33, an orthographic projection of the twenty-second via V22 on the base substrate is located within a range of an orthographic projection of the second region of the active pattern of the twelfth transistor (also the second region of the active pattern of the sixteenth transistor) on the base substrate. The first insulation layer, the second insulation layer and the third insulation layer within the twenty-second via V22 are etched away to expose the surface of the second region of the active pattern of the twelfth transistor (also the second region of the active pattern of the sixteenth transistor), and the twenty-second via V22 is configured such that the second electrode of the twelfth transistor (also the second electrode of the sixteenth transistor) formed subsequently is connected to the second region of the active pattern of the twelfth transistor (also the second region of the active pattern of the sixteenth transistor) through the twenty-second via V22

In an exemplary embodiment, as shown in FIG. 33, an orthographic projection of the twenty-third via V23 on the base substrate is located within a range of an orthographic projection of the second region of the active pattern of the thirteenth transistor on the base substrate. The first insulation layer, the second insulation layer and the third insulation layer within the twenty-third via V23 are etched away to expose the surface of the second region of the active pattern of the thirteenth transistor, and the twenty-third via V23 is configured such that the second electrode of the thirteenth transistor formed subsequently is connected to the second region of the active pattern of the thirteenth transistor through the twenty-third via V23.

In an exemplary embodiment, as shown in FIG. 33, an orthographic projection of the twenty-fourth via V24 on the base substrate is located within a range of an orthographic projection of the first region of the active pattern of the fourteenth transistor on the base substrate. The first insulation layer, the second insulation layer and the third insulation layer within the twenty-fourth via V24 are etched away to expose the surface of the first region of the active pattern of the fourteenth transistor, and the twenty-fourth via V24 is configured such that the first electrode of the first transistor (also the first electrode of the fourteenth transistor) formed subsequently is connected to the first region of the active pattern of the fourteenth transistor through the twenty-fourth via V24.

In an exemplary embodiment, as shown in FIG. 33, an orthographic projection of the twenty-fifth via V25 on the base substrate is located within a range of an orthographic projection of the second region of the active pattern of the fourteenth transistor on the base substrate. The first insulation layer, the second insulation layer and the third insulation layer within the twenty-fifth via V25 are etched away to expose the surface of the second region of the active pattern of the fourteenth transistor, and the twenty-fifth via V25 is configured such that the second electrode of the fourteenth transistor (also the first electrode of the fifteenth transistor) formed subsequently is connected to the second region of the active pattern of the fourteenth transistor through the twenty-fifth via V25.

In an exemplary embodiment, as shown in FIG. 33, an orthographic projection of the twenty-sixth via V26 on the base substrate is located within a range of an orthographic projection of the first region of the active pattern of the fifteenth transistor on the base substrate. The first insulation layer, the second insulation layer and the third insulation layer within the twenty-sixth via V26 are etched away to expose the surface of the first region of the active pattern of the fifteenth transistor, and the twenty-sixth via V26 is configured such that the second electrode of the fourteenth transistor (also the first electrode of the fifteenth transistor) formed subsequently is connected to the first region of the active pattern of the fifteenth transistor through the twenty-sixth via V26.

In an exemplary embodiment, as shown in FIG. 33, an orthographic projection of the twenty-seventh via V27 on the base substrate is located within a range of an orthographic projection of the second region of the active pattern of the fifteenth transistor on the base substrate. The first insulation layer, the second insulation layer and the third insulation layer within the twenty-seventh via V27 are etched away to expose the surface of the second region of the active pattern of the fifteenth transistor, and the twenty-seventh via V27 is configured such that the second electrode of the fifteenth transistor formed subsequently is connected to the second region of the active pattern of the fifteenth transistor through the twenty-seventh via V27.

In an exemplary embodiment, as shown in FIG. 33, an orthographic projection of the twenty-eighth via V28 on the base substrate is located within a range of an orthographic projection of the first region of the active pattern of the sixteenth transistor on the base substrate. The first insulation layer, the second insulation layer and the third insulation layer within the twenty-eighth via V28 are etched away to expose the surface of the first region of the active pattern of the sixteenth transistor, and the twenty-eighth via V28 is configured such that the first electrode of the sixteenth transistor formed subsequently is connected to the first region of the active pattern of the sixteenth transistor through the twenty-eighth via V28.

In an exemplary embodiment, as shown in FIGS. 16 and 33, an orthographic projection of the twenty-ninth via V29 on the base substrate is located within a range of an orthographic projection of a first region of the active pattern of the seventeenth transistor on the base substrate. The first insulation layer, the second insulation layer and the third insulation layer within the twenty-ninth via V29 are etched away to expose a surface of the first region of the active pattern of the seventeenth transistor, and the twenty-ninth via V29 is configured such that a first electrode of the seventeenth transistor subsequently formed is connected to the first region of the active pattern of the seventeenth transistor through the twenty-ninth via V29.

In an exemplary embodiment, as shown in FIG. 33, an orthographic projection of the thirtieth via V30 on the base substrate is located within a range of an orthographic projection of the second region of the active pattern of the seventeenth transistor (also the first region of the active pattern of the eighteenth transistor) on the base substrate. The first insulation layer, the second insulation layer and the third insulation layer within the thirtieth via V30 are etched away to expose the surface of the second region of the active pattern of the seventeenth transistor (also the first region of the active pattern of the eighteenth transistor), and the thirtieth via V30 is configured such that the second electrode of the seventeenth transistor (also the first electrode of the eighteenth transistor) formed subsequently is connected to the second region of the active pattern of the seventeenth transistor (also the first region of the active pattern of the eighteenth transistor) through the thirtieth via V30.

In an exemplary embodiment, as shown in FIG. 33, an orthographic projection of the thirty-first via V31 on the base substrate is located within a range of an orthographic projection of the second region of the active pattern of the eighteenth transistor (also the second region of the active pattern of the nineteenth transistor) on the base substrate. The first insulation layer, the second insulation layer, and the third insulation layer within the thirty-first via V31 are etched away to expose the surface of the second region of the active pattern of the eighteenth transistor (also the second region of the active pattern of the nineteenth transistor), and the thirty-first via V31 is configured such that the second electrode of the eighteenth transistor (also the second electrode of the nineteenth transistor) formed subsequently is connected to the second region of the active pattern of the eighteenth transistor (also the second region of the active pattern of the nineteenth transistor) through the thirty-first via V31

In an exemplary embodiment, as shown in FIG. 33, an orthographic projection of the thirty-second via V32 on the base substrate is located within a range of an orthographic projection of the first region of the active pattern of the nineteenth transistor on the base substrate. The first insulation layer, the second insulation layer and the third insulation layer within the thirty-second via V32 are etched away to expose the surface of the first region of the active pattern of the nineteenth transistor, and the thirty-second via V32 is configured such that the first electrode of the nineteenth transistor formed subsequently is connected to the first region of the active pattern of the nineteenth transistor through the thirty-second via V32.

In an exemplary embodiment, as shown in FIG. 33, an orthographic projection of the thirty-third via V33 on the base substrate is located within a range of an orthographic projection of the gate electrode of the first transistor (which is also the gate electrode of the fourteenth transistor) on the base substrate, the second insulation layer and the third insulation layer within the thirty-third via V33 are etched away to expose the surface of the gate electrode of the first transistor (which is also the gate electrode of the fourteenth transistor), and the thirty-third via V33 is configured such that the third connection portion and the first electrode of the second transistor formed subsequently to the gate electrode of the first transistor (also the gate electrode of the fourteenth transistor) through the thirty-third via V33.

In an exemplary embodiment, as shown in FIG. 33, an orthographic projection of the thirty-fourth via V34 on the base substrate is located within a range of an orthographic projection of the gate electrode of the second transistor (also the gate electrode of the eighth transistor) on the base substrate. The second insulation layer and the third insulation layer within the thirty-fourth via V34 are etched away to expose the surface of the gate electrode of the second transistor (also the gate electrode of the eighth transistor), and the thirty-fourth via V34 is configured such that the second electrode of the first transistor and the second electrode of the thirteenth transistor formed subsequently is connected to the gate electrode of the second transistor (also the gate electrode of the eighth transistor) through the thirty-fourth via V34.

In the exemplary embodiment, as shown in FIG. 33, an orthographic projection of the thirty-fifth via V35 on the base substrate is located within a range of an orthographic projection of the gate electrode of the third transistor on the base substrate, the second insulation layer and the third insulation layer within the thirty-fifth via V35 are etched away to expose the surface of the gate electrode of the third transistor, and the thirty-fifth via V35 is configured such that the fifth connection portion formed subsequently is connected to the gate electrode of the third transistor through the thirty-fifth via V35.

In an exemplary embodiment, as shown in FIG. 33, an orthographic projection of the thirty-sixth via V36 on the base substrate is located within a range of an orthographic projection of the gate electrode of the fourth transistor (also the gate electrode of the sixteenth transistor and the first plate of the third capacitor) on the base substrate. The second insulation layer and the third insulation layer within the thirty-sixth via V36 are etched away to expose the surface of the gate electrode of the fourth transistor (also the gate electrode of the sixteenth transistor and the first plate of the third capacitor), and the thirty-sixth via V36 is configured such that the second electrode of the fifteenth transistor and the first electrode of the sixteenth transistor formed subsequently is connected to the gate electrode of the fourth transistor (also the gate electrode of the sixteenth transistor and the first plate of the third capacitor) through the thirty-sixth via V36.

In an exemplary implementation, as shown in FIG. 33, an orthographic projection of the thirty-seventh via V37 on the base substrate is located within a range of an orthographic projection of the gate electrode of the fifth transistor on the base substrate. The third insulation layer and the second insulation layer within the seventeenth via V37 are etched away to expose a surface of the gate electrode of the fifth transistor, and the thirty-seventh via V37 is configured such that the second electrode of the second transistor (also the second electrode of the third transistor and the first electrode of the eleventh transistor) formed subsequently is connected to the gate electrode of the fifth transistor through the thirty-seventh via V37.

In an exemplary embodiment, as shown in FIG. 33, an orthographic projection of the thirty-eighth via V38 on the base substrate is located within a range of an orthographic projection of the gate electrode of the sixth transistor (the first plate of the first capacitor) on the base substrate. The second insulation layer and the third insulation layer within the thirty-eighth via V38 are etched away to expose the surface of the gate electrode of the sixth transistor (the first plate of the first capacitor), and the thirty-eighth via V38 is configured such that the second electrode of the eleventh transistor formed subsequently is connected to the gate electrode of the sixth transistor (the first plate of the first capacitor) through the thirty-eighth via V38.

In an exemplary implementation, as shown in FIG. 33, an orthographic projection of the thirty-ninth via V39 on the base substrate is located within a range of an orthographic projection of the gate electrode of the seventh transistor on the base substrate. The third insulation layer and the second insulation layer within the thirty-ninth via V39 are etched away to expose a surface of the gate electrode of the seventh transistor, and the nineteenth via V39 is configured such that the fourth connection portion and the first electrode of the sixth transistor formed subsequently is connected to the gate electrode of the seventh transistor through the thirty-ninth via V39.

In an exemplary embodiment, as shown in FIG. 33, an orthographic projection of the fortieth via V40 on the base substrate is located within a range of an orthographic projection of the gate electrode of the ninth transistor (also the gate electrode of the eighteenth transistor and the first plate of the second capacitor) on the base substrate. The second insulation layer and the third insulation layer within the fortieth via V40 are etched away to expose the surface of the gate electrode of the ninth transistor (also the gate electrode of the eighteenth transistor and the first plate of the second capacitor), and the fortieth via V40 is configured such that the second electrode of the seventh transistor and the second electrode of the eighth transistor formed subsequently is connected to the gate electrode of the ninth transistor (also the gate electrode of the eighteenth transistor and the first plate of the second capacitor) through the fortieth via V40.

In an exemplary embodiment, as shown in FIG. 33, an orthographic projection of the forty-first via V41 on the base substrate is located within a range of an orthographic projection of the gate electrode of the tenth transistor (also the gate electrode of the seventeenth transistor) on the base substrate, the second insulation layer and the third insulation layer within the forty-first via V41 are etched away to expose the surface of the gate electrode of the tenth transistor (also the gate electrode of the seventeenth transistor), and the forty-first via V41 is configured such that the second electrode of the twelfth transistor and the second electrode of the sixteenth transistor formed subsequently is connected to the gate electrode of the tenth transistor (also the gate electrode of the seventeenth transistor) through the forty-first via V41.

In an exemplary embodiment, as shown in FIG. 33, an orthographic projection of the forty-second via V42 on the base substrate is located within a range of an orthographic projection of the gate electrode of the eleventh transistor (also the gate electrode of the fifteenth transistor) on the base substrate. The second insulation layer and the third insulation layer within the forty-second via V42 are etched away to expose the surface of the gate electrode of the eleventh transistor (also the gate electrode of the fifteenth transistor), and the forty-second via V42 is configured such that the first electrode of the third transistor formed subsequently is connected to the gate electrode of the eleventh transistor (also the gate electrode of the fifteenth transistor) through the forty-second via V42.

In an exemplary embodiment, as shown in FIG. 33, an orthographic projection of the forty-third via V43 on the base substrate is located within a range of an orthographic projection of the gate electrode of the twelfth transistor on the base substrate. The second insulation layer and the third insulation layer within the forty-third via V43 are etched away to expose the surface of the gate electrode of the twelfth transistor, and the forty-third via V43 is configured such that the first electrode of the tenth transistor formed subsequently is connected to the gate electrode of the twelfth transistor through the forty-third via V43.

In the exemplary embodiment, as shown in FIG. 33, an orthographic projection of the forty-fourth via V44 on the base substrate is located within a range of an orthographic projection of the gate electrode of the thirteenth transistor on the base substrate. The second insulation layer and the third insulation layer within the forty-fourth via V44 are etched away to expose the surface of the gate electrode of the thirteenth transistor, and the forty-fourth via V44 is configured such that the seventh connection portion formed subsequently is connected to the gate electrode of the thirteenth transistor through the forty-fourth via V44.

In the exemplary embodiment, as shown in FIG. 33, an orthographic projection of the forty-fifth via V45 on the base substrate is located within a range of an orthographic projection of the gate electrode of the nineteenth transistor on the base substrate. The second insulation layer and the third insulation layer within the forty-fifth via V45 are etched away to expose the surface of the gate electrode of the nineteenth transistor, and the forty-fifth via V45 is configured such that the eighth connection portion formed subsequently is connected to the gate electrode of the nineteenth transistor through the forty-fifth via V45.

In an exemplary embodiment, as shown in FIG. 33, an orthographic projection of the forty-sixth via V46 on the base substrate is located within a range of an orthographic projection of the first plate of the fourth capacitor on the base substrate. The second insulation layer and the third insulation layer within the forty-sixth via V46 are etched away to expose the surface of the first plate of the fourth capacitor, and the forty-sixth via V46 is configured such that the first electrode of the tenth transistor formed subsequently is connected to the first plate of the fourth capacitor through the forty-sixth via V46.

In an exemplary embodiment, as shown in FIG. 33, an orthographic projection of the forty-seventh via V47 on the base substrate is located within a range of an orthographic projection of the first connection portion on the base substrate. The second insulation layer and the third insulation layer within the forty-seventh via V47 are etched away to expose the surface of the first connection portion, and the forty-seventh via V47 is configured such that the first electrode of the fourth transistor formed subsequently is connected to the first connection portion through the forty-seventh via V47.

In an exemplary embodiment, as shown in FIG. 33, an orthographic projection of the forty-eighth via V48 on the base substrate is located within a range of an orthographic projection of the second plate of the first capacitor on the base substrate. The forty-eighth via V48 expose the surface of the second plate of the first capacitor, and the forty-eighth via V48 is configured such that the second electrode of the sixth transistor (also the first electrode of the seventh transistor) formed subsequently is connected to the second plate of the first capacitor through the forty-eighth via V48.

In an exemplary embodiment, as shown in FIG. 33, an orthographic projection of the forty-ninth via V49 on a substrate is within a range of an orthographic projection of a second plate of the second capacitor on the base substrate. The forty-ninth via V49 expose the surface of the second plate of the second capacitor, and the forty-ninth via V49 is configured such that the first electrode of the fifth transistor (also a first electrode of an eighth transistor, a first electrode of a ninth transistor, and a first electrode of a thirteenth transistor) formed subsequently is connected to the second plate of the second capacitor through the forty-ninth via V49.

In an exemplary embodiment, as shown in FIG. 33, an orthographic projection of the fiftieth via V50 on the base substrate is within a range of an orthographic projection of the second plate of the third capacitor on the base substrate. The fiftieth via V50 exposes the surface of the second plate of the third capacitor, and the fiftieth via V50 is configured such that the second electrode of the fourth transistor (also a second electrode of a fifth transistor) formed subsequently is connected to the second plate of the third capacitor through the fiftieth via V50.

In an exemplary embodiment, as shown in FIG. 33, an orthographic projection of the fifty-first via V51 on the base substrate is within a range of an orthographic projection of the second plate of the fourth capacitor on the base substrate. The fifty-first via V51 exposes the surface of the second plate of the fourth capacitor, and the fifty-first via V51 is configured such that the second electrode of the ninth transistor (also the second electrode of the tenth transistor) formed subsequently is connected to the second plate of the fourth capacitor through the fifty-first via V51.

In the exemplary embodiment, as shown in FIG. 33, an orthographic projection of the fifty-second via V52 on the base substrate is located within a range of an orthographic projection of the second connection portion on the base substrate. The fifty-second via V52 expose the surface of the second connection portion, and the fifty-second via V52 is configured such that the first electrode of the twelfth transistor formed subsequently is connected to the second connection portion through the fifty-second via V52.

(5) Forming a pattern of a third conductive layer.

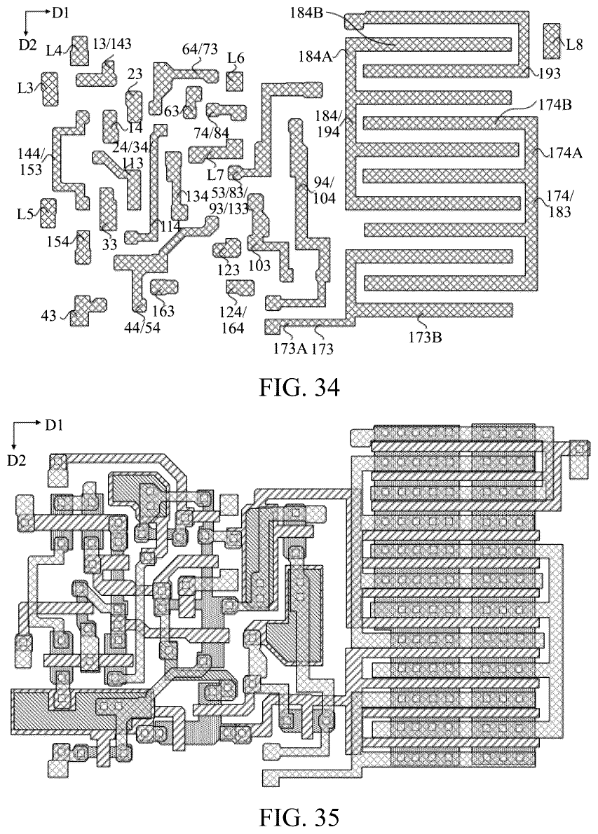

In an exemplary implementation, forming a pattern of a third conductive layer may include: depositing a fourth conductive thin film on the base substrate on which the pattern is formed, patterning the fourth conductive thin film by using a patterning process to form the fourth conductive layer arranged on the third insulation layer. As shown in FIG. 34 and FIG. 35, FIG. 34 is a schematic diagram of the third conductive layer in FIG. 26, and FIG. 35 is a schematic diagram of the third conductive layer formed in FIG. 26. In an exemplary embodiment, the third conductive layer may be referred to as a first source drain metal (SD1) layer.

In an exemplary embodiment, as shown in FIGS. 34 and 35, the pattern of the third conductive layer may include at least a first electrode 13 and a second electrode 14 of a first transistor to a first electrode 193 and a second electrode 194 of a nineteenth transistor, and a third connection portion L3 to an eighth connection portion L8.

In an exemplary embodiment, as shown in FIGS. 34 and 35, the first electrode 13 of the first transistor and the first electrode 143 of the fourteenth transistor are in an integral structure. The first electrode 13 of the first transistor (also the first electrode 143 of the fourteenth transistor) has a “ [symbol] ” shape. The first electrode 13 of the first transistor (also the first electrode 143 of the fourteenth transistor) is connected to the first region of the active pattern of the first transistor through a first via and to the first region of the active pattern of the fourteenth transistor through a twenty-fourth via.

In an exemplary embodiment, as shown in FIGS. 34 and 35, the second electrode 14 of the first transistor is individually provided. The second electrode 14 of the second transistor may have a strip shape and extend in the second direction D2. The second electrode 14 of the first transistor is connected to the second region of the active pattern of the first transistor through the second via, and is connected to the gate electrode of the second transistor (also the gate electrode of the eighth transistor) through a thirty-fourth via.

In an exemplary embodiment, as shown in FIGS. 34 and 35, the first electrode 23 of the second transistor is individually provided. The first electrode 23 of the second transistor may have a strip shape and extend in the second direction D2. The first electrode 23 of the second transistor is connected to the first region of the active pattern of the second transistor through the third via, and is connected to the gate electrode of the first transistor (also the gate electrode of the fourteenth transistor) through a thirty-third via.

In an exemplary embodiment, as shown in FIGS. 34 and 35, the second electrode 24 of the second transistor, the second electrode 34 of the third transistor, and the first electrode 113 of the eleventh transistor are in an integral structure. The integral structure of the second electrode 24 of the second transistor, the second electrode 34 of the third transistor, and the first electrode 113 of the eleventh transistor has a polyline shape and extends at least partially in the second direction D2. The second electrode 24 of the second transistor (also the second electrode 34 of the third transistor and the first electrode 113 of the eleventh transistor) is connected to the second region of the active pattern of the second transistor through the fourth via, to the second region of the active pattern of the third transistor through the sixth via, to the first region of the active pattern of the eleventh transistor through the nineteenth via, and to the gate electrode of the fifth transistor through the thirty-seventh via.

In an exemplary embodiment, as shown in FIGS. 34 and 35, the first electrode 33 of the third transistor is individually provided. The first electrode 33 of the third transistor has a strip shape and extends in the second direction D2. The first electrode 33 of the third transistor is connected to the first region of the active pattern of the third transistor through the fifth via, and is connected to the gate electrode of the eleventh transistor (also the gate electrode of the fifteenth transistor) through the forty-second via.

In an exemplary embodiment, as shown in FIGS. 34 and 35, the first electrode 43 of the fourth transistor is individually provided. The first electrode 43 of the fourth transistor has a strip shape and extends at least partially in the second direction D2. The first electrode 43 of the fourth transistor is connected to a first region of the active pattern of the fourth transistor through the seventh via and is connected to a first connection portion through the forty-seventh via.

In an exemplary embodiment, as shown in FIGS. 34 and 35, the second electrode 44 of the fourth transistor and the second electrode 54 of the fifth transistor are separately disposed in an integral structure. The second electrode 44 of the fourth transistor and the second electrode 54 of the fifth transistor are in an integral structure which has a polyline shape and extend at least partially in the second direction D2. The second electrode 44 of the fourth transistor (also the second electrode 54 of the fifth transistor) is connected to the second region of the active pattern of the fourth transistor through the eighth via, to the second region of the active pattern of the fifth transistor through the tenth via, and to the second plate of the third capacitor through the fiftieth via.

In an exemplary embodiment, as shown in FIGS. 34 and 35, the first electrode 53 of the fifth transistor, the first electrode 83 of the eighth transistor, the first electrode 93 of the ninth transistor, and the first electrode 133 of the thirteenth transistor are in an integral structure, and the integral structure of the first electrode 53 of the fifth transistor, the first electrode 83 of the eighth transistor, the first electrode 93 of the ninth transistor, and the first electrode 133 of the thirteenth transistor are in an integral structure which has a polyline shape and extends at least partially in the second direction D2. The first electrode 53 of the fifth transistor (also the first electrode 83 of the eighth transistor, the first electrode 83 of the ninth transistor and the first electrode 133 of the thirteenth transistor) is connected to the first region of the active pattern of the fifth transistor (also the first region of the active pattern of the eighth transistor and the first region of the active pattern of the thirteenth transistor) through the ninth via, to the first region of the active pattern of the ninth transistor through the fifteenth via, and to the second plate of the second capacitor through the forty-ninth via.

In the exemplary embodiment, as shown in FIGS. 34 and 35, the first electrode 63 of the sixth transistor is individually provided. The first electrode 63 of the sixth transistor has an “ [symbol] ” shape. The first electrode 63 of the sixth transistor is connected to the first region of the active pattern of the sixth transistor through the eleventh via, and is connected to the gate electrode of the seventh transistor through the thirty-ninth via.

In the exemplary embodiment, as shown in FIGS. 34 and 35, the second electrode 64 of the sixth transistor and the first electrode 73 of the seventh transistor are in an integral structure. The integral structure of the second electrode 64 of the sixth transistor and the first electrode 73 of the seventh transistor has a “ [symbol] ” shape. The second electrode 64 of the sixth transistor (also the first electrode 73 of the seventh transistor) is connected to the second region of the active pattern of the sixth transistor through the twelfth via, to the first region of the active pattern of the seventh transistor through a thirteenth via, and to the second plate of the first capacitor through the forty-eighth via.

In the exemplary embodiment, as shown in FIGS. 34 and 35, the second electrode 74 of the seventh transistor and the first electrode 84 of the eighth transistor are in an integral structure. The integral structure of the second electrode 74 of the seventh transistor and the first electrode 84 of the eighth transistor has a strip shape and extends in the first direction D1. The second electrode 74 of the seventh transistor (also the first electrode 84 of the eighth transistor) is connected to the second region of the active pattern of the seventh transistor (also the second region of the active pattern of the eighth transistor) through the fourteenth via, and is connected to the gate electrode of the ninth transistor (also the gate electrode of the eighteenth transistor and the first plate of the second capacitor) through the fortieth via.

In an exemplary embodiment, as shown in FIGS. 34 and 35, the second electrode 94 of the ninth transistor and the first electrode 104 of the tenth transistor are in an integral structure. The integral structure of the second electrode 94 of the ninth transistor and the first electrode 104 of the tenth transistor has a “ [symbol] ” shape. The second electrode 94 of the ninth transistor (also the first electrode 104 of the tenth transistor) is connected to the second region of the active pattern of the ninth transistor through the sixteenth via, to the second region of the active pattern of the tenth transistor through the eighteenth via, and to the second plate of the fourth capacitor through the fifty-first via.

In an exemplary embodiment, as shown in FIGS. 34 and 35, the first electrode 103 of the tenth transistor may be individually provided. The first electrode 103 of the tenth transistor has a polyline shape and extends at least partially in the second direction D2. The first electrode 103 of the tenth transistor is connected to the first region of the active pattern of the tenth transistor through the seventeenth via, to the gate electrode of the twelfth transistor through the forty-third via, and to the first plate of the fourth capacitor through the forty-sixth via.

In an exemplary embodiment, as shown in FIGS. 34 and 35, the second electrode 114 of the eleventh transistor may be individually provided. The second electrode 114 of the eleventh transistor has a polyline shape and extends at least partially in the second direction D2. The second electrode 114 of the eleventh transistor is connected to the second region of the active pattern of the eleventh transistor through the twentieth via, and is connected to the gate electrode of the sixth transistor (the first plate of the first capacitor) through the thirty-eighth via.

In an exemplary embodiment, as shown in FIGS. 34 and 35, the first electrode 123 of the twelfth transistor may be individually provided. The first electrode 123 of the twelfth transistor has a strip shape and extends in the first direction D1. The first electrode 123 of the twelfth transistor is connected to the first region of the active pattern of the twelfth transistor through the twenty-first via, and is connected to the second connection portion through the fifty-second via.

In an exemplary embodiment, as shown in FIGS. 34 and 35, the second electrode 124 of the twelfth transistor and the first electrode 164 of the sixteenth transistor are in an integral structure. The integral structure of the second electrode 124 of the twelfth transistor and the first electrode 164 of the sixteenth transistor has a strip shape and extends in the first direction D1. The second electrode 124 of the twelfth transistor (also the first electrode 164 of the sixteenth transistor) is connected to the second region of the active pattern of the twelfth transistor (also the second region of the active pattern of the sixteenth transistor) through the twenty-second via, and to the gate electrode of the tenth transistor (also the gate electrode of the seventeenth transistor) through the forty-first via.

In an exemplary embodiment, as shown in FIGS. 34 and 35, the second electrode 134 of the thirteenth transistor may be individually provided. The second electrode 134 of the thirteenth transistor has a strip shape and extends in the first direction D1. The second electrode 134 of the thirteenth transistor is connected to the second region of the active pattern of the thirteenth transistor through the twenty-third via, to the gate electrode of the second transistor (also the gate electrode of the eighth transistor) through the thirty-fourth via, and to the second connection portion through the fifty-second via.

In the exemplary embodiment, as shown in FIGS. 34 and 35, the second electrode 144 of the fourteenth transistor and the first electrode 153 of the fifteenth transistor are in an integral structure. The integral structure of the second electrode 144 of the fourteenth transistor and the first electrode 153 of the fifteenth transistor has a “ [symbol] ” shape rotated to the right. The second electrode 144 of the fourteenth transistor (also the first electrode 153 of the fifteenth transistor) is connected to the second region of the active pattern of the fourteenth transistor through the twenty-fifth via, and to the first region of the active pattern of the fifteenth transistor through the twenty-sixth via.

In an exemplary embodiment, as shown in FIGS. 34 and 35, the second electrode 154 of the fifteenth transistor may be individually provided. The second electrode 154 of the fifteenth transistor has a strip shape and extends in the second direction D2. The second electrode 154 of the fifteenth transistor is connected to the second region of the active pattern of the fifteenth transistor through the twenty-seventh via, and is connected to the gate electrode of the fourth transistor (also the gate electrode of the sixteenth transistor and the first plate of the third capacitor) through the thirty-sixth via.

In an exemplary embodiment, as shown in FIGS. 34 and 35, the first electrode 163 of the sixteenth transistor may be individually provided. The first electrode 163 of the sixteenth transistor has a strip shape and extends in the first direction D1. The first electrode 163 of the sixteenth transistor is connected to the first region of the active pattern of the sixteenth transistor through the twenty-eighth via, and is connected to the gate electrode of the fourth transistor (also the gate electrode of the sixteenth transistor and the first plate of the third capacitor) through the thirty-sixth via.

In an exemplary embodiment, as shown in FIGS. 34 and 35, the first electrode 173 of the seventeenth transistor may be individually provided. The first electrode 173 of the seventeenth transistor includes a fourth connection section 173A and at least one fourth branch section 173B located on the side of the fourth connection section 173A near the display area and connected to the fourth connection section 173A. The first electrode 173 of the seventeenth transistor has a comb-shaped structure, the fourth connection section 173A has a “ [symbol] ” shape which is equivalent to a “comb back”, the fourth branch section 173B extends in the first direction D1, and at least one fourth branch section 173B is arranged in the second direction D2 which is equivalent to a “comb tooth”. The first electrode 173 of the seventeenth transistor is connected to the first region of the active pattern of the seventeenth transistor through the twenty-ninth via.

In the exemplary embodiment, as shown in FIGS. 34 and 35, the second electrode 174 of the seventeenth transistor and the first electrode 183 of the eighteenth transistor are in an integral structure. The integral structure of the second electrode 174 of the seventeenth transistor and the first electrode 183 of the eighteenth transistor has a comb-shaped structure. The integral structure of the second electrode 174 of the seventeenth transistor and the first electrode 183 of the eighteenth transistor includes a fifth connection section 174A and at least one fifth branch section 174B connected to the fifth connection section 174A and located on the side of the fifth connection section 174A away from the display area, the fifth connection section 174A having a strip shape and extending in the second direction D2 which is equivalent to a “comb back”, the at least one fifth branch section 174B having a strip shape and extending in the first direction D1, and the at least one fifth branch section 174B being arranged in the second direction D2 which is equivalent to a “comb tooth”. The second electrode 174 of the seventeenth transistor (also the first electrode 183 of the eighteenth transistor) is connected to the second region of the active pattern of the seventeenth transistor (also the first region of the active pattern of the eighteenth transistor) through the thirtieth via.

In an exemplary embodiment, as shown in FIGS. 34 and 35, the second electrode 184 of the eighteenth transistor and the second electrode 194 of the nineteenth transistor are in an integral structure. The integral structure of the second electrode 184 of the eighteenth transistor and the second electrode 194 of the nineteenth transistor has a comb-shaped structure. The integral structure of the second electrode 184 of the eighteenth transistor and the second electrode 194 of the nineteenth transistor includes a sixth connection section 184A and at least one sixth branch section 184B connected to the sixth connection section 184A and located on the side of the sixth connection section 184A near the display area, the sixth connection section 184A having a strip shape and extending in the second direction D2 which is equivalent to a “comb back”, the at least one sixth branch section 184B having a strip shape and extending in the first direction D1, and the at least one sixth branch section 184B being arranged in the second direction D2 which is equivalent to a “comb tooth”. The second electrode 184 of the eighteenth transistor (also the second electrode 194 of the nineteenth transistor) is connected to the second region of the active pattern of the eighteenth transistor (also the second region of the active pattern of the nineteenth transistor) through the thirty-first via.

In an exemplary embodiment, as shown in FIGS. 34 and 35, the first electrode 193 of the nineteenth transistor may be individually provided. The first electrode 193 of the nineteenth transistor has an “n” shape rotated to the left, and its opening is away from the display area. The first electrode 193 of the nineteenth transistor is connected to the first region of the active pattern of the nineteenth transistor through the thirty-second via.

In the exemplary embodiment, as shown in FIGS. 34 and 35, the third connection portion L3 is individually provided. The third connection portion L3 has a strip shape and extends in the second direction D2. The third connection portion L3 is connected to the gate electrode of the first transistor (also the gate electrode of the fourteenth transistor) through the thirty-third via.

In the exemplary embodiment, as shown in FIGS. 34 and 35, the fourth connection portion L4 is individually provided. The fourth connection portion L4 has a strip shape and extends in the second direction D2. The fourth connection portion L4 is connected to the gate electrode of the seventh transistor through the thirty-ninth via.

In the exemplary embodiment, as shown in FIGS. 34 and 35, the fifth connection portion L5 is individually provided. The fifth connection portion L5 has a strip shape and extends in the second direction D2. The fifth connection portion L5 is connected to the gate electrode of the third transistor through the thirty-fifth via.

In the exemplary embodiment, as shown in FIGS. 34 and 35, the sixth connection portion L6 is individually provided. The sixth connection portion L6 has a strip shape and extends in the second direction D2. The sixth connection portion L6 is connected to the gate electrode of the seventh transistor through the thirty-ninth via.

In the exemplary embodiment, as shown in FIGS. 34 and 35, the seventh connection portion L7 is individually provided. The seventh connection portion L has a strip shape and extends in the first direction D1. The seventh connection portion L7 is connected to the gate electrode of the thirteenth transistor through the forty-fourth via.

In the exemplary embodiment, as shown in FIGS. 34 and 35, the eighth connection portion L8 is individually provided. The eighth connection portion L8 has a strip shape and extends in the second direction D2. The eighth connection portion L8 is connected to the gate electrode of the nineteenth transistor through the forty-fifth via.

(6) A pattern of a fourth insulation layer is formed.

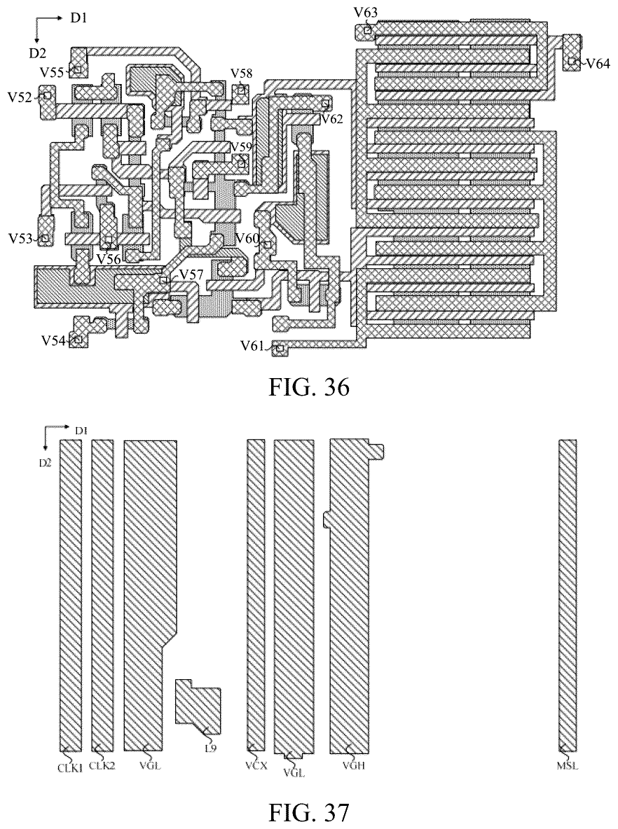

In an exemplary embodiment, forming a pattern of a fourth insulation layer may include: depositing a fourth insulating film on a substrate on which the pattern is formed, and patterning the fourth insulating film by a patterning process to form a pattern of a fourth insulation layer covering the structure, wherein the fourth insulation layer is provided with a plurality of via patterns, as shown in FIG. 36, which is a schematic diagram after forming the pattern of the fourth insulation layer in FIG. 26.

In an exemplary embodiment, as shown in FIG. 36, the pattern of the fourth insulation layer of each shift register may include at least the fifty-second via V52 to the sixty-fourth via V64.

In the exemplary embodiment, as shown in FIG. 36, an orthographic projection of the fifty-second via V52 on the base substrate is located within a range of an orthographic projection of the third connection portion on the base substrate. The fifty-second via V52 expose the surface of the third connection portion, and the fifty-second via V52 is configured such that one of the first clock signal lines and the second clock signal lines formed subsequently is connected to the third connection portion through the fifty-second via V52. FIG. 36 illustrates an example embodiment in which the fifty-second via V52 is configured such that the first clock signal line formed subsequently is connected to the third connection portion through the fifty-second via V52.

In the exemplary embodiment, as shown in FIG. 36, an orthographic projection of the fifty-third via V53 on the base substrate is located within a range of an orthographic projection of the first connection portion on the base substrate. The fifty-third via V53 exposes the surface of the fifth connection portion, and the fifty-third via V53 is configured such that one of the first clock signal lines and the second clock signal lines formed subsequently is connected to the fifth connection portion through the fifty-third via V53. FIG. 36 illustrates an example embodiment in which the fifty-third via V53 is configured such that the first clock signal line formed subsequently is connected to the fifth connection portion through the fifty-third via V53.

In an exemplary embodiment, as shown in FIG. 36, an orthographic projection of the fifty-fourth via V54 on the base substrate is located within a range of an orthographic projection of the first electrode of the fourth transistor on the base substrate. The fifty-fourth via V54 exposes the surface of the first electrode of the fourth transistor, and the fifty-fourth via V54 is configured such that the other signal line of the first clock signal line and the second clock signal line formed subsequently is connected to the first electrode of the fourth transistor through the fifty-fourth via V54. FIG. 36 illustrates an example embodiment in which the fifty-fourth via V54 is configured such that the second clock signal line formed subsequently is connected to the first electrode of the fourth transistor through the fifty-fourth via V54.

In the exemplary embodiment, as shown in FIG. 36, an orthographic projection of the fifty-fifth via V55 on the base substrate is located within a range of an orthographic projection of the fourth connection portion on the base substrate. The fifty-fifth via V55 exposes the surface of the fourth connection portion, and the fifty-fifth via V55 is configured such that the other signal line of the first clock signal line and the second clock signal line formed subsequently is connected to the fourth connection portion through the fifty-fifth via V55. FIG. 36 illustrates an example embodiment in which the fifty-fifth via V55 is configured such that the second clock signal line formed subsequently is connected to the fourth connection portion through the fifty-fifth via V55.

In an exemplary embodiment, as shown in FIG. 36, an orthographic projection of the fifty-sixth via V56 on the base substrate is located within a range of an orthographic projection of the first electrode of the third transistor on the base substrate. The fifty-sixth via V56 exposes the surface of the first electrode of the third transistor, and the fifty-sixth via V56 is configured such that the first one of second power lines formed subsequently is connected to the first electrode of the third transistor through the fifty-sixth via V56.

In an exemplary embodiment, as shown in FIG. 36, an orthographic projection of the fifty-seventh via V57 on the base substrate is located within a range of an orthographic projection of the second electrode of the fourth transistor (also the second electrode of the fifth transistor) on the base substrate. The fifty-seventh via V57 exposes the surface of the second electrode of the fourth transistor (also the second electrode of the fifth transistor), and the fifty-seventh via V57 is configured such that the ninth connection portion formed subsequently is connected to the second electrode of the fourth transistor (also the second electrode of the fifth transistor) through the fifty-seventh via V57.

In the exemplary embodiment, as shown in FIG. 36, an orthographic projection of the fifty-eighth via V58 on the base substrate is located within a range of an orthographic projection of the sixth connection portion on the base substrate. The fifty-eighth via V58 exposes the surface of the sixth connection portion, and the fifty-eighth via V58 is configured such that the third power line formed subsequently is connected to the sixth connection portion through the fifty-eighth via V58.

In an exemplary embodiment, as shown in FIG. 36, an orthographic projection of the fifty-ninth via V59 on the base substrate is located within a range of an orthographic projection of the seventh connection portion on the base substrate. The fifty-ninth via V59 exposes the surface of the seventh connection portion, and the fifty-ninth via V59 is configured such that the third power line formed subsequently is connected to the seventh connection portion through the fifty-ninth via V59.

In an exemplary embodiment, as shown in FIG. 36, an orthographic projection of the sixtieth via V60 on the base substrate is located within a range of an orthographic projection of the first electrode of the tenth transistor on the base substrate. The sixtieth via V60 exposes the surface of the first electrode of the tenth transistor, and the sixtieth via V60 is configured such that the second one of second power lines formed subsequently is connected to the first electrode of the tenth transistor through the sixtieth via V60.

In an exemplary embodiment, as shown in FIG. 36, an orthographic projection of the sixty-first via V61 on the base substrate is located within a range of an orthographic projection of the first electrode of the seventeenth transistor on the base substrate. The sixty-first via V61 exposes the surface of the first electrode of the seventeenth transistor, and the sixty-first via V61 is configured such that the second one of second power lines formed subsequently is connected to the first electrode of the seventeenth transistor through the sixty-first via V61.

In an exemplary embodiment, as shown in FIG. 36, an orthographic projection of the sixty-second via V62 on the base substrate is located within a range of an orthographic projection of the first electrode of the fifth transistor (also the first electrode of the eighth transistor, the first electrode of the ninth transistor and the first electrode of the thirteenth transistor) on the base substrate. The sixty-second via V62 exposes the surface of the first electrode of the fifth transistor (also the first electrode of the eighth transistor, the first electrode of the ninth transistor and the first electrode of the thirteenth transistor), and the sixty-second via V62 is configured such that a first power line formed subsequently is connected to the first electrode of the fifth transistor (also the first electrode of the eighth transistor, the first electrode of the ninth transistor and the first electrode of the thirteenth transistor) through the sixty-second via V62.

In an exemplary embodiment, as shown in FIG. 36, an orthographic projection of the sixty-third via V63 on the base substrate is located within a range of an orthographic projection of the first electrode of the nineteenth transistor on the base substrate. The sixty-third via V63 exposes the surface of the first electrode of the nineteenth transistor, and the sixty-third via V63 is configured such that a first power line formed subsequently is connected to the first electrode of the nineteenth transistor through the sixty-third via V63.

In the exemplary embodiment, as shown in FIG. 36, an orthographic projection of the sixty-fourth via V64 on the base substrate is located within a range of an orthographic projection of the eighth connection portion on the base substrate. The sixty-fourth via V64 exposes the surface of the eighth connection portion, and the sixty-fourth via V64 is configured such that the scan control signal line formed subsequently is connected to the eighth connection portion through the sixty-fourth via V64.

(7) Forming a pattern of a fourth conductive layer.

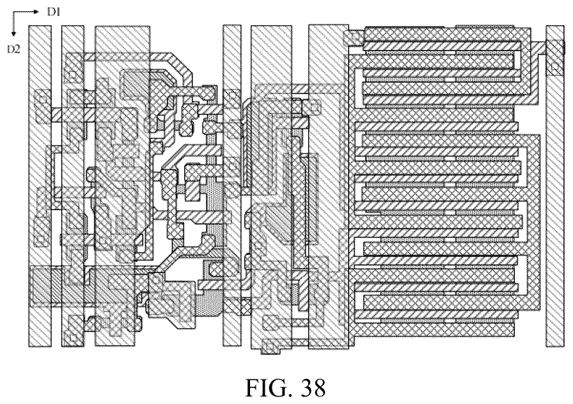

In an exemplary implementation, forming a pattern of a fourth conductive layer may include: a fourth conductive thin film is deposited on the base substrate on which the aforementioned pattern is formed, the fourth conductive thin film is patterned by a patterning process to form the fourth conductive layer disposed on the fifth insulation layer, as shown in FIGS. 37 and 38, and FIG. 37 is a schematic diagram of the pattern of the fourth conductive layer in FIG. 26, and FIG. 38 is a schematic diagram after the pattern of the fourth conductive layer is formed. In an exemplary embodiment, the fourth metal layer may be referred to as a second source drain metal (SD2) layer.

In an exemplary embodiment, as shown in FIGS. 37 and 38, the pattern of the fourth conductive layer located in each shift register may include at least a first clock signal line CLK1, a second clock signal line CLK2, a first power supply line VGH, two second power supply lines VGL, a third power supply line VCX, a scan control signal line MSL, and a ninth connection portion L9.

In the exemplary embodiment, as shown in FIGS. 37 and 38, the first clock signal line CLK1, the second clock signal line CLK2, the first one of second power supply lines VGL, the third power supply line VCX, the second one of second power supply lines VGL, the first power supply line VGH, and the scan control signal line MSL are sequentially arranged in a direction close to the display area. The ninth connection portion L9 is located between the first one of second power supply lines VGL and the third power supply line VCX.

In the exemplary embodiment, as shown in FIGS. 37 and 38, the shape of the first clock signal line CLK1 may be a line shape in which the main body portion extends in the second direction D2. The first clock signal line CLK1 is connected to the third connection portion through the fifty-second via and is connected to the fifth connection portion through the fifty-third via.

In the exemplary embodiment, as shown in FIGS. 37 and 38, the shape of the second clock signal line CLK2 may be a line shape in which the main body portion extends in the second direction D2. The second clock signal line CLK2 is connected to the first electrode of the fourth transistor through the fifty-fourth via, and is connected to the fourth connection portion through the fifty-fifth via.

In an exemplary embodiment, as shown in FIGS. 37 and 38, the shape of the first one of second power supply lines VGL may be a line shape in which the main body portion extends in the second direction D2. The first one of second power lines VGL is connected to the first electrode of the fourth transistor through the fifty-sixth via and to the first electrode of the third transistor through the fifty-fifth via.

In an exemplary embodiment, as shown in FIGS. 37 and 38, the shape of the third power supply line VCX may be a line shape in which the main body portion extends in the second direction D2. The third power line VCX is connected to the sixth connection portion through the fifty-eighth via, and is connected to the seventh connection portion through the fifty-ninth via.

In an exemplary embodiment, as shown in FIGS. 37 and 38, the shape of the second one of second power supply lines VGL may be a line shape in which the main body portion extends in the second direction D2. The second power supply line VGL is connected to the first electrode of the tenth transistor through the sixtieth via and to the first electrode of the seventeenth transistor through the sixty-first via.

In an exemplary embodiment, as shown in FIGS. 37 and 38, the shape of the first power supply line VGH may be a line shape in which the main body portion extends in the second direction D2. The first power line VGH is connected to the first electrode of the fifth transistor (also the first electrode of the eighth transistor, the first electrode of the ninth transistor and the first electrode of the thirteenth transistor) through the sixty-second via, and is connected to the first electrode of the nineteenth transistor through the sixty-third via.

In an exemplary embodiment, as shown in FIGS. 37 and 38, the shape of the scan control signal line MSL may be a line shape in which the main body portion extends in the second direction D2. The scan control signal line MSL is connected to the eighth connection portion through the sixty-fourth via.

In an exemplary embodiment, the line width of the scan control signal line MSL is less than the line width of any of the first power supply line VGH and the second power supply line VGL.

In an exemplary embodiment, the line width of the third power supply line VCX is less than the line width of any of the first power supply line VGH and the second power supply line VGL.

In an exemplary embodiment, the line width of the first clock signal line CLK1 and the line width of the second clock signal line CLK2 is less than the line width of any of the first power supply line VGH and the second power supply line VGL.

(8) A planarization layer is formed.

In an exemplary embodiment, forming a pattern of a planarization layer may include depositing a fifth insulating film on a substrate on which the pattern is formed, coating the planarization film, patterning the fifth insulating film and the planarization film by a patterning process, forming a pattern of a fifth insulation layer covering the structure and a pattern of the planarization layer covering a pattern of a fifth insulation layer.

So far, the drive circuit layer has been prepared on the base substrate. In a plane parallel to the display substrate, the drive circuit layer may include a plurality of shift registers electrically connected with the first clock signal line, the second clock signal line, the first power supply line, the second power supply line, the third power supply line and the scan control signal line. In a plane perpendicular to the display substrate, the drive circuit layer may be disposed on the base substrate, which may include a first flexible layer, a block layer, a base substrate conductive layer, and a second flexible layer stacked. The drive circuit layer may include a semiconductor layer, a first insulation layer, a first conductive layer, a second insulation layer, a third conductive layer, a fourth insulation layer, a fourth conductive layer, a fifth insulation layer, and a planarization layer that are sequentially disposed on the base substrate. The semiconductor layer may include at least an active pattern of a first transistor to a nineteenth transistor, the first conductive layer may include at least a gate electrode of the first transistor to a nineteenth transistor and a first plate of the first capacitor to a first plate of the fourth capacitor, the second conductive layer may include at least a second plate of the first capacitor to a second plate of the fourth capacitor, the third conductive layer may include at least a first electrode and a second electrode of any one of the first transistor to the nineteenth transistor, and the fourth conductive layer may include at least a first clock signal line, a second clock signal line, a first power supply line, a second power supply line, a third power supply line and a scan control signal line.

In an exemplary embodiment, the base substrate may be a rigid base substrate or a flexible base substrate, wherein the rigid base substrate may be, but is not limited to, one or more of glass and metal foil; the flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber.

In an exemplary embodiment, the flexible base substrate may include a first flexible material layer, a first inorganic material layer, a semiconductor layer, a second flexible material layer, and a second inorganic material layer which are stacked. Materials of the first flexible material layer and the second flexible material layer may be Polyimide (PI), Polyethylene Terephthalate (PET), or surface treated polymer soft film, etc., and materials of the first inorganic material layer and the second inorganic material layer may be Silicon Nitride (SiNx), Silicon Oxide (SiOx), or the like, for improving water and oxygen resistance of a base substrate. The first inorganic material layer and the second inorganic material layer may also be referred to as barrier layers, and the material of the semiconductor layer may be amorphous silicon. (a-si) In an exemplary embodiment, taking a stacked structure of PI1/Barrier1/a-si/PI2/Barrier2 as an example, its manufacturing process may include: first coating a layer of polyimide on a glass carrier board, after the layer of polyimide is cured to form a film, a first flexible (PI1) layer is formed; then depositing a layer of barrier film on the first flexible layer to form a first barrier (Barrier 1) layer overlaying the first flexible layer; then depositing a layer of amorphous silicon film on the first barrier layer to form an amorphous silicon (a-si) layer overlaying the first barrier layer; then coating another layer of polyimide on the amorphous silicon layer, after this layer of polyimide is cured to form a film, a second flexible (PI2) layer is formed; and then depositing a layer of barrier film on the second flexible layer to form a second barrier (Barrier 2) layer overlaying the second flexible layer, so as to complete the substrate manufacturing.

In an exemplary embodiment, the semiconductor layer may be an amorphous silicon layer, a polycrystalline silicon layer, or may be a metal oxide layer. Herein, the metal oxide layer may use an oxide including indium and tin, an oxide including tungsten and indium, an oxide including tungsten, indium and zinc, an oxide including titanium and indium, an oxide including titanium, indium and tin, an oxide including indium and zinc, an oxide including silicon, indium and tin, or an oxide including indium or gallium and zinc. The metal oxide layer may be a single layer, a double-layer, or a multi-layer.

In an exemplary embodiment, the first conductive layer, the second conductive layer, the third conductive layer, and the fourth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo.

In an exemplary embodiment, the first insulation layer, the second insulation layer, the third insulation layer, and the fourth insulation layer may be made of any one or more of Silicon Oxide (SiOx), Silicon Nitride (SiNx), and Silicon Oxynitride (SiON), and may be a single layer, a multi-layer, or a composite layer. The first insulation layer and the second insulation layer may be referred to as Gate Insulation (GI) layers, the third insulation layer may be referred to as Interlayer Dielectric (ILD) layers, and the fourth insulation layer may be referred to as a Passivation (PVX) layer.

In an exemplary embodiment, the planarization layer and the planarization layer may be made of an organic material, such as resin.

In an exemplary embodiment, after preparation of the drive circuit layer is completed, a light emitting structure layer is prepared on the drive circuit layer, and a preparation process of the light emitting structure layer may include following operations.

An anode conductive thin film is deposited on the base substrate on which the patterns are formed, and the anode conductive thin film is patterned by a patterning process to form a pattern of an anode conductive layer arranged on a second planarization layer. A pixel definition thin film is deposited on the base substrate on which the patterns are formed, and the pixel definition thin film is patterned by the patterning process to form a pattern of a pixel definition layer exposing the pattern of the anode conductive layer. An organic luminescent material is coated on the base substrate on which the pattern of the pixel definition layer is formed, and a pattern of an organic structure layer is formed by patterning the pattern of the organic luminescent material. A cathode conductive thin film is deposited on the base substrate on which the pattern of the organic material layer is formed and a cathode conductive layer is formed by patterning the cathode conductive thin film by the patterning process.

So far, the light emitting structure layer has been prepared on the base substrate.

In an exemplary embodiment, the anode conductive layer includes at least a plurality of anode patterns. The plurality of anode patterns may include an anode of a first light emitting device, an anode of a second light emitting device, an anode of a third light emitting device, and an anode of a fourth light emitting device, wherein the anode of the first light emitting device is located at a red sub-pixel emitting red light, the anode of the second light emitting device may be located at a blue sub-pixel emitting blue light, the anode of the third light emitting device may be located at a first green sub-pixel emitting green light, and the anode of the fourth light emitting device may be located at a second green sub-pixel emitting green light.

In an exemplary embodiment, the anode of the first light emitting device and the anode of the second light emitting device may be alternately disposed in the first direction D1, and the anode of the third light emitting device and the anode of the fourth light emitting device may be alternately disposed in the first direction D1. Alternatively, the anode of the first light emitting device and the anode of the second light emitting device may be alternately arranged in the second direction D2, and the anode of the third light emitting device and the anode of the fourth light emitting device may be alternately arranged in the second direction D2.

In an exemplary embodiment, four sub-pixels in one pixel unit may have the same or different anode shapes and areas.

In an exemplary embodiment, the anode conductive layer may be of a single-layer structure, such as Indium Tin Oxide (ITO) or Indium Zinc Oxide (IZO), or may be of a multi-layer composite structure, such as ITO/Ag/ITO.

In an exemplary embodiment, the organic structure layer may include at least an organic light emitting layer of a light emitting device.

In an exemplary embodiment, the cathode conductive layer may include at least cathodes of a plurality of light emitting devices.

In an exemplary embodiment, the cathode layer may be made of a metal material, such as any one or more of argentum (Ag), copper (Cu), aluminum (Al), and molybdenum (Mo), or a conductive alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. Exemplarily, the fourth conductive layer may be of a three-layer stacked structure formed of titanium, aluminum, and titanium.

The display substrate according to the embodiment of the present disclosure may be applied to a display product with any resolution.

In an exemplary embodiment, the subsequent preparation process may include forming a package structure layer on the cathode conductive layer, the package structure layer may include a stacked first package layer, a second package layer and a third package layer, the first package layer and the third package layer may be made of an inorganic material, the second package layer may be made of an organic material, and the second package layer is disposed between the first package layer and the third package layer to ensure that external water vapor cannot enter the light emitting structure layer.

An embodiment of the present disclosure further provides a display apparatus, which may include: a display substrate.

The display substrate is the display substrate according to any of the aforementioned embodiments, and has similar implementation principles and implementation effects, which will not be repeated here.

In an exemplary embodiment, the display apparatus may be any product or component with a display function such as a wearable device, a mobile phone, a tablet computer, a television, a display, a laptop computer, a digital photo frame, and a navigator.

The drawings of the embodiments of the present disclosure only involve structures involved in the embodiments of the present disclosure, and other structures may refer to a general design.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although the implementations of the present disclosure are disclosed above, the contents are only implementations used for ease of understanding of the present disclosure and not intended to limit the present disclosure. Any of those skilled in the art of the present disclosure can make any modifications and variations in the implementation mode and details without departing from the spirit and scope of the present disclosure. However, the protection scope of the present disclosure should be subject to the scope defined by the appended claims.

1. A shift register, comprising: a cascaded output sub-circuit and a scan output sub-circuit;
the cascaded output sub-circuit being electrically connected with a signal input terminal, a first clock signal terminal, a second clock signal terminal, a first power supply terminal, a second power supply terminal, a cascaded output terminal, a first node and a second node, respectively, and configured to provide signals to the first node and the second node under controlling of signals from the signal input terminal, the first clock signal terminal and the second clock signal terminal, and to provide a signal from the first power supply terminal or the second power supply terminal to the cascaded output terminal under controlling of signals from the first node and the second node;
the scan output sub-circuit being electrically connected with a scan control signal terminal, the first power supply terminal, the second power supply terminal, a scan output terminal, the first node and the second node, respectively, and configured to provide a signal from the first power supply terminal or the second power supply terminal to the scan output terminal under controlling of the signals from the first node, the second node and the scan control signal terminal.

2. The shift register according to claim 1, wherein the scan output sub-circuit comprises: a first output control sub-circuit and a second output control sub-circuit;
the first output control sub-circuit is electrically connected with the second power supply terminal, the scan output terminal and the second node, respectively, and is configured to provide a signal from the second power supply terminal to the scan output terminal under controlling of a signal from the second node;
the second output control sub-circuit is electrically connected with the scan control signal terminal, the first power supply terminal, the scan output terminal and the first node, respectively, and is configured to provide a signal from the first power supply terminal to the scan output terminal under controlling of signals from the scan control signal terminal and the first node.

3. The shift register according to claim 2, wherein the scan output sub-circuit further comprises: a storage sub-circuit;
the storage sub-circuit is electrically connected with the scan output terminal and the first power supply terminal, respectively, and is configured to store a voltage difference between signals at the scan output terminal and the first power supply terminal.

4. The shift register according to claim 2, wherein the first output control sub-circuit comprises: a seventeenth transistor;
a control electrode of the seventeenth transistor is electrically connected with the second node, a first electrode of the seventeenth transistor is electrically connected with the second power supply terminal, and a second electrode of the seventeenth transistor is electrically connected with the scan output terminal.

5. The shift register according to claim 2, wherein the second output sub-circuit comprises: an eighteenth transistor and a nineteenth transistor;
a control electrode of the eighteenth transistor is electrically connected with the first node, a first electrode of the eighteenth transistor is electrically connected with the first power supply terminal, and a second electrode of the eighteenth transistor is electrically connected with a third node;
a control electrode of the nineteenth transistor is electrically connected with the scan control signal terminal, a first electrode of the nineteenth transistor is electrically connected with the scan output terminal, and a second electrode of the nineteenth transistor is electrically connected with the third node.

6. The shift register according to claim 2, wherein the second output sub-circuit comprises: an eighteenth transistor and a nineteenth transistor;
a control electrode of the eighteenth transistor is electrically connected with the first node, a first electrode of the eighteenth transistor is electrically connected with the scan output terminal, and a second electrode of the eighteenth transistor is electrically connected with a third node;
a control electrode of the nineteenth transistor is electrically connected with the scan control signal terminal, a first electrode of the nineteenth transistor is electrically connected with the first power supply terminal, and a second electrode of the nineteenth transistor is electrically connected with the third node.

7. The shift register according to claim 3, wherein the storage sub-circuit comprises: a fifth capacitor;
a first plate of the fifth capacitor is electrically connected with the scan output terminal, and a second plate of the fifth capacitor is electrically connected with the first power supply terminal.

8. The shift register according to claim 1, wherein the cascaded output sub-circuit comprises: a first transistor to a sixteenth transistor and a first capacitor to a fourth capacitor, and any one of the first capacitor to the fourth capacitor comprises: a first plate and a second plate;
a control electrode of the first transistor is electrically connected with the first clock signal terminal, a first electrode of the first transistor is electrically connected with the signal input terminal, and a second electrode of the first transistor is electrically connected with a fourth node;
a control electrode of a second transistor is electrically connected with the fourth node, a first electrode of the second transistor is electrically connected with the first clock signal terminal, and a second electrode of the second transistor is electrically connected with a fifth node;
a control electrode of a third transistor is electrically connected with the first clock signal terminal, a first electrode of the third transistor is electrically connected with the second power supply terminal, and a second electrode of the third transistor is electrically connected with the fifth node;
a control electrode of a fourth transistor is electrically connected with a sixth node, a first electrode of the fourth transistor is electrically connected with the second clock signal terminal, and a second electrode of the fourth transistor is electrically connected with a seventh node;
a control electrode of a fifth transistor is electrically connected with the fifth node, a first electrode of the fifth transistor is electrically connected with the first power supply terminal, and a second electrode of the fifth transistor is electrically connected with the seventh node;
a control electrode of a sixth transistor is electrically connected with a ninth node, a first electrode of the sixth transistor is electrically connected with the second clock signal terminal, and a second electrode of the sixth transistor is electrically connected with an eighth node;
a control electrode of a seventh transistor is electrically connected with the second clock signal terminal, a first electrode of the seventh transistor is electrically connected with the eighth node, and a second electrode of the seventh transistor is electrically connected with the first node;
a control electrode of an eighth transistor is electrically connected with the fourth node, a first electrode of the eighth transistor is connected with the first power supply terminal, and a second electrode of the eighth transistor is connected with the first node;
a control electrode of a ninth transistor is electrically connected with the first node, a first electrode of the ninth transistor is electrically connected with the first power supply terminal, and a second electrode of the ninth transistor is electrically connected with the cascaded output terminal;
a control electrode of a tenth transistor is electrically connected with the second node, a first electrode of the tenth transistor is electrically connected with the second power supply terminal, and a second electrode of the tenth transistor is electrically connected with the cascaded output terminal;
a control electrode of an eleventh transistor is electrically connected with the second power supply terminal, a first electrode of the eleventh transistor is electrically connected with the fifth node, and a second electrode of the eleventh transistor is electrically connected with the ninth node;
a control electrode of a twelfth transistor is electrically connected with the second power supply terminal, a first electrode of the twelfth transistor is electrically connected with the fourth node, and a second electrode of the twelfth transistor is electrically connected with the second node;
a control electrode of a thirteenth transistor is electrically connected with a third power supply terminal, a first electrode of the thirteenth transistor is electrically connected with the first power supply terminal, and a second electrode of the thirteenth transistor is electrically connected with the fourth node;
a control electrode of a fourteenth transistor is electrically connected with the first clock signal terminal, a first electrode of the fourteenth transistor is electrically connected with the signal input terminal, and a second electrode of the fourteenth transistor is electrically connected with a tenth node;
a control electrode of a fifteenth transistor is electrically connected with the second power supply terminal, a first electrode of the fifteenth transistor is electrically connected with the tenth node, and the second electrode of the fifteenth transistor is electrically connected with the sixth node;
a control electrode of the sixteenth transistor is electrically connected with the sixth node, a first electrode of the sixteenth transistor is electrically connected with the sixth node, and a second electrode of the sixteenth transistor is electrically connected with the second node;
a first plate of the first capacitor is electrically connected with the ninth node, and a second plate of the first capacitor is electrically connected with the eighth node;
a first plate of a second capacitor is electrically connected with the first node, and a second plate of the second capacitor is electrically connected with the first power supply terminal;
a first plate of a third capacitor is electrically connected with the sixth node, and a second plate of the third capacitor is electrically connected with the seventh node;
a first plate of the fourth capacitor is electrically connected with the second power supply terminal, and a second plate of the fourth capacitor is electrically connected with the cascaded output terminal.

9. The shift register according to claim 1, wherein the scan output sub-circuit comprises: a seventeenth transistor to a nineteenth transistor, or comprises: a seventeenth transistor to a nineteenth transistor and a fifth capacitor;
a control electrode of the seventeenth transistor is electrically connected with the second node, a first electrode of the seventeenth transistor is electrically connected with the second power supply terminal, and a second electrode of the seventeenth transistor is electrically connected with the scan output terminal;
a control electrode of an eighteenth transistor is electrically connected with the first node, a first electrode of the eighteenth transistor is electrically connected with the first power supply terminal, and a second electrode of the eighteenth transistor is electrically connected with a third node;
a control electrode of the nineteenth transistor is electrically connected with the scan control signal terminal, a first electrode of the nineteenth transistor is electrically connected with the scan output terminal, and a second electrode of the nineteenth transistor is electrically connected with the third node;
a first plate of the fifth capacitor is electrically connected with the scan output terminal, and a second plate of the fifth capacitor is electrically connected with the first power supply terminal.

10. The shift register according to claim 1, wherein the scan output sub-circuit comprises: a seventeenth transistor to a nineteenth transistor, or comprises: a seventeenth transistor to a nineteenth transistor and a fifth capacitor;
a control electrode of the seventeenth transistor is electrically connected with the second node, a first electrode of the seventeenth transistor is electrically connected with the second power supply terminal, and a second electrode of the seventeenth transistor is electrically connected with the scan output terminal;
a control electrode of an eighteenth transistor is electrically connected with the first node, a first electrode of the eighteenth transistor is electrically connected with the scan output terminal, and a second electrode of the eighteenth transistor is electrically connected with a third node;
a control electrode of the nineteenth transistor is electrically connected with the scan control signal terminal, a first electrode of the nineteenth transistor is electrically connected with the first power supply terminal, and a second electrode of the nineteenth transistor is electrically connected with the third node;
a first plate of the fifth capacitor is electrically connected with the scan output terminal, and a second plate of the fifth capacitor is electrically connected with the first power supply terminal.

11. A display substrate having a display area and a non-display area, wherein the display substrate comprises: a gate drive circuit located in the non-display area, and an array of sub-pixels and a plurality of gate lines located in the display area, the sub-pixels comprising a pixel drive circuit and a light emitting device, the gate lines extending at least partially in a first direction, the gate drive circuit comprising a plurality of cascaded shift registers according to claim 1, the pixel drive circuit comprising a plurality of transistors;
a cascaded output terminal of at least one stage of shift register is electrically connected with a signal input terminal of the at least one stage of shift register;
the gate line is electrically connected with a gate electrode of the at least one transistor, and any shift register is electrically connected with at least one gate line.

12. The display substrate according to claim 11, wherein the display area is divided into a plurality of display sub-areas, at least one display sub-area comprising at least one gate line; wherein display modes of any one display sub-area comprise a first display mode and a second display mode, and a refresh frequency of the first display mode is greater than that of the second display mode;
in a state where a display mode of a display sub-area is the first display mode, for a shift register connected to the gate line in the display sub-area, when a signal at the cascaded output terminal is a first level signal, a signal at the scan control signal terminal is an active level signal during at least part of time period, and a signal at the scan output terminal is the first level signal;
in a state where the display mode of the display sub-area is the second display mode, for the shift register connected to the gate line in the display sub-area, when a signal at the cascaded output terminal is the first level signal, a signal at the scan control signal terminal is an inactive level signal, and a signal at the scan output terminal is a second level signal;
wherein a voltage value of the first level signal is greater than that of the second level signal.

13. The display substrate according to claim 11, further comprising: at least one scan control signal line located in the non-display area, the scan control signal line extending at least partially in a second direction, the first direction and the second direction intersecting;
scan control signal terminals connected to all shift registers being electrically connected with the at least one scan control signal line.

14. The display substrate according to claim 13, wherein a quantity of scan control signal lines is one,
the scan control signal terminals connected to all shift registers are electrically connected with a same scan control signal line.

15. The display substrate according to claim 13, wherein a quantity of scan control signal lines is at least two;
a scan control signal terminal connected to any one of shift registers of a M*(k−1)+k*M (a−1)+1 stage of shift register to a k*M+k*M (a−1) stage of shift register is electrically connected with a k-th scan control signal line, 1≤k≤K, 1≤a≤N/M, wherein M is a quantity of stages of shift registers to which one scan control signal line is connected, N is a total quantity of stages of shift registers, and K is a quantity of scan control signal lines.

16. The display substrate according to claim 15, wherein a picture displayed on the display substrate comprises a plurality of display frames, and in any one display frame, a output signal at the scan output terminal of the shift register is a pulse signal, and a duration H of the pulse signal satisfies a following relational expression;
$$h = L * [ M * K - M - 1 ) ] * h$$
wherein L is a quantity of gate lines connected to any stage of shift registers, h is a unit time and is equal to a refresh interval time of adjacent row sub-pixels.

17. The display substrate according to claim 13, further comprising: a first clock signal line, a second clock signal line, a first power supply line, a second power supply line, and a third power supply line located in the non-display area; wherein any one of the first clock signal line, the second clock signal line, the first power supply line, the second power supply line, and the third power supply line extends at least partially in the second direction;
a first clock signal terminal connected to any stage of shift register is electrically connected with one of the first clock signal line and the second clock signal line, a second clock signal terminal connected to any stage of shift register is electrically connected with the other of the first clock signal line and the second clock signal line, clock signal lines connected to first clock signal terminals connected to adjacent shift registers are different, clock signal lines connected to second clock signal terminals connected to adjacent shift registers are different, first power supply terminals connected to all shift registers are electrically connected with the first power supply line, second power supply terminals connected to all shift registers are electrically connected with the second power supply line, and third power supply terminals connected to all shift registers are electrically connected with the third power supply line.

18. The display substrate according to claim 17, wherein the scan control signal line is located on a side of any one of the first clock signal line, the second clock signal line, the first power supply line, the second power supply line, and the third power supply line close to the display area.

19. The display substrate according to claim 17, wherein a quantity of the second power supply lines is two, and the first clock signal line, the second clock signal line, a first one of the second power supply lines, the third power supply line, a second one of the second power supply lines, and the first power supply line are sequentially arranged in a direction close to the display area.

20. The display substrate according to claim 19, wherein the shift register comprises a seventeenth transistor to a nineteenth transistor; the seventeenth transistor to the nineteenth transistor are arranged in the second direction;
at least part of any one of the seventeenth transistor to the nineteenth transistor is located between the first power supply line and the scan control signal line.

21-24. (canceled)
